(19) United States
(12) Patent Application Publication
(10) Pub. No.: US 2026/0050214 A1
(43) Pub. Date: Feb. 19, 2026

(54) MOLECULAR RESIST COMPOSITION AND PATTERNING PROCESS

(71) Applicant: SHIN-ETSU CHEMICAL CO., LTD., Tokyo (JP)

(72) Inventors: Shun KIKUCHI, Joetsu-shi (JP); Masahiro FUKUSHIMA, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/294,679

(22) Filed: Aug. 8, 2025

(30) Foreign Application Priority Data
Aug. 19, 2024 (JP) 2024-137936

(51) Int. Cl. G03F 7/004; G03F 7/20; G03F 7/32

(52) U.S. Cl. CPC G03F 7/0045; G03F 7/2004; G03F 7/2059; G03F 7/322; G03F 7/325

(57) ABSTRACT

The present invention is a molecular resist composition comprising: a sulfonium salt represented by the following formula (1) or (2); an iodonium salt comprising an iodonium cation represented by the following formula (1-1) and a halide ion, a nitrate ion, a hydrogen sulfate ion, a hydrogen carbonate ion, a tetraphenylborate ion, or an anion represented by any of the following formulae (1-2) to (1-8); and an organic solvent, in which the molecular resist composition is free of a base polymer. This can provide a molecular resist composition that exhibits excellent sensitivity, resolution, and LWR in photolithography employing high-energy rays, and a patterning process using the molecular resist composition.

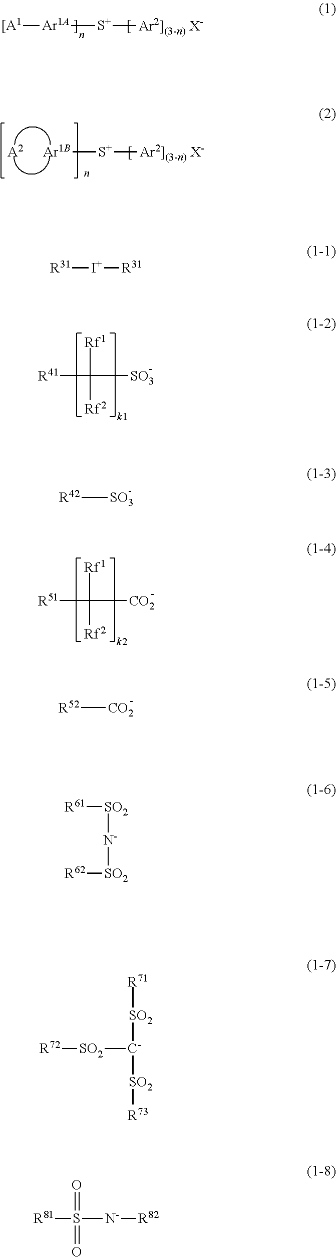

### TECHNICAL FIELD

The present invention relates to a molecular resist composition and a patterning process.

### BACKGROUND ART

With the expansion of the IoT market, there is an increasing demand for higher integration, higher speed, and lower power consumption of LSIs, and miniaturization of pattern rules is rapidly advancing. In particular, logic devices are driving the trend toward miniaturization. As a state-of-the-art miniaturization technology, mass production of 10 nm node devices has been implemented by means of double patterning, triple patterning, and quadruple patterning using ArF immersion lithography, and development of 7 nm node devices using next-generation extreme ultraviolet (EUV) lithography with a wavelength of 13.5 nm is underway.

In EUV lithography, a chemically amplified resist composition can be applied, and in line patterns, a line width of 20 nm or less can be formed. However, when a polymer-based resist composition used in ArF lithography is employed for EUV lithography, the large molecular size of the base polymer contained therein results in roughness on the pattern surface, making pattern control difficult. Accordingly, various low-molecular-weight materials have been proposed.

A molecular resist composition is a resist composition that contains, as its main component, a low-molecular-weight compound and is free of a base polymer used in polymer-based resist compositions. The molecular resist composition is expected as one effective measure for forming fine patterns. For example, an alkali-developable negative-type radiation-sensitive composition using a polyvalent polyphenol compound as a main component has been proposed (Patent Document 1). Also, an alkali-developable positive-type resist composition containing only an acid generator in which a tert-butoxycarbonyl group is added to a cation of a sulfonium salt and combined with an anion of a strong acid has been proposed (Non Patent Document 1). The acid generator is expected to improve roughness due to its small molecular size as compared with polymeric materials; however, in the case of the molecular resist composition using the chemical amplification mechanism, control of acid diffusion is difficult, and therefore satisfactory performance has not yet been obtained. Furthermore, in EUV resist compositions, not only roughness but also high sensitivity and high resolution must be achieved simultaneously, and further improvements are required.

As a factor that makes material development for EUV lithography difficult, the small number of photons in EUV exposure is cited. The energy of EUV is far higher than that of ArF excimer laser light, and the number of photons in EUV exposure is one fourteenth that in ArF exposure. Furthermore, the dimension of patterns formed by EUV exposure is less than or equal to half of that by ArF exposure. Therefore, EUV exposure is susceptible to variation in the number of photons. In a region of extremely short-wavelength radiation, variation in the number of photons is caused by a physical phenomenon referred to as shot noise, and influence thereof cannot be eliminated. Accordingly, what is referred to as stochastics has been attracting attention. Although the influence of shot noise cannot be eliminated, discussions have been made regarding how the influence can be reduced. Due to the influence of shot noise, not only critical dimension uniformity (CDU) and line width roughness (LWR) become large, but also a phenomenon in which a hole becomes blocked with a probability on the order of one in several million has been observed. When a hole becomes blocked, an electrical conduction failure occurs, and as a result, operation of the transistor is not performed, whereby performance of the entire device is adversely affected.

As a method for reducing the influence of shot noise on the resist side, there has been proposed an inorganic resist composition using, as a core, an element having a high EUV absorption (Patent Document 2). However, although the inorganic resist composition exhibits relatively high sensitivity, the sensitivity is still insufficient, and various problems remain, such as poor solubility in resist solvents, storage stability, and occurrence of defects.

### CITATION LIST

### Patent Literature

Patent Document 1: JP 2005-326838 A
Patent Document 2: JP 2015-108781 A

### Non Patent Literature

Non Patent Document 1: Proc. of SPIE Vol. 6923, 69230K (2008)

### SUMMARY OF INVENTION

### Technical Problem

The present invention has been made in view of the foregoing circumstances, and an object thereof is to provide a molecular resist composition that exhibits excellent sensitivity, resolution, and LWR in photolithography employing high-energy rays, and a patterning process using the molecular resist composition.

### Solution to Problem

To solve the problem, the present invention provides a molecular resist composition comprising: a sulfonium salt represented by the following formula (1) or (2);
an iodonium salt comprising an iodonium cation represented by the following formula (1-1) and a halide ion, a nitrate ion, a hydrogen sulfate ion, a hydrogen carbonate ion, a tetraphenylborate ion, or an anion represented by any one of the following formulae (1-2) to (1-8); and
an organic solvent;
wherein the molecular resist composition is free of a base polymer.

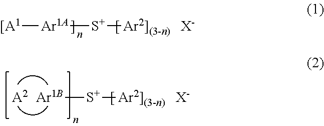

wherein n is an integer of 1 to 3; A¹ is a hydrocarbyl group having 2 to 20 carbon atoms and containing a polymerizable functional group, and the hydrocarbyl group optionally contains a hetero atom; A² is a group containing a polymerizable functional group and forming an alicyclic ring having 4 to 20 carbon atoms together with two carbon atoms in Ar^{1B}, and the alicyclic ring optionally contains a hetero atom; Ar^{1A} is an arylene group having 6 to 20 carbon atoms, and hydrogen atoms on the aromatic ring of the arylene group are optionally partially or entirely substituted with halogen atoms or hydrocarbyl groups having 1 to 20 carbon atoms and optionally containing a hetero atom; Ar^{1B} is a trivalent aromatic hydrocarbon group having 6 to 20 carbon atoms, and hydrogen atoms on the aromatic ring of the trivalent aromatic hydrocarbon group are optionally partially or entirely substituted with halogen atoms or hydrocarbyl groups having 1 to 20 carbon atoms and optionally containing a hetero atom; Ar² is an aryl group having 6 to 20 carbon atoms, and hydrogen atoms on the aromatic ring of the aryl group are optionally partially or entirely substituted with halogen atoms or hydrocarbyl groups having 1 to 20 carbon atoms and optionally containing a hetero atom; two Ar^{1A} groups, two Ar^{1B} groups, two Ar² groups, Ar^{1A} and Ar², or Ar^{1B} and Ar² are optionally bonded to each other to form a ring together with the sulfur atom to which they are bonded; and X⁻ is a counter anion;

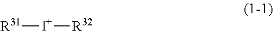

wherein R³¹ and R³² are each independently a halogen atom or a hydrocarbyl group having 1 to 30 carbon atoms and optionally containing a hetero atom;

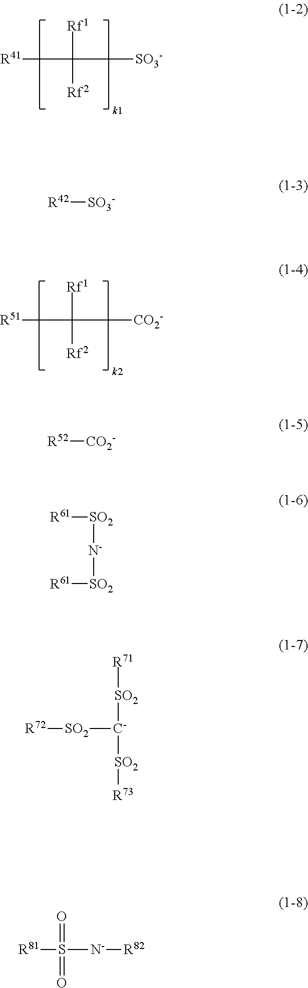

wherein k1 and k2 are each independently 1, 2, 3, or 4; Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time; R⁴¹ is a hydrogen atom, a halogen atom, a hydroxy group, or a hydrocarbyl group having 1 to 50 carbon atoms and optionally containing a hetero atom; R⁴² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atom of the sulfo group is substituted with a fluorine atom or a fluoroalkyl group; R⁵¹ is a hydrogen atom, a halogen atom, a hydroxy group, or a hydrocarbyl group having 1 to 50 carbon atoms and optionally containing a hetero atom; R⁵² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the carboxy group is substituted with fluorine atoms or a fluoroalkyl group; R⁶¹ and R⁶² are each independently a hydrocarbyl group having 1 to 50 carbon atoms and optionally containing a hetero atom; R⁷¹ to R⁷³ are each independently a hydrocarbyl group having 1 to 50 carbon atoms and optionally containing a hetero atom; R⁸¹ is a fluorine atom or a fluorinated hydrocarbyl group having 1 to 10 carbon atoms, and the fluorinated hydrocarbyl group optionally contains a hydroxy group, an ether bond, or an ester bond; R⁸² is a hydrogen atom or a hydrocarbyl group having 1 to 20 carbon atoms, and the hydrocarbyl group optionally contains a hydroxy group, an ether bond, or an ester bond; and R⁸¹ and R⁸² are optionally bonded to each other to form a ring together with the atoms to which they are bonded.

With the molecular resist composition of the present invention, excellent sensitivity, resolution, and LWR can be realized in photolithography employing high-energy rays, particularly electron beam (EB) lithography and EUV lithography.

In the present invention, it is preferable that the A¹ is an acryloyloxy group, a methacryloyloxy group, a cycloalkenyl group having 3 to 20 carbon atoms and optionally containing a hetero atom, a cycloalkenyloxy group having 3 to 20 carbon atoms and optionally containing a hetero atom, a cycloalkenylcarbonyloxy group having 3 to 20 carbon atoms and optionally containing a hetero atom, an alkenyl group having 2 to 20 carbon atoms and optionally containing a hetero atom, or an alkenyloxy group having 2 to 20 carbon atoms and optionally containing a hetero atom, and that the A² is a group that forms, together with two carbon atoms in Ar^{1B}, a cycloalkene ring having 4 to 20 carbon atoms and optionally containing a hetero atom or a polycyclic ring having 4 to 20 carbon atoms and having one double bond and optionally containing a hetero atom.

In the case where A¹ is a hydrocarbyl group including a polymerizable functional group, and A² is a polymerizable functional group-containing group that forms a ring together with two carbon atoms in Ar^{1B}, suitable pattern formation becomes possible by a contribution of polymerization via the polymerizable functional group.

In the present invention, it is preferable that the above-mentioned X⁻ is the same as the counter anion of the iodonium cation represented by the formula (1-1).

Thus, in the molecular resist composition of the present invention, it is preferable that the anion X⁻ of the sulfonium salt represented by the formula (1) or (2) and the counter anion of the iodonium cation represented by the formula (1-1) are expressed by similar structures.

In the present invention, it is preferable that the anion represented by any of formulae (1-2) to (1-8) includes a polymerizable functional group.

In the present invention, from the view point of pattern formation, it is preferable that both the cation forming the sulfonium salt represented by the formula (1) or (2) and the anion represented by any of formulae (1-2) to (1-8), that is, the counter anion of the iodonium cation represented by the formula (1-1), have polymerizable functional groups, and it is more preferable that both the anion of the sulfonium salt and the anion of the iodonium salt have polymerizable functional groups.

The molecular resist composition of the present invention may further contain a radical scavenger and may also contain a surfactant.

The molecular resist composition of the present invention may contain such components as required.

In addition, the present invention provides a patterning process comprising:
forming a resist film on a substrate using the above molecular resist composition;
exposing the resist film to high-energy ray; and developing the exposed resist film with a developer.

According to the patterning process of the present invention, by forming a resist film on a substrate using the molecular resist composition of the present invention, it becomes possible to form a pattern having excellent sensitivity, resolution, and LWR in photolithography employing high-energy rays, particularly electron beam (EB) lithography and EUV lithography.

In such a case, an alkaline aqueous solution is used as a developer to dissolve the exposed portion, thereby obtaining a positive-type pattern in which the unexposed portion is not dissolved. Alternatively, an organic solvent or an alkaline aqueous solution is used as a developer to dissolve the unexposed portion, thereby obtaining a negative-type pattern in which the exposed portion is not dissolved.

Thus, by employing the molecular resist composition of the present invention in combination with an appropriate developer, both a positive-type pattern and a negative-type pattern can be obtained.

In the present invention, it is preferable that the organic solvent used as the developer is at least one selected from the group consisting of 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate.

When the molecular resist composition of the present invention is used to obtain a negative-type pattern by organic solvent development, the above-described organic solvent can be suitably employed.

In the present invention, an electron beam or extreme ultraviolet ray is used as the high-energy ray.

Since the molecular resist composition of the present invention exhibits excellent sensitivity, resolution, and LWR, particularly in EB lithography and EUV lithography, a favorable pattern that satisfies the requirements for finer pattern rules can be formed.

### Advantageous Effects of Invention

As described above, the molecular resist composition of the present invention is highly useful for forming fine patterns, since it achieves both high sensitivity and high resolution, and also exhibits excellent LWR in photolithography employing high-energy rays, particularly EB lithography and EUV lithography.

### BRIEF DESCRIPTION OF DRAWINGS

FIG. 1 is a ¹H-NMR spectrum of PAG-1 obtained in Synthesis Example 1-1;

FIG. 2 is a ¹H-NMR spectrum of PAG-2 obtained in Synthesis Example 1-2;

FIG. 3 is a ¹H-NMR spectrum of PAG-3 obtained in Synthesis Example 1-3;

FIG. 4 is a ¹H-NMR spectrum of PAG-4 obtained in Synthesis Example 1-4;

FIG. 5 is a ¹H-NMR spectrum of PAG-5 obtained in Synthesis Example 1-5;

FIG. 6 is a ¹H-NMR spectrum of PAG-6 obtained in Synthesis Example 1-6;

FIG. 7 is a ¹H-NMR spectrum of PAG-7 obtained in Synthesis Example 1-7;

FIG. 8 is a ¹H-NMR spectrum of PAG-8 obtained in Synthesis Example 1-8; and

FIG. 9 is a ¹H-NMR spectrum of PAG-9 obtained in Synthesis Example 1-9.

### DESCRIPTION OF EMBODIMENTS

The present inventors have conducted extensive studies in order to achieve the above-described object, and as a result, have found that a molecular resist composition containing a sulfonium salt and an iodonium salt, each having a specific partial structure, provides a resist film exhibiting high sensitivity, excellent resolution, and LWR, and is extremely effective for high-precision fine processing, thereby completing the present invention.

That is, the present invention is a molecular resist composition comprising: a sulfonium salt represented by the following formula (1) or (2); an iodonium salt comprising an iodonium cation represented by the following formula (1-1) and a halide ion, a nitrate ion, a hydrogen sulfate ion, a hydrogen carbonate ion, a tetraphenylborate ion, or an anion represented by any one of the following formulae (1-2) to (1-8); and an organic solvent, wherein the molecular resist composition is free of a base polymer,

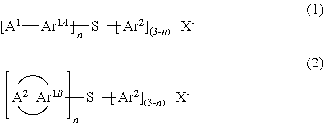

wherein n is an integer of 1 to 3; A¹ is a hydrocarbyl group having 2 to 20 carbon atoms and containing a polymerizable functional group, and the hydrocarbyl group optionally contains a hetero atom; A² is a group containing a polymerizable functional group and forming an alicyclic ring having 4 to 20 carbon atoms together with two carbon atoms in Ar^{1B}, and the alicyclic ring optionally contains a hetero atom; Ar^{1A} is an arylene group having 6 to 20 carbon atoms, and hydrogen atoms on the aromatic ring of the arylene group are optionally partially or entirely substituted with halogen atoms or hydrocarbyl groups having 1 to 20 carbon atoms and optionally containing a hetero atom; Ar^{1B} is a trivalent aromatic hydrocarbon group having 6 to 20 carbon atoms, and hydrogen atoms on the aromatic ring of the trivalent aromatic hydrocarbon group are optionally partially or entirely substituted with halogen atoms or hydrocarbyl groups having 1 to 20 carbon atoms and optionally containing a hetero atom; Ar² is an aryl group having 6 to 20 carbon atoms, and hydrogen atoms on the aromatic ring of the aryl group are optionally partially or entirely substituted with halogen atoms or hydrocarbyl groups having 1 to 20 carbon atoms and optionally containing a hetero atom; two Ar^{1A} groups, two Ar^{1B} groups, two Ar² groups, Ar^{1A} and Ar², or Ar^{1B} and Ar²′ are optionally bonded to each other to form a ring together with the sulfur atom to which they are bonded; and X⁻ is a counter anion;

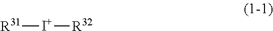

wherein R³¹ and R³² are each independently a halogen atom or a hydrocarbyl group having 1 to 30 carbon atoms and optionally containing a hetero atom;

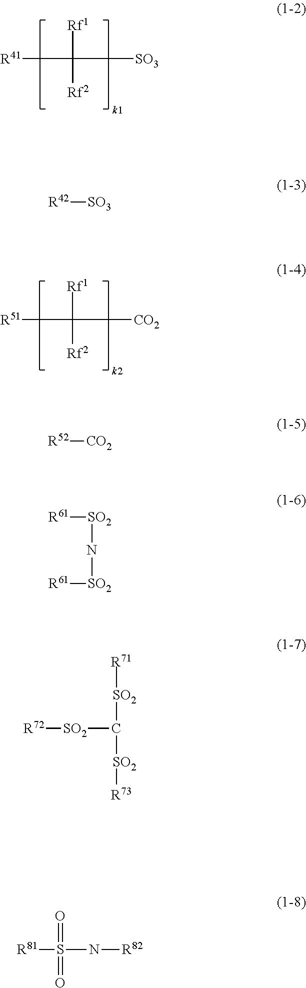

wherein k1 and k2 are each independently 1, 2, 3, or 4; Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time; R⁴¹ is a hydrogen atom, a halogen atom, a hydroxy group, or a hydrocarbyl group having 1 to 50 carbon atoms and optionally containing a hetero atom; R⁴² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the sulfo group is substituted with a fluorine atom or a fluoroalkyl group; R⁵¹ is a hydrogen atom, a halogen atom, a hydroxy group, or a hydrocarbyl group having 1 to 50 carbon atoms and optionally containing a hetero atom; R⁵² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the carboxy group is substituted with a fluorine atom or a fluoroalkyl group; R⁶¹ and R⁶² are each independently a hydrocarbyl group having 1 to 50 carbon atoms and optionally containing a hetero atom; R⁷¹ to R⁷³ are each independently a hydrocarbyl group having 1 to 50 carbon atoms and optionally containing a hetero atom; R⁸¹ is a fluorine atom or a fluorinated hydrocarbyl group having 1 to 10 carbon atoms, and the fluorinated hydrocarbyl group optionally contains a hydroxy group, an ether bond, or an ester bond; R⁸² is a hydrogen atom or a hydrocarbyl group having 1 to 20 carbon atoms, and the hydrocarbyl group optionally contains a hydroxy group, an ether bond, or an ester bond; and R⁸¹ and R⁸² are optionally bonded to each other to form a ring together with the atoms to which they are bonded.

The present invention will be described in detail below; however, the present invention is not limited to the following description. In the present specification, a numerical range defined by endpoints shall be construed to include all values lying within the stated range.

### [Molecular Resist]

A molecular resist composition of the present invention comprises: (i) a sulfonium salt represented by the aforementioned formula (1) or (2); (ii) an iodonium salt comprising an iodonium cation represented by the aforementioned formula (1-1) and a halide ion, a nitrate ion (NO₃⁻), a hydrogen sulfate ion (HSO₄⁻), a hydrogen carbonate ion (HCO₃⁻), a tetraphenylborate ion (BPh₄⁻), or an anion represented by any one of the following formulae (1-2) to (1-8); (iii) an organic solvent; and (iv) no base polymer. In the molecular resist composition of the present invention, the term “main component” refers to a component having the highest content excluding the solvent.

The molecular resist composition of the present invention employs, as a main component, the above-described sulfonium salt which is a monomolecular compound, and by combining the same with the above-described photodecomposable iodonium salt, it becomes possible to form a pattern exhibiting improved contrast, sensitivity, and resolution, even in the absence of a base polymer that is generally employed in polymer-based resist compositions, since the sulfonium salt having a polymerizable functional group undergoes polymerization and thereby efficiently increases in molecular weight.

The above-described sulfonium salt contributes to improvement in roughness due to its small molecular size as compared with polymeric materials. On the other hand, the above-described iodonium salt improves the absorption of EUV light by its incorporation, thereby further improving the stochastics, sensitivity, and roughness of the resist.

The components included in the molecular resist composition of the present invention will be described below.

### [Sulfonium Salt]

The molecular resist composition of the present invention comprises, as a main component, a sulfonium salt represented by the following formula (1) or (2).

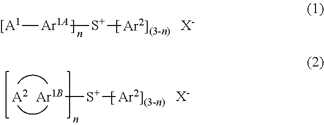

In the above formulae, n is an integer of 1 to 3. A¹ is a hydrocarbyl group having 2 to 20 carbon atoms and containing a polymerizable functional group, and the hydrocarbyl group optionally contains a hetero atom.

A² is a group containing a polymerizable functional group and forming an alicyclic ring having 4 to 20 carbon atoms together with two carbon atoms in Ar^{1B}, and the alicyclic ring optionally contains a hetero atom. Ar^{1A} is an arylene group having 6 to 20 carbon atoms, and hydrogen atoms on the aromatic ring of the arylene group are optionally partially or entirely substituted with halogen atoms or hydrocarbyl groups having 1 to 20 carbon atoms and optionally containing a hetero atom.

Ar^{1B} is a trivalent aromatic hydrocarbon group having 6 to 20 carbon atoms, and hydrogen atoms on the aromatic ring of the trivalent aromatic hydrocarbon group are optionally partially or entirely substituted with halogen atoms or hydrocarbyl groups having 1 to 20 carbon atoms and optionally containing a hetero atom.

Ar² is an aryl group having 6 to 20 carbon atoms, and hydrogen atoms on the aromatic ring of the aryl group are optionally partially or entirely substituted with halogen atoms or hydrocarbyl groups having 1 to 20 carbon atoms and optionally containing a hetero atom.

In addition, two Ar^{1A}, two Ar^{1B}, two Ar², Ar^{1A} and Ar², or Ar^{1B} and Ar² may be bonded to each other to form a ring together with the sulfur atom to which they are bonded.

X⁻ is a counter anion.

The polymerizable functional group contained in the above-described A¹ and A² is radical-polymerizable.

In formulae (1) and (2), n is an integer of 1 to 3.

In formula (1), A¹ is a hydrocarbyl group having 2 to 20 carbon atoms and containing a polymerizable functional group, and the hydrocarbyl group optionally contains a hetero atom. In formula (2), A² is a group containing a polymerizable functional group and forming an alicyclic ring having 4 to 20 carbon atoms together with two carbon atoms in Ar^{1B}, and the alicyclic ring optionally contains a hetero atom. Examples of the heteroatom include an oxygen atom, a sulfur atom, a nitrogen atom, a halogen atom, and the like.

Preferred examples of A¹ include an acryloyloxy group, a methacryloyloxy group, a cycloalkenyl group having 3 to 20 carbon atoms and optionally containing a hetero atom, a cycloalkenyloxy group having 3 to 20 carbon atoms and optionally containing a hetero atom, a cycloalkenylcarbonyloxy group having 3 to 20 carbon atoms and optionally containing a hetero atom, an alkenyl group having 2 to 20 carbon atoms and optionally containing a hetero atom, or an alkenyloxy group having 2 to 20 carbon atoms and optionally containing a hetero atom. Preferred examples of A² include a group that forms, together with two carbon atoms in Ar^{1B}, a cycloalkene ring having 4 to 20 carbon atoms and optionally containing a hetero atom or a polycyclic ring having 4 to 20 carbon atoms and having one double bond and optionally containing a hetero atom.

Specific examples of the groups represented by A¹ are shown below, but are not limited to these examples. In the formulae below, the broken line represents a bond to Ar^{1A}.

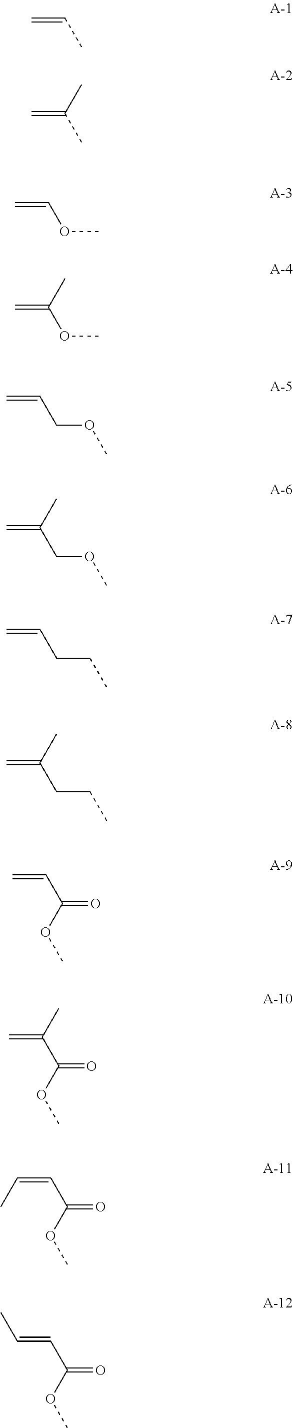

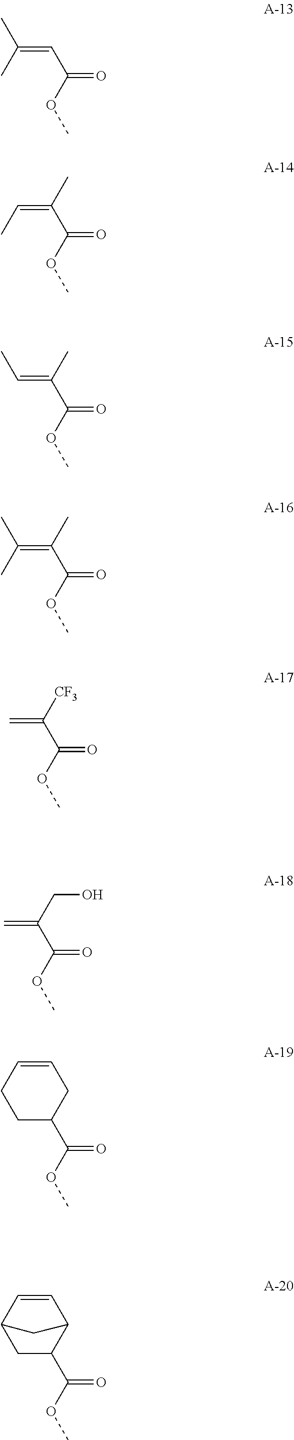

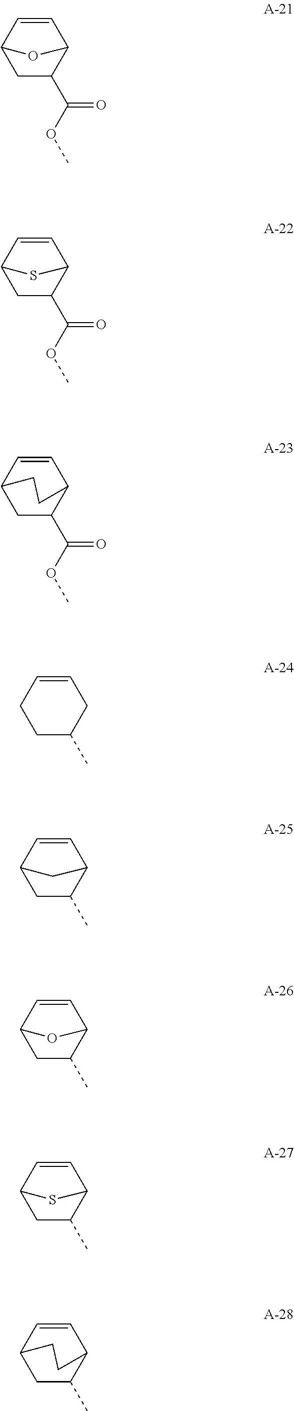

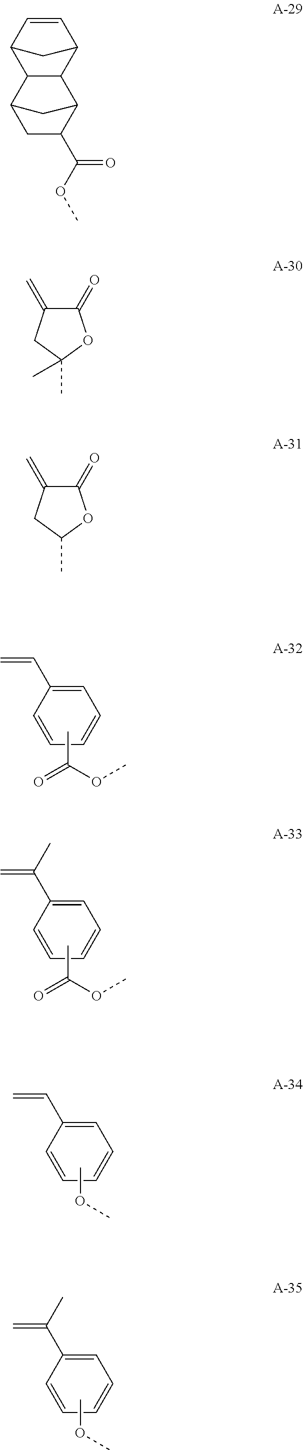

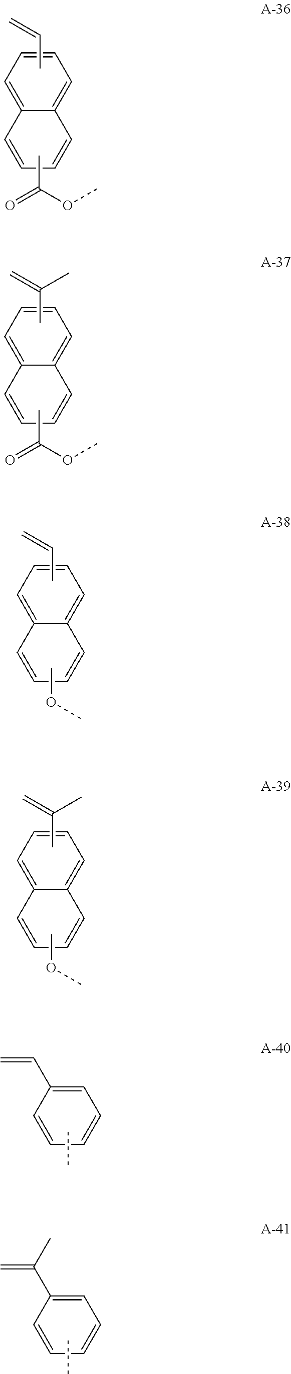

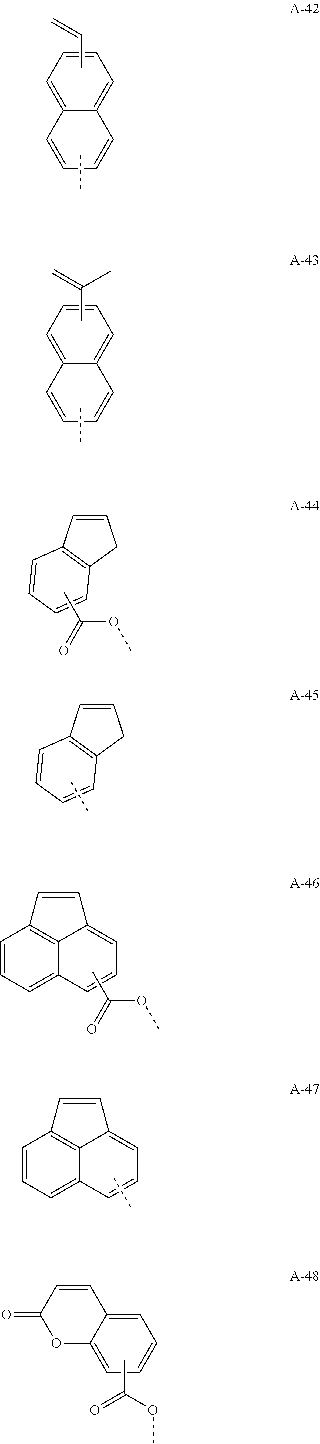

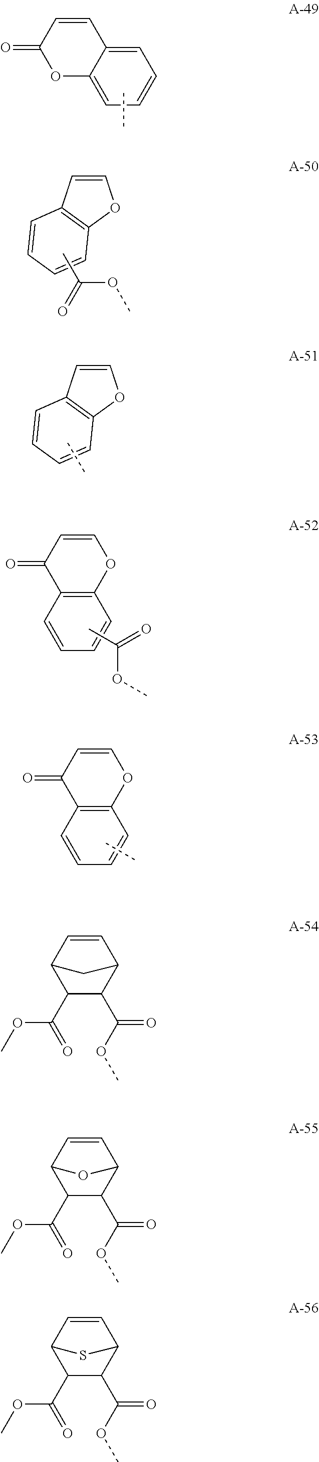

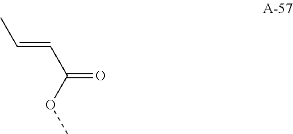

Specific examples of alicyclic structures having 4 to 20 carbon atoms formed by A² and two carbon atoms in Ar^{1B} are shown below; however, these are not limited to the examples. In the formulae below, “C” represents the carbon atoms contained in Ar^{1B}.

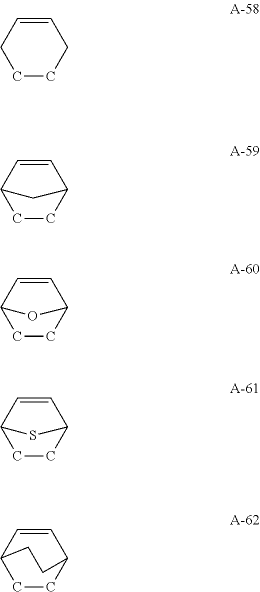 [SMILES: C1=CCCCC1 ; C1=CC2CCC1C2 ; C1=CC2CCC1O2 ; C1=CC2CCC1S2 ; C1=CC2CCC1CC2]

Among these, from the viewpoint of ease of introduction in the synthesis process and polymerization reactivity, A-1 to A-18, A-30 to A-43, and A-57 are preferred, furthermore A-9 to A-18, A-30 to A-35, and A-40 being more preferred.

In formula (1), Ar^{2A} is an arylene group having 6 to 20 carbon atoms. Examples of the arylene group include a phenylene group, a naphthylene group, and an anthracenediyl group. In formula (2), Ar^{1B} is a trivalent aromatic hydrocarbon group having 6 to 20 carbon atoms. Examples of the trivalent aromatic hydrocarbon group include groups obtained by removing three hydrogen atoms from benzene, naphthalene, or anthracene. In formulae (1) and (2), Ar² is an aryl group having 6 to 20 carbon atoms. Examples of the aryl group include a phenyl group, a naphthyl group, and an anthracenyl group. Among these, from the viewpoint of solubility in solvents, Ar^{2A} is preferably a phenylene group or a naphthylene group, more preferably a phenylene group; Ar^{1B} is preferably a benzentriyl group or a naphthalentriyl group, more preferably a benzentriyl group; and Ar² is preferably a phenyl group or a naphthyl group, more preferably a phenyl group.

Some or all of the hydrogen atoms of the arylene group, trivalent aromatic hydrocarbon group, and aryl group are optionally substituted with a halogen atom or a hydrocarbyl group having 1 to 20 carbon atoms and optionally containing a hetero atom. Examples of the halogen atom include a fluorine atom, a chlorine atom, a bromine atom, an iodine atom, and the like. The hydrocarbyl group having 1 to 20 carbon atoms may be saturated or unsaturated, and may be linear, branched, or cyclic. Specific examples thereof include alkyl groups having 1 to 20 carbon atoms, such as methyl group, ethyl group, propyl group, isopropyl group, n-butyl group, sec-butyl group, tert-butyl group, tert-pentyl group, n-pentyl group, n-hexyl group, n-octyl group, 2-ethylhexyl group, n-nonyl group, and n-decyl group; cyclic saturated hydrocarbyl groups having 3 to 20 carbon atoms, such as cyclopentyl group, cyclohexyl group, cyclopentylmethyl group, cyclopentylethyl group, cyclopentylbutyl group, cyclohexylmethyl group, cyclohexylethyl group, cyclohexylbutyl group, norbornyl group, tricyclo[5.2.1.0^{2,6}]decanyl group, adamantyl group, and adamantylmethyl group; and aryl groups having 6 to 20 carbon atoms, such as phenyl group, naphthyl group, and anthracenyl group. In addition, the hydrogen atoms of the above hydrocarbyl group are optionally partially or entirely substituted with a group containing a hetero atom such as an oxygen atom, a sulfur atom, a nitrogen atom, or a halogen atom, and some of the —CH₂— groups constituting the hydrocarbyl group are optionally substituted with a group containing a hetero atom such as an oxygen atom, a sulfur atom, or a nitrogen atom, and as a result, the hydrocarbyl group optionally contains a hydroxy group, a cyano group, a halogen atom, a carbonyl group, an ether bond, a thioether bond, an ester bond, a sulfonate ester bond, a carbonate bond, a carbamate bond, a lactone ring, a sultone ring, or a carboxylic acid anhydride group (—C(═O)—O—C(═O)—).

In addition, when present, two Ar^{1A}, two Ar^{1B}, two Ar², Ar^{1A} and Ar², or Ar^{1B} and Ar² are optionally bonded to each other to form a ring together with the sulfur atom to which they are bonded. Examples of the structure of the ring include, but are not limited to, those shown below.

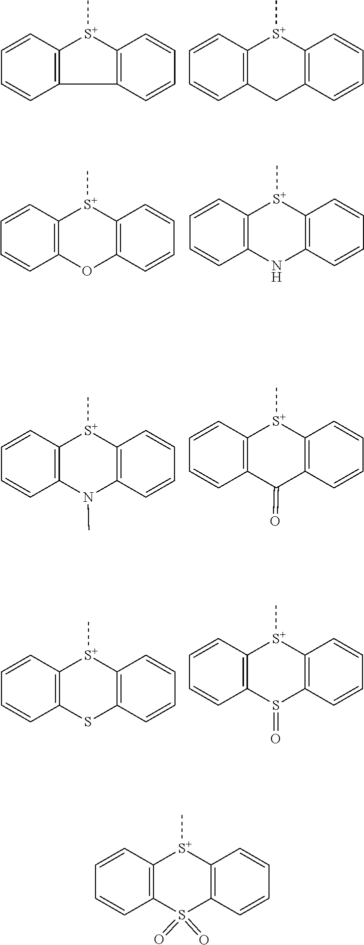

wherein the broken line is a bond.

Specific examples of the cation of the sulfonium salt represented by formula (1) include, but are not limited to, those shown below.

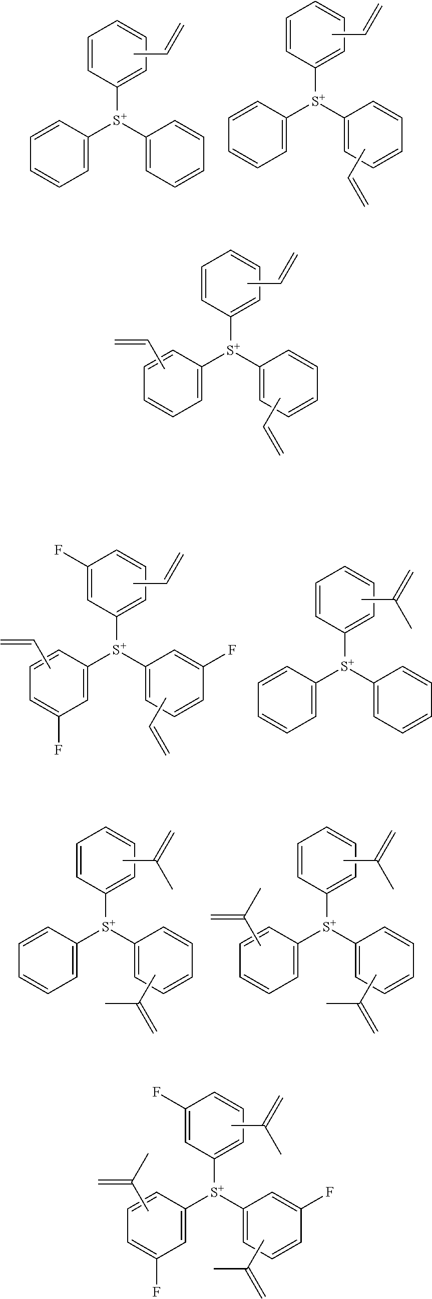

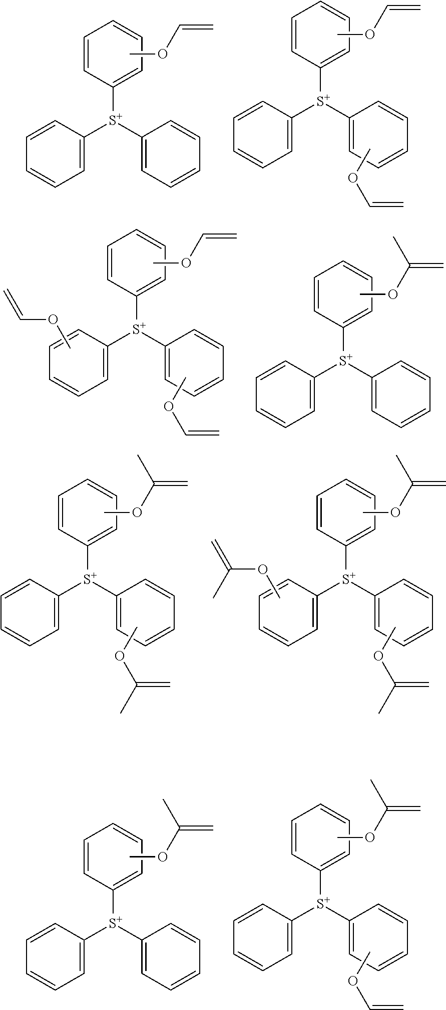

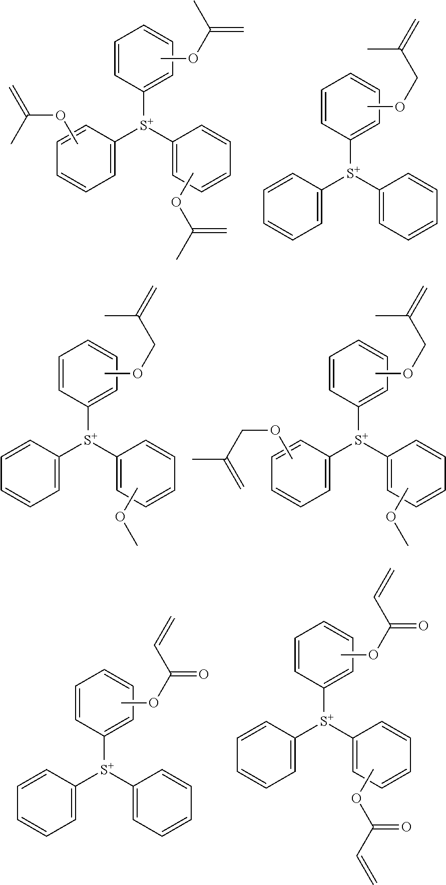

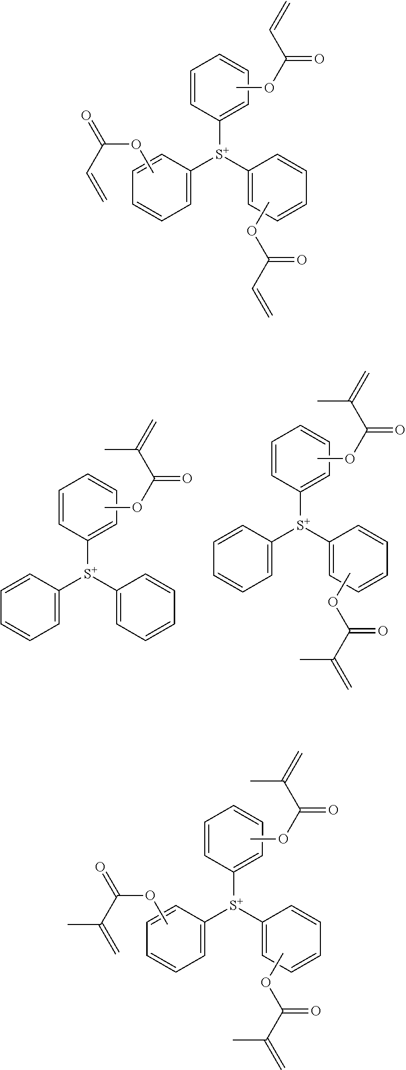

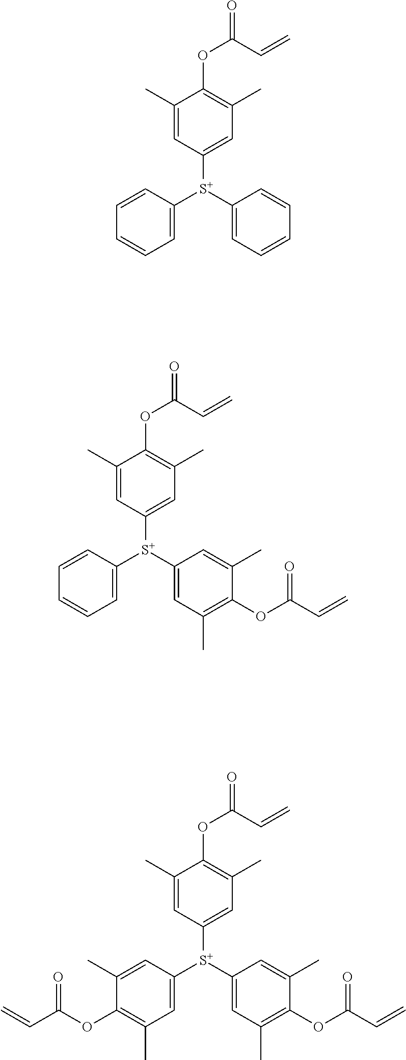

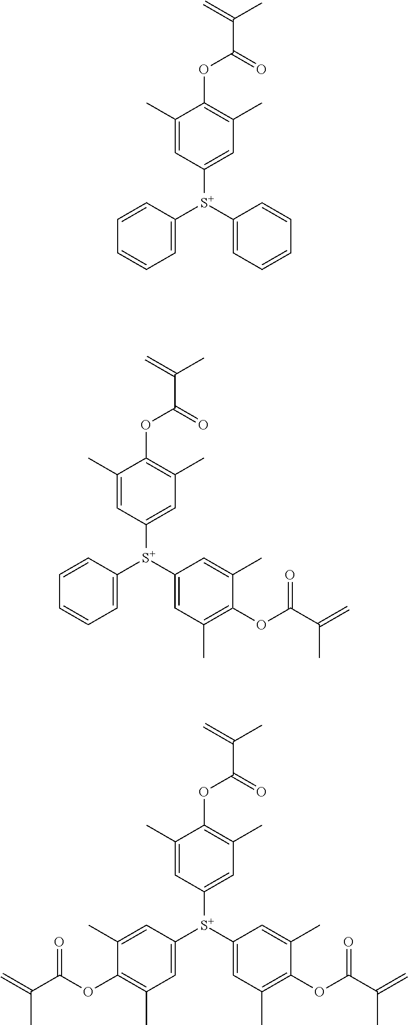

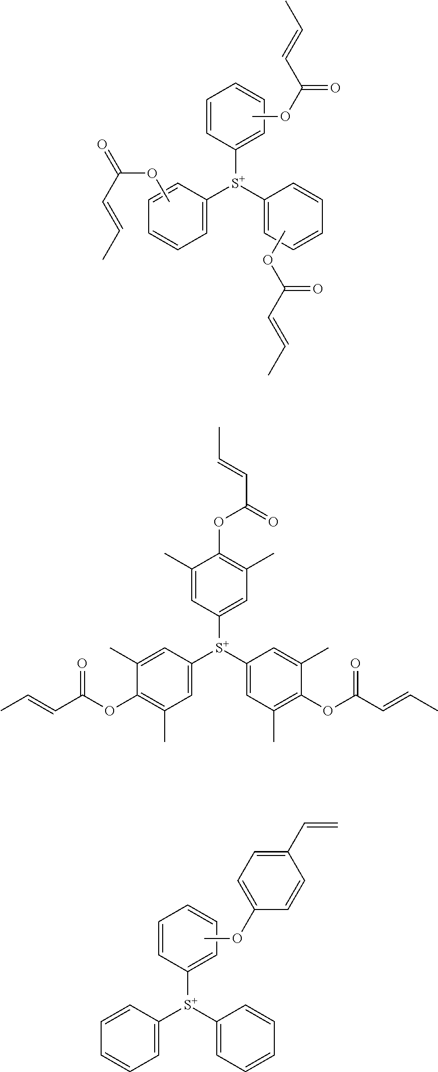

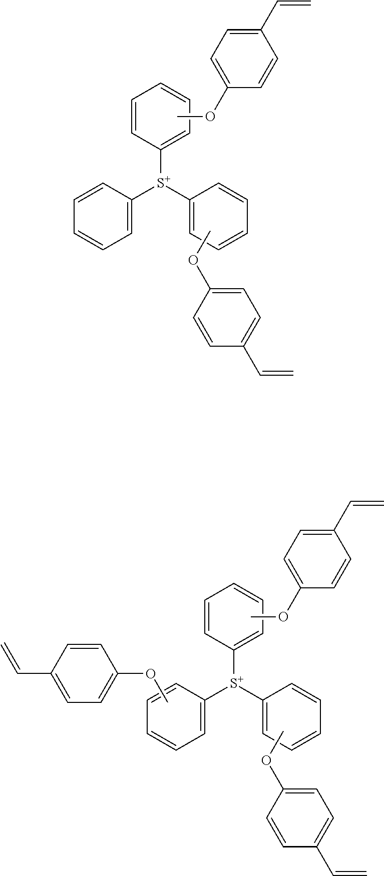

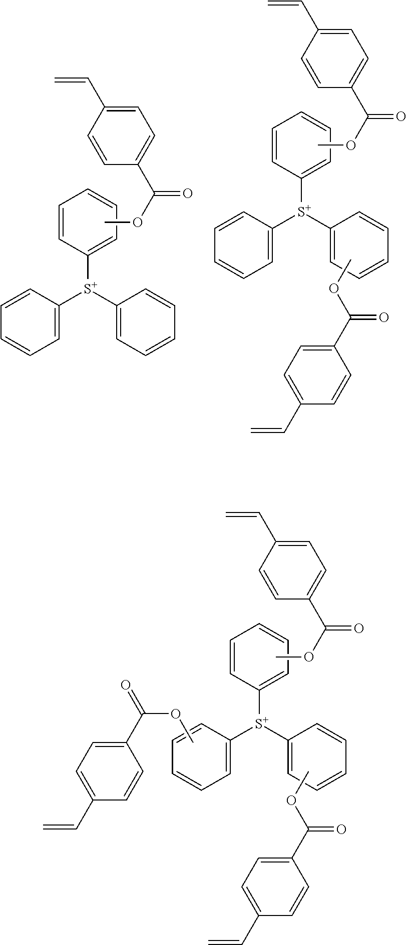

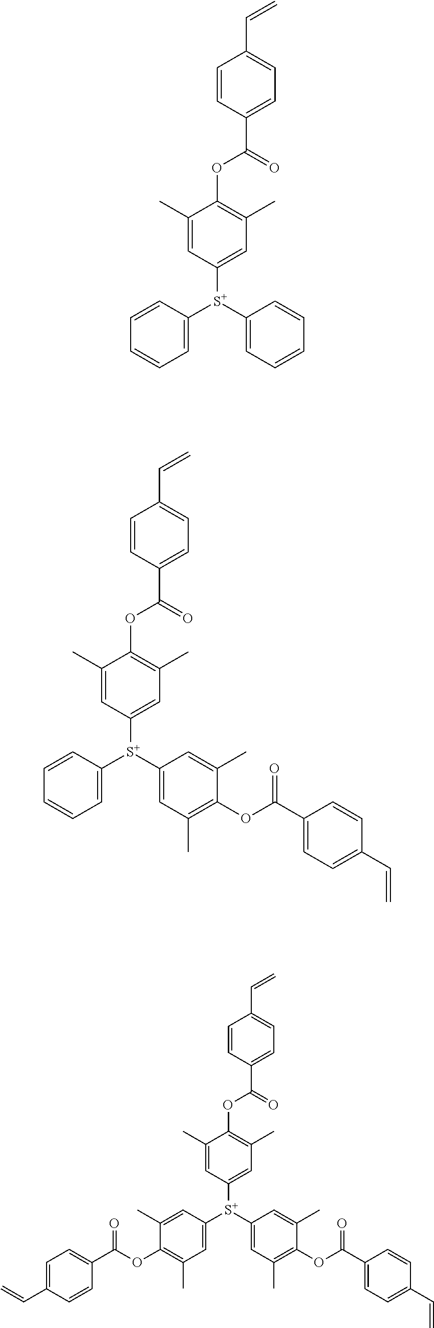

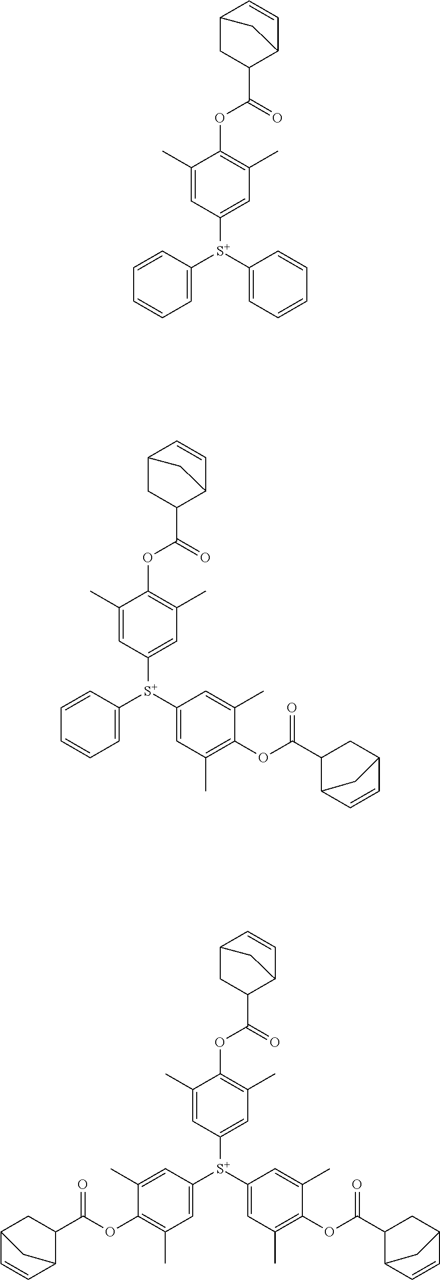 [SMILES: Cc1cc([S+](c2ccccc2)c2ccccc2)cc(C)c1OC(=O)C1CC2C=CC1C2 ; Cc1cc([S+](c2ccccc2)c2cc(C)c(OC(=O)C3CC4C=CC3C4)c(C)c2)cc(C)c1OC(=O)C1CC2C=CC1C2 ; Cc1cc([S+](c2cc(C)c(OC(=O)C3CC4C=CC3C4)c(C)c2)c2cc(C)c(OC(=O)C3CC4C=CC3C4)c(C)c2)cc(C)c1OC(=O)C1CC2C=CC1C2]

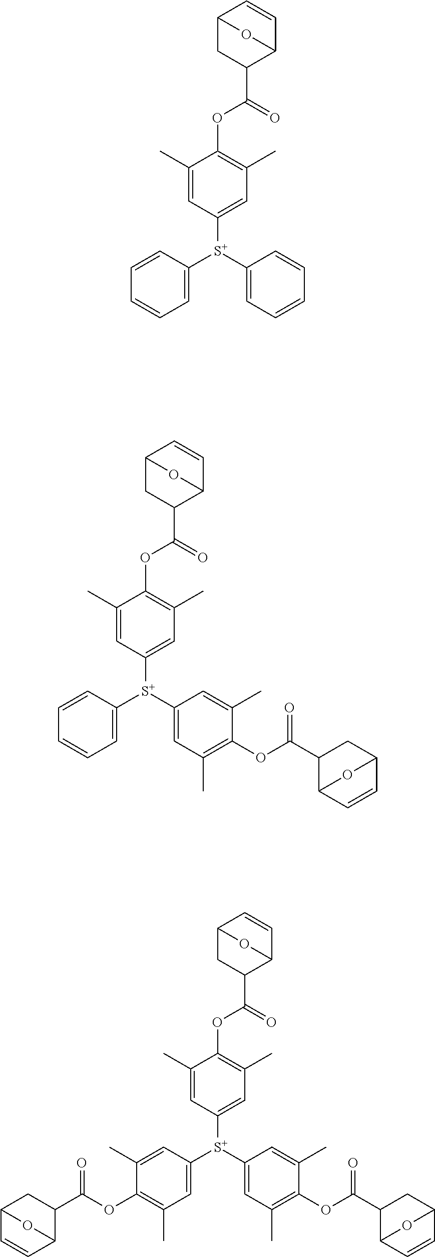 [SMILES: Cc1cc([S+](c2ccccc2)c2ccccc2)cc(C)c1OC(=O)C1CC2C=CC1O2 ; Cc1cc([S+](c2ccccc2)c2cc(C)c(OC(=O)C3CC4C=CC3O4)c(C)c2)cc(C)c1OC(=O)C1CC2C=CC1O2 ; Cc1cc([S+](c2cc(C)c(OC(=O)C3CC4C=CC3O4)c(C)c2)c2cc(C)c(OC(=O)C3CC4C=CC3O4)c(C)c2)cc(C)c1OC(=O)C1CC2C=CC1O2]

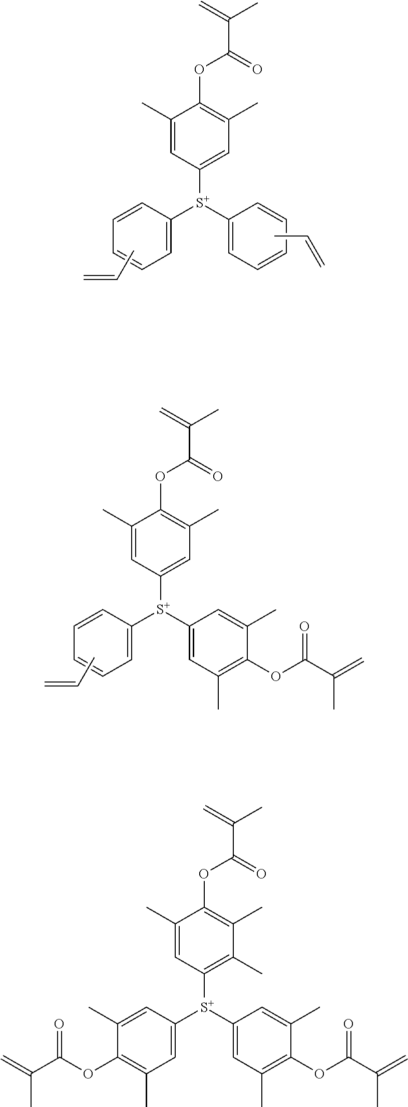

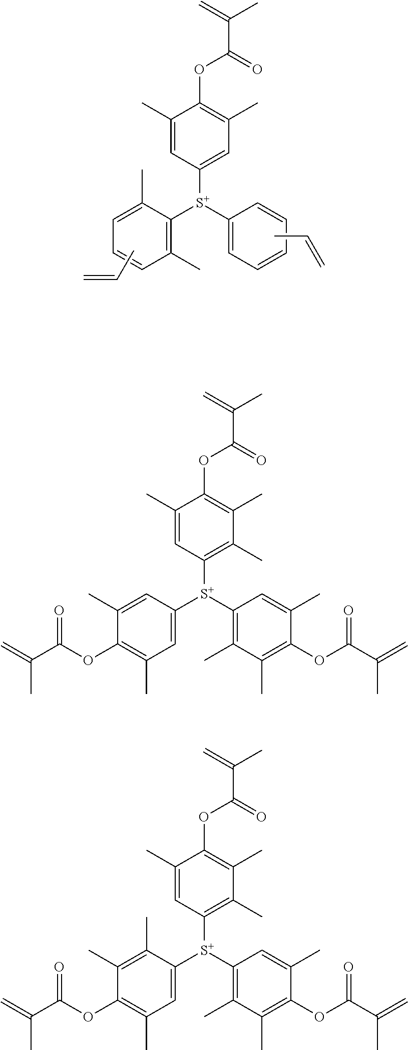

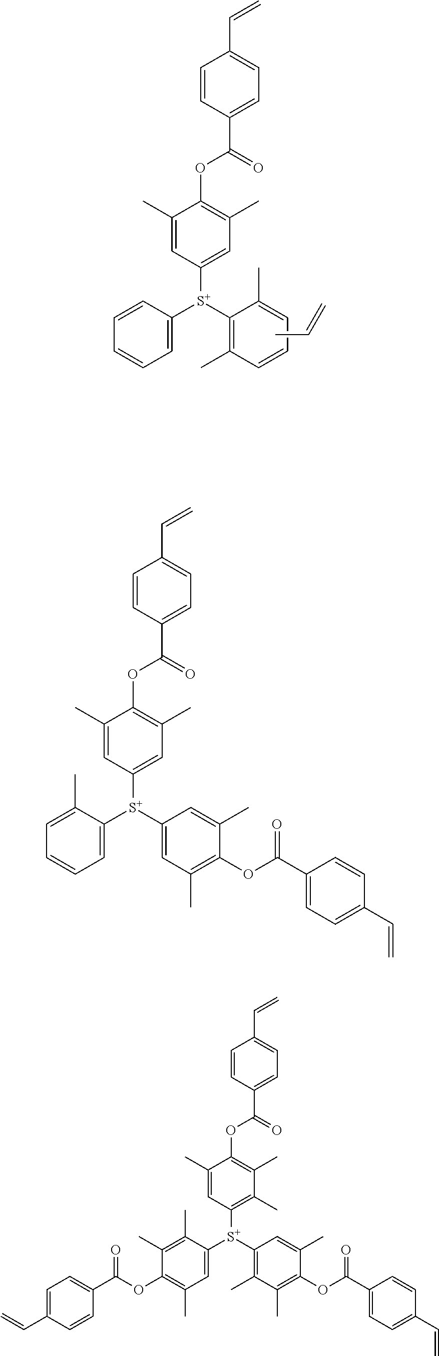

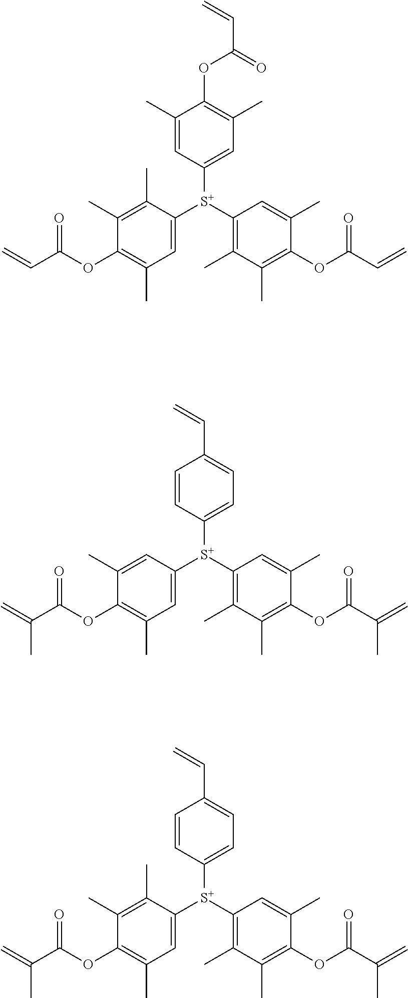

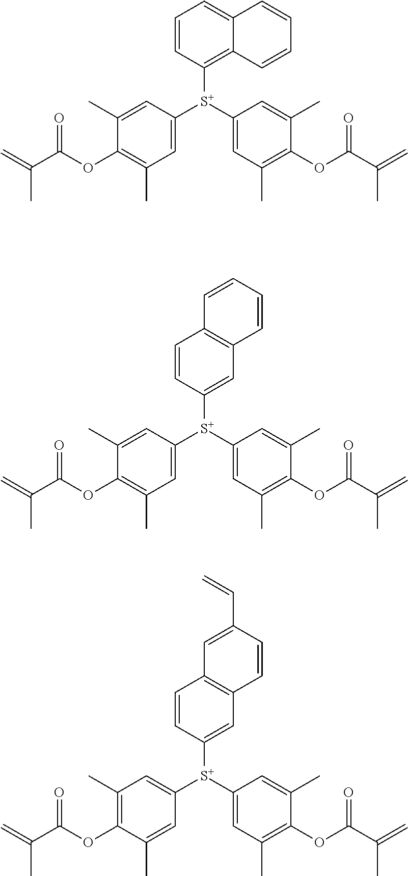

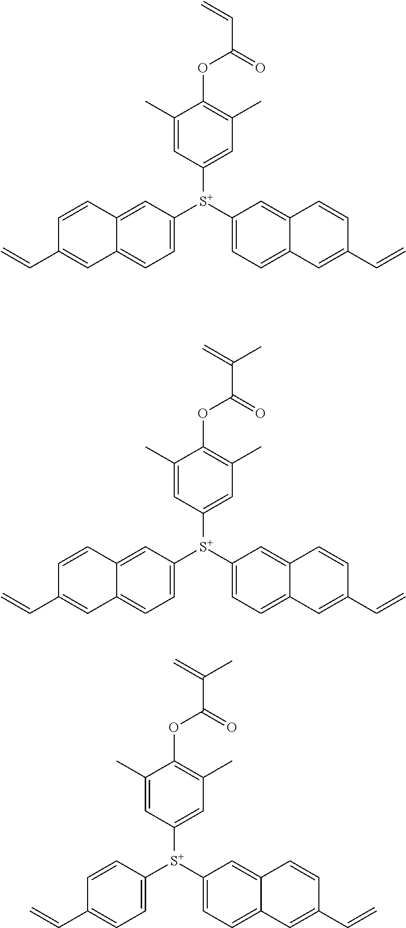

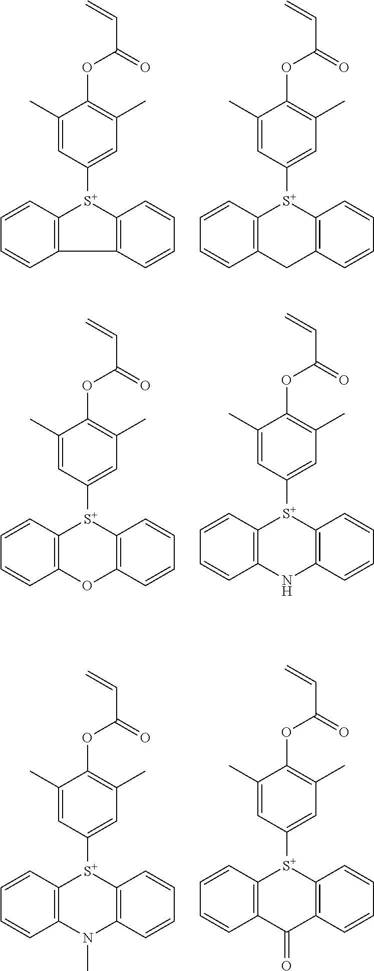 [SMILES: C=CC(=O)Oc1c(C)cc(-[s+]2c3ccccc3c3ccccc32)cc1C ; C=CC(=O)Oc1c(C)cc([S+]2c3ccccc3Cc3ccccc32)cc1C ; C=CC(=O)Oc1c(C)cc([S+]2c3ccccc3Oc3ccccc32)cc1C ; C=CC(=O)Oc1c(C)cc([S+]2c3ccccc3Nc3ccccc32)cc1C ; C=CC(=O)Oc1c(C)cc([S+]2c3ccccc3N(C)c3ccccc32)cc1C ; C=CC(=O)Oc1c(C)cc(-[s+]2c3ccccc3c(=O)c3ccccc32)cc1C]

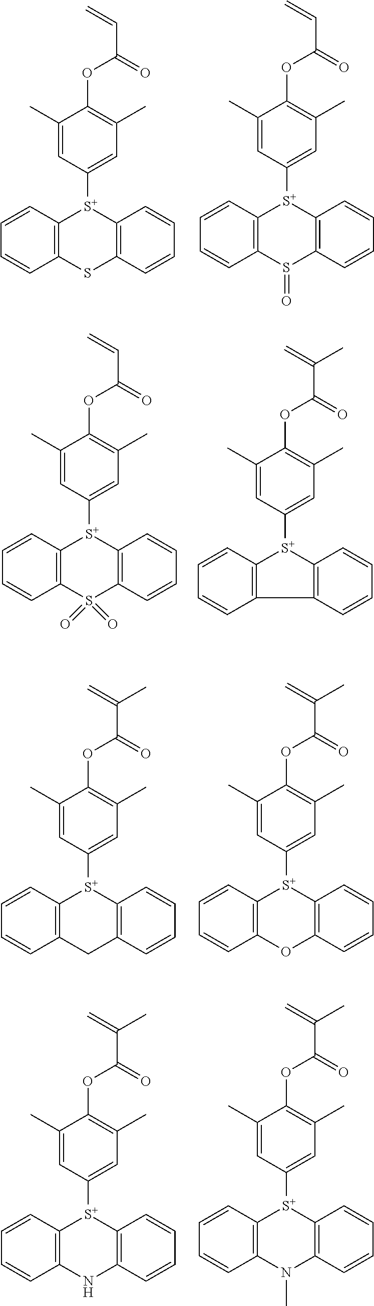

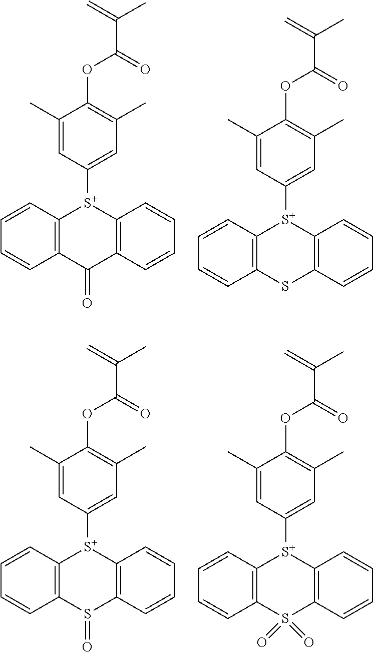 [SMILES: C=C(C)C(=O)Oc1c(C)cc(-[s+]2c3ccccc3c(=O)c3ccccc32)cc1C ; C=C(C)C(=O)Oc1c(C)cc([S+]2c3ccccc3Sc3ccccc32)cc1C ; C=C(C)C(=O)Oc1c(C)cc([S+]2c3ccccc3S(=O)c3ccccc32)cc1C ; C=C(C)C(=O)Oc1c(C)cc([S+]2c3ccccc3S(=O)(=O)c3ccccc32)cc1C]

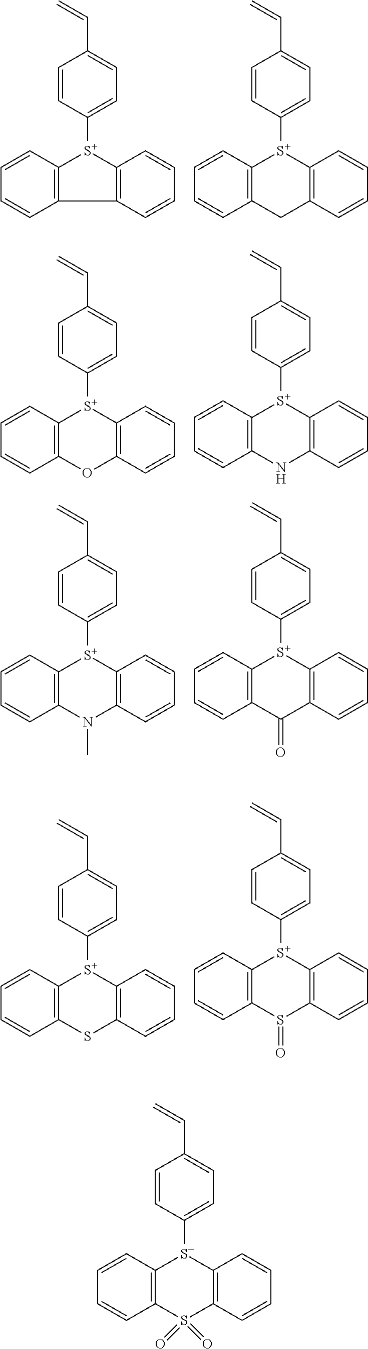

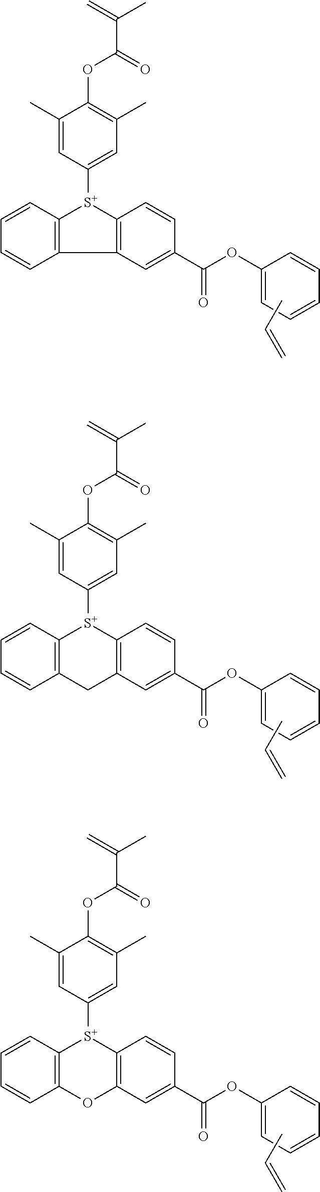

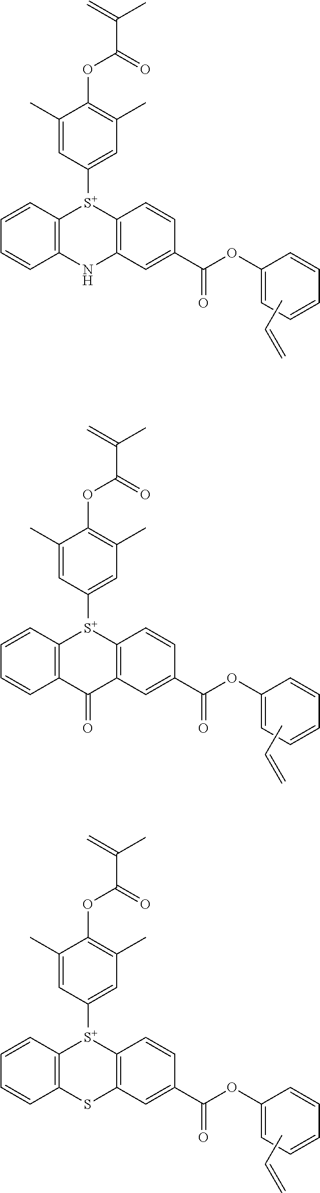

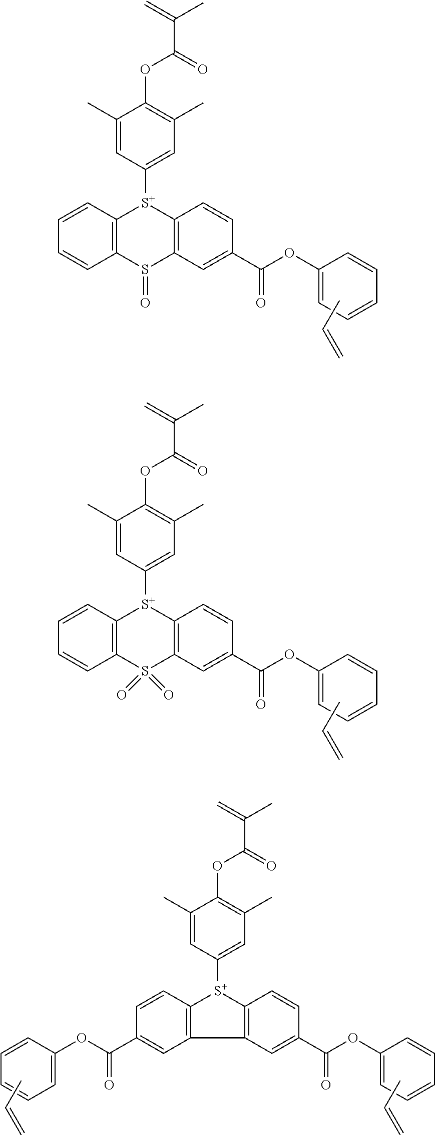

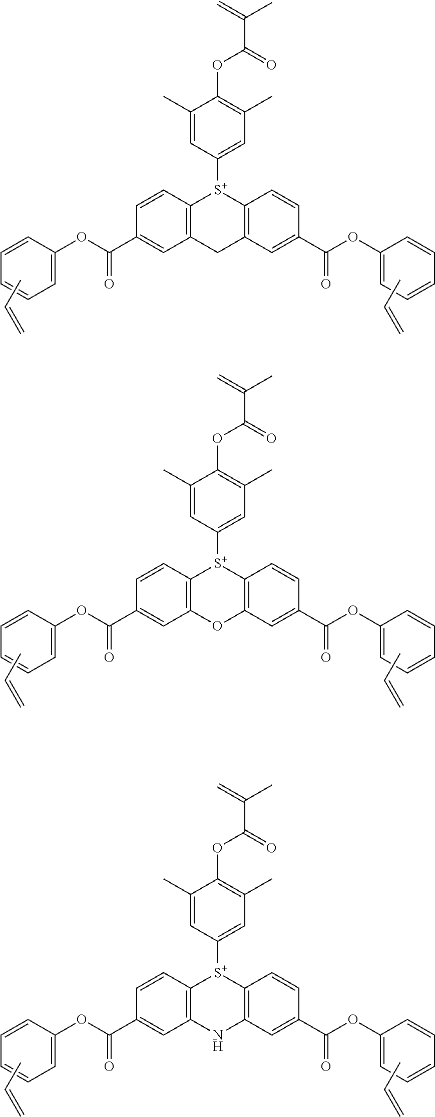

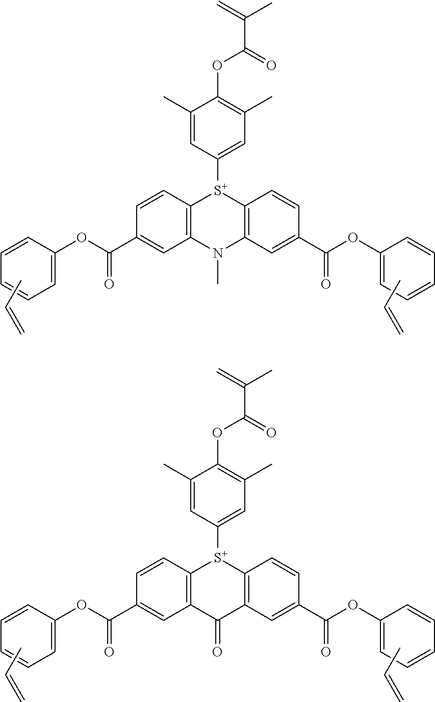

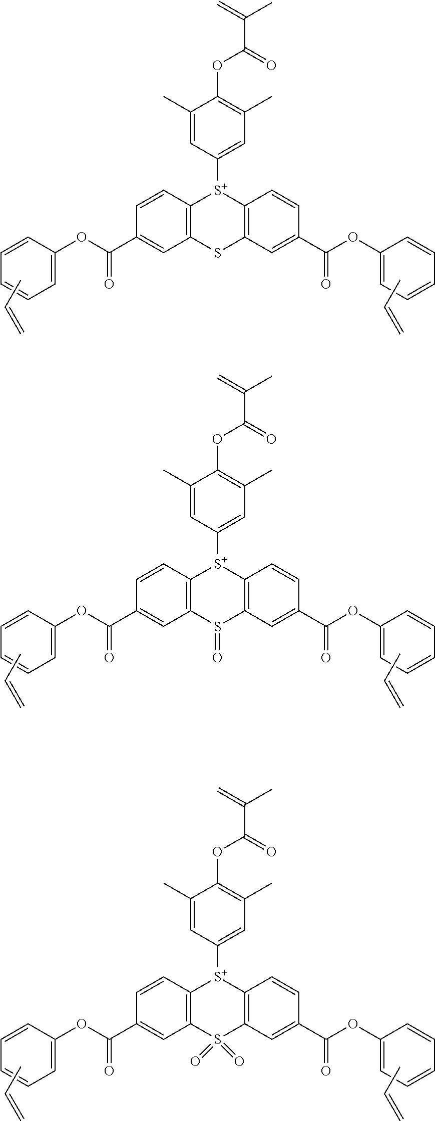

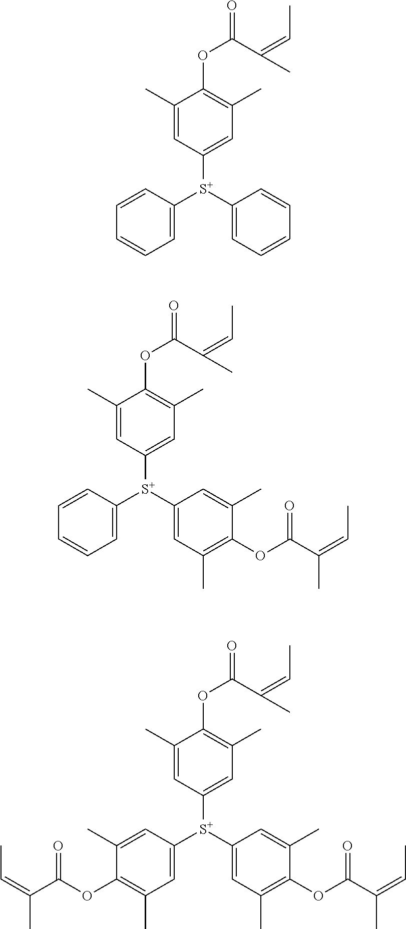 [SMILES: C/C=C(/C)C(=O)Oc1c(C)cc([S+](c2ccccc2)c2ccccc2)cc1C ; C/C=C(/C)C(=O)Oc1c(C)cc([S+](c2ccccc2)c2cc(C)c(OC(=O)/C(C)=C\C)c(C)c2)cc1C ; C/C=C(/C)C(=O)Oc1c(C)cc([S+](c2cc(C)c(OC(=O)/C(C)=C\C)c(C)c2)c2cc(C)c(OC(=O)/C(C)=C\C)c(C)c2)cc1C]

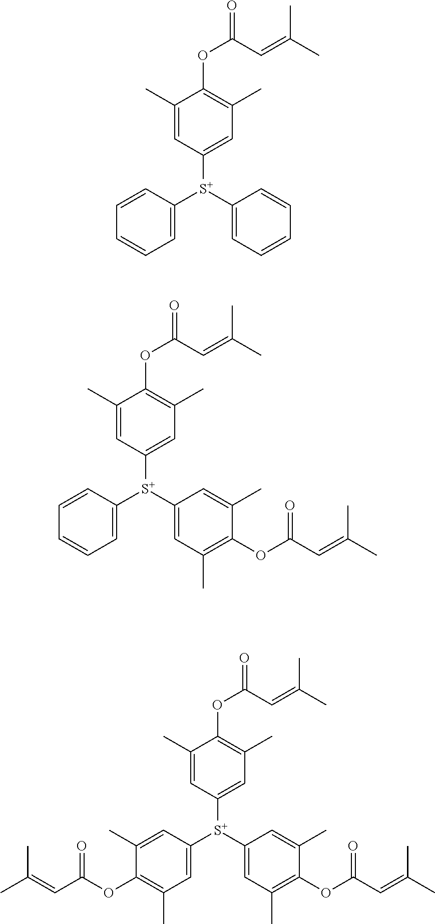

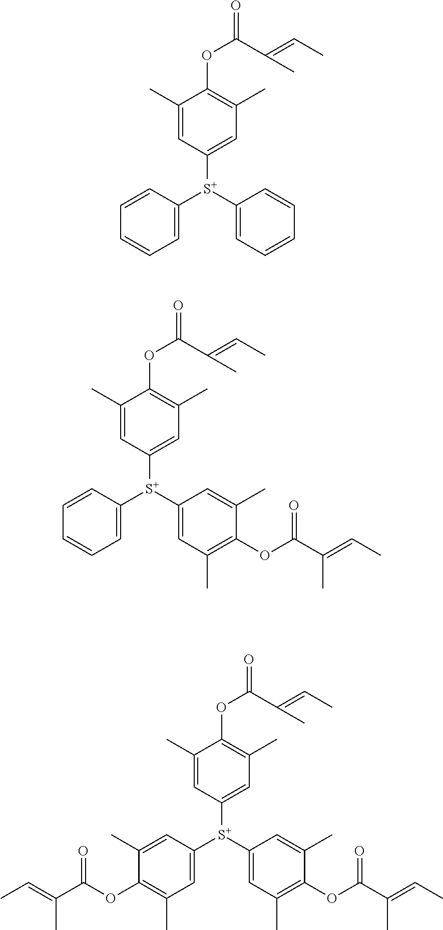

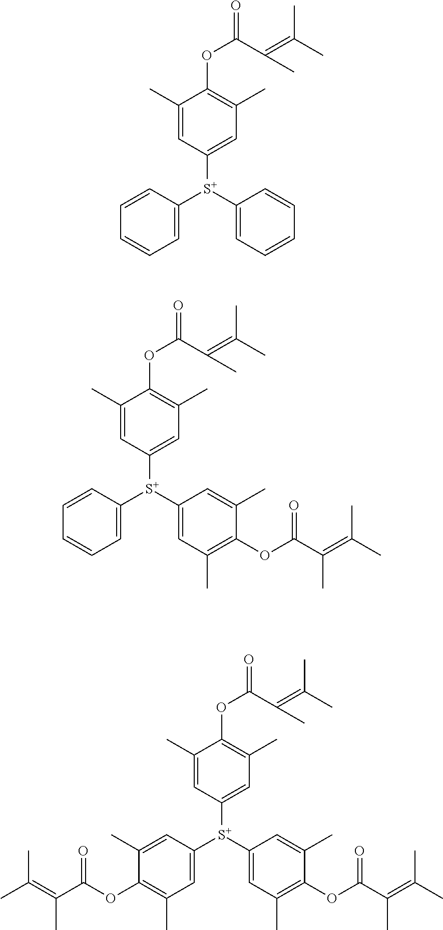

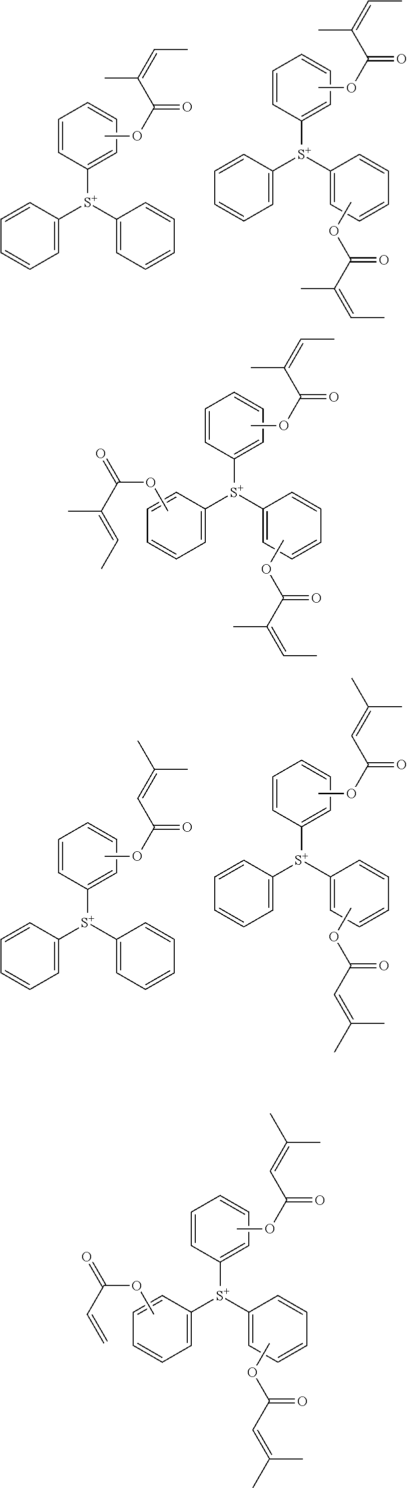

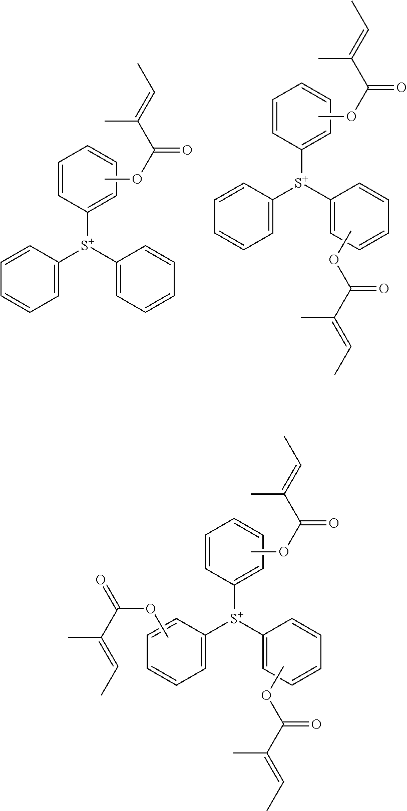

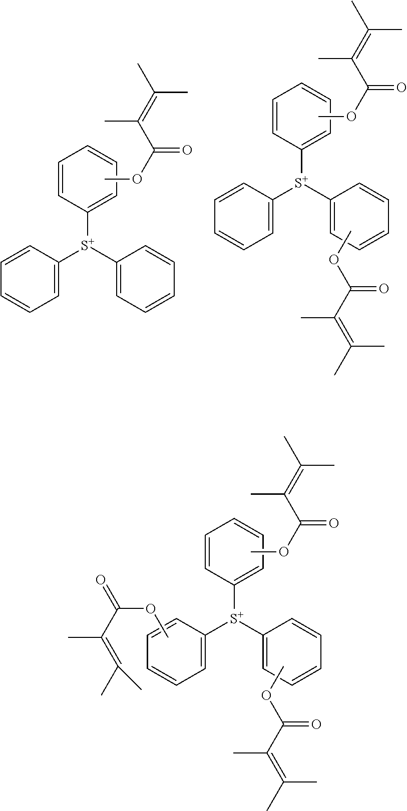

Specific examples of the cation of the sulfonium salt represented by formula (2) include, but are not limited to, those shown below.

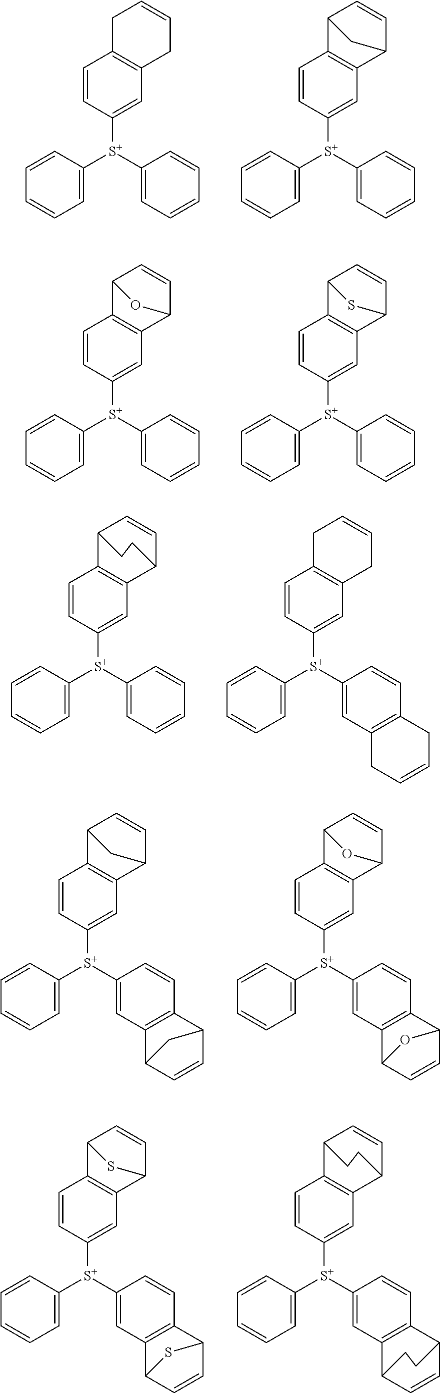

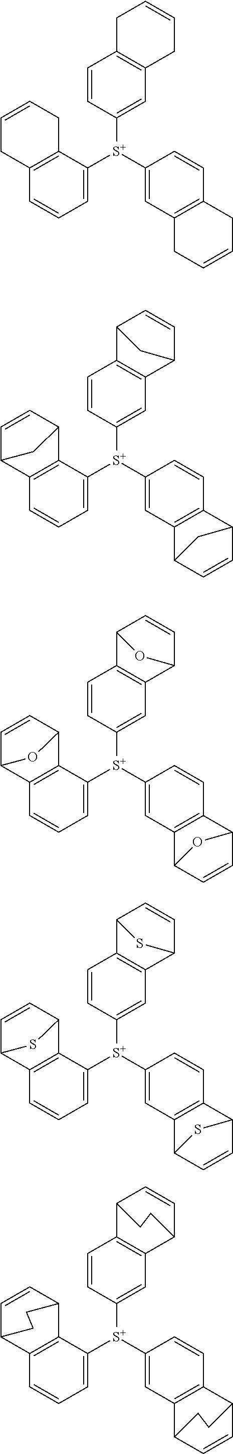 [SMILES: C1=CCc2cc([S+](c3ccc4c(c3)CC=CC4)c3cccc4c3CC=CC4)ccc2C1 ; C1=CC2CC1c1ccc([S+](c3ccc4c(c3)C3C=CC4C3)c3cccc4c3C3C=CC4C3)cc12 ; C1=CC2OC1c1ccc([S+](c3ccc4c(c3)C3C=CC4O3)c3cccc4c3C3C=CC4O3)cc12 ; C1=CC2SC1c1ccc([S+](c3ccc4c(c3)C3C=CC4S3)c3cccc4c3C3C=CC4S3)cc12 ; C1=CC2CCC1c1ccc([S+](c3ccc4c(c3)C3C=CC4CC3)c3cccc4c3C3C=CC4CC3)cc12]

In formulae (1) and (2), X⁻ is a counter anion. The counter anion is not particularly limited, but may be a non-nucleophilic anion. Preferred examples of the counter anion include a halide ion, a nitrate ion, a hydrogensulfate ion, a hydrogencarbonate ion, a tetraphenylborate ion, or an anion represented by any of formulae (1-2) to (1-8).

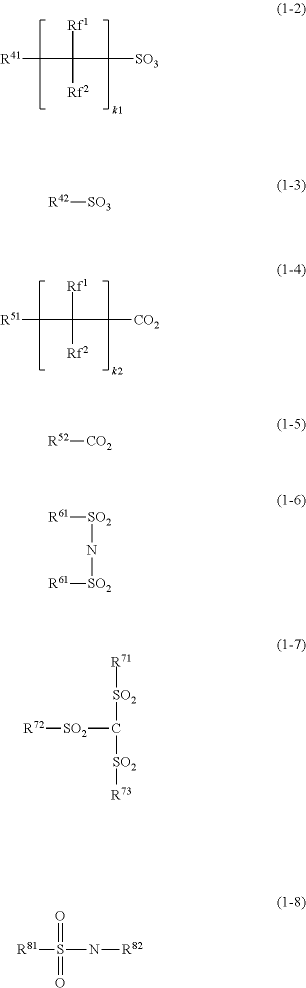

In formulae (1-2) and (1-4), k₁ and k₂ are each independently an integer of 1 to 4 (i.e., 1, 2, 3, or 4). Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time.

In formula (1-2), R⁴¹ is a hydrogen atom, a halogen atom, a hydroxy group, or a hydrocarbyl group having 1 to 50, preferably 1 to 40 carbon atoms and optionally containing a hetero atom.

In formula (1-3), R⁴² is a hydrogen atom, a halogen atom, a hydroxy group, or a hydrocarbyl group having 1 to 50, preferably 1 to 40 carbon atoms and optionally containing a hetero atom. However, those in which hydrogen on the α- or β-position carbon atoms of the sulfo group are substituted with a fluorine atom or a fluoroalkyl group are excluded.

In formula (1-4), R⁵¹ is a hydrogen atom, a halogen atom, a hydroxy group, or a hydrocarbyl group having 1 to 50, preferably 1 to 40 carbon atoms and optionally containing a hetero atom.

In Formula (1-5), R⁵² is a hydrogen atom, a halogen atom, a hydroxy group, or a hydrocarbyl group having 1 to 50, preferably 1 to 40 carbon atoms and optionally containing a hetero atom. However, those in which hydrogen on the α- or β-position carbon atoms of the carboxy group are substituted with a fluorine atom or a fluoroalkyl group are excluded.

In Formula (1-6), R⁶¹ and R⁶² are each independently a hydrocarbyl group having 1 to 50, preferably 1 to 40 carbon atoms and optionally containing a hetero atom.

In Formula (1-7), R⁷¹ to R⁷³ are each independently a hydrocarbyl group having 1 to 50, preferably 1 to 40 carbon atoms and optionally containing a hetero atom.

In formula (1-8), R⁸¹ is a fluorine atom or a fluorinated hydrocarbyl group having 1 to 10 carbon atoms, and the fluorinated hydrocarbyl group optionally contains a hydroxy group, an ether bond, or an ester bond. R⁸² is a hydrogen atom or a hydrocarbyl group having 1 to 20 carbon atoms, and the hydrocarbyl group optionally contains a hydroxy group, an ether bond, or an ester bond. Further, R⁸¹ and R⁸² are optionally bonded to each other to form a ring together with the atoms to which they are bonded.

Among the anions represented by X⁻, a halide ion, a nitrate ion, or an anion represented by any of formulae (1-2) to (1-8) is more preferred, and a halide ion, a nitrate ion, or an anion represented by formula (1-3), (1-5), or (1-7) is still more preferred.

The hydrocarbyl groups having 1 to 50 carbon atoms represented by R⁴¹, R⁴², R⁵¹, R⁵², R⁶¹, R⁶², R⁷¹, R⁷², and R⁷³ may be saturated or unsaturated, and may be linear, branched, or cyclic. Specific examples thereof include alkyl groups having 1 to 50 carbon atoms, such as methyl group, ethyl group, propyl group, isopropyl group, n-butyl group, sec-butyl group, tert-butyl group, tert-pentyl group, n-pentyl group, n-hexyl group, n-octyl group, 2-ethylhexyl group, n-nonyl group, and n-decyl group; cyclic saturated hydrocarbyl groups having 3 to 50 carbon atoms, such as cyclopentyl group, cyclohexyl group, cyclopentylmethyl group, cyclopentylethyl group, cyclopentylbutyl group, cyclohexylmethyl group, cyclohexylethyl group, cyclohexylbutyl group, norbornyl group, tricyclo[5.2.1.0^{2,6}]decyl group, and adamantyl group, adamantylmethyl group; and aryl groups having 6 to 50 carbon atoms, such as phenyl group, naphthyl group, and anthracenyl group; and groups obtained by combining any of these, and the like. In addition, some or all of the hydrogen atoms of the above hydrocarbyl group are optionally substituted with a group containing a hetero atom such as an oxygen atom, a sulfur atom, a nitrogen atom, or a halogen atom, and some of the —CH₂— groups constituting the hydrocarbyl group are optionally substituted with a group containing a hetero atom such as an oxygen atom, a sulfur atom, or a nitrogen atom, and as a result, the hydrocarbyl group may contain a hydroxy group, a cyano group, a halogen atom, a carbonyl group, an ether bond, a thioether bond, an ester bond, a sulfonate ester bond, a carbonate bond, a carbamate bond, a lactone ring, a sultone ring, or a carboxylic acid anhydride group (—C(═O)—O—C(═O)—).

The fluorinated hydrocarbyl group having 1 to 10 carbon atoms represented by R⁸¹ is a group in which some or all of the hydrogen atoms of a hydrocarbyl group having 1 to 10 carbon atoms are substituted with fluorine atoms. The hydrocarbyl group having 1 to 10 carbon atoms may be saturated or unsaturated, and may be linear, branched, or cyclic. Specific examples thereof include those having 1 to 10 carbon atoms among the hydrocarbyl groups having 1 to 50 carbon atoms exemplified as the groups represented by R⁴¹, R⁴², R⁵¹, R⁵², R⁶¹, R⁶², R⁷¹, R⁷², and R⁷³.

The hydrocarbyl group having 1 to 20 carbon atoms represented by R⁸² may be saturated or unsaturated, and may be linear, branched, or cyclic. Specific examples thereof include those having 1 to 20 carbon atoms among the hydrocarbyl groups having 1 to 50 carbon atoms exemplified as the groups represented by R⁴¹, R⁴², R⁵¹, R⁵², R⁶¹, R⁶², R⁷¹, R⁷², and R⁷³.

It is preferable that the anion represented by any of formulae (1-2) to (1-8) contains a polymerizable functional group, and the anion may contain a hydrocarbyl group having 2 to 20 carbon atoms that contains a polymerizable functional group or may contain a hetero atom, in structure of the anion. Specific examples thereof include those similar to the group exemplified as a group represented by A¹ in formula (1).

Examples of the anion represented by formula (1-2) include, but are not limited to, those shown below. In the following formulae, Ac represents an acetyl group, and Rf¹ is the same as described above.

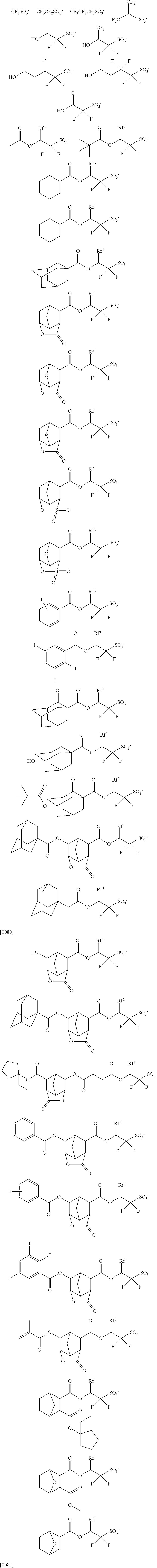

[chemical structure]

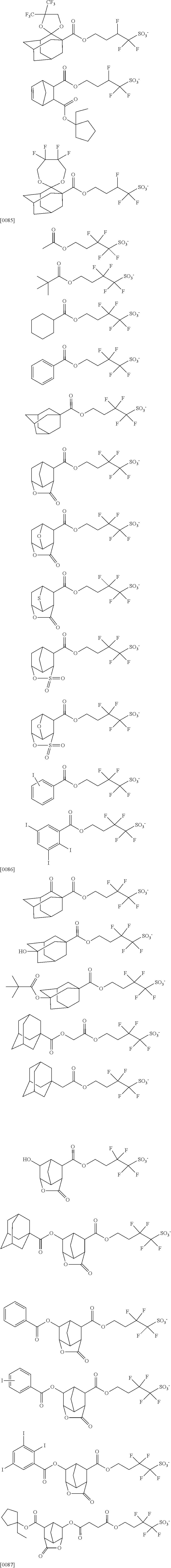

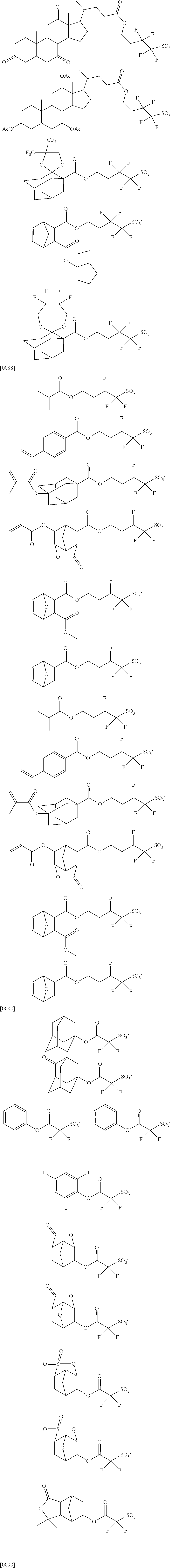

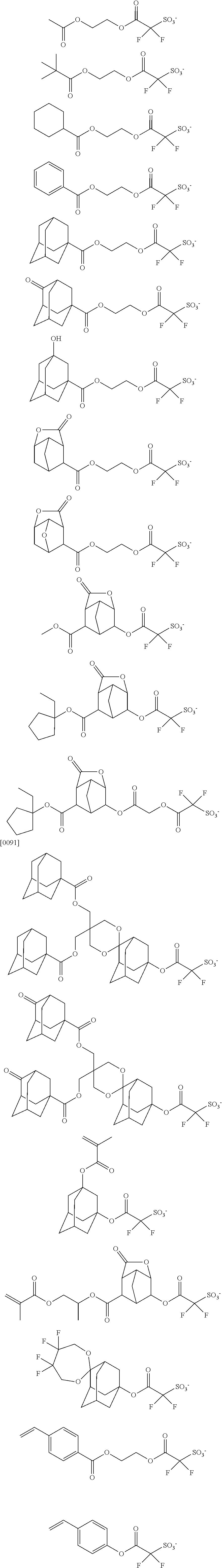

Examples of the anion represented by formula (1-3) include, but are not limited to, those shown below.

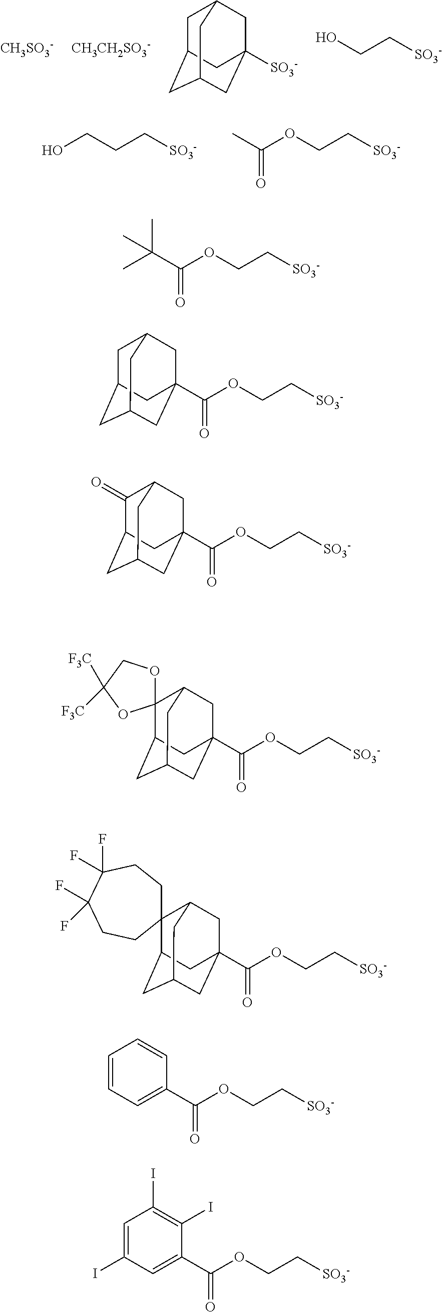

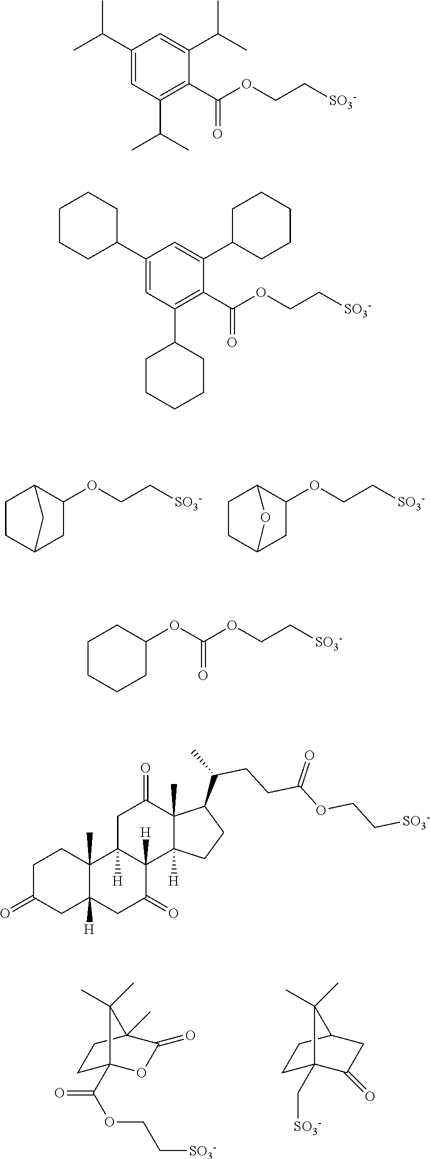

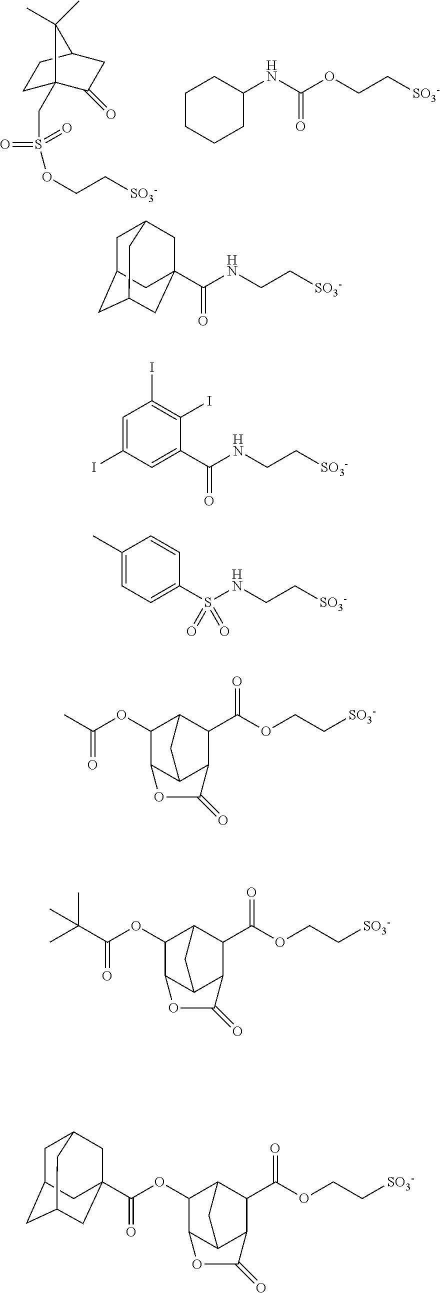

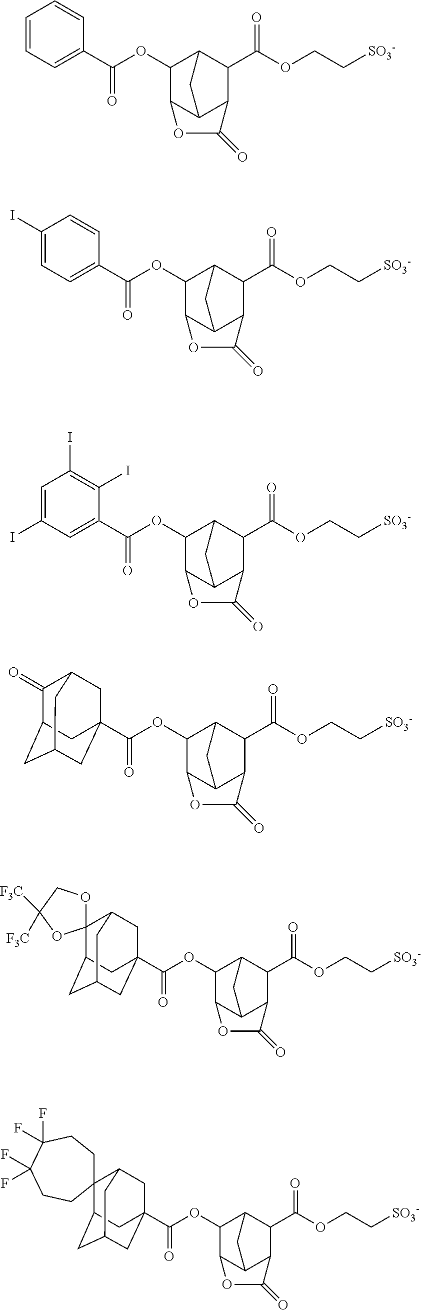

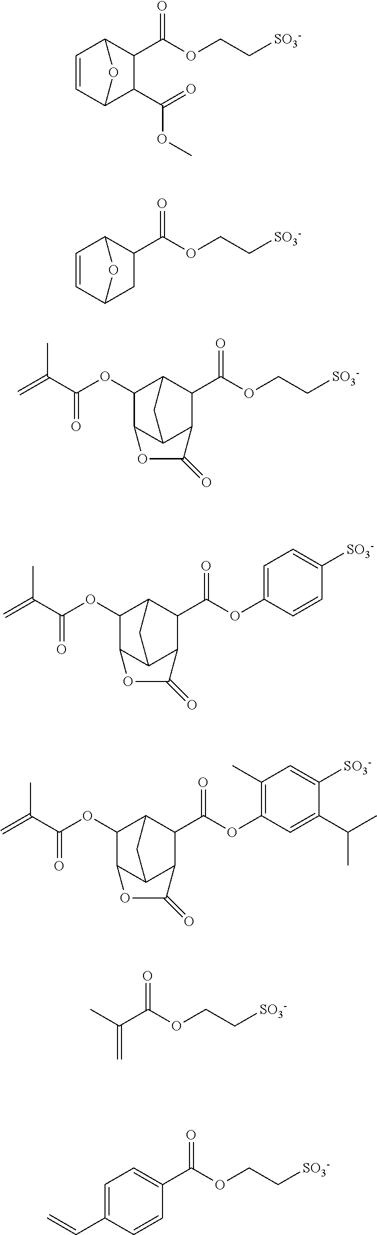

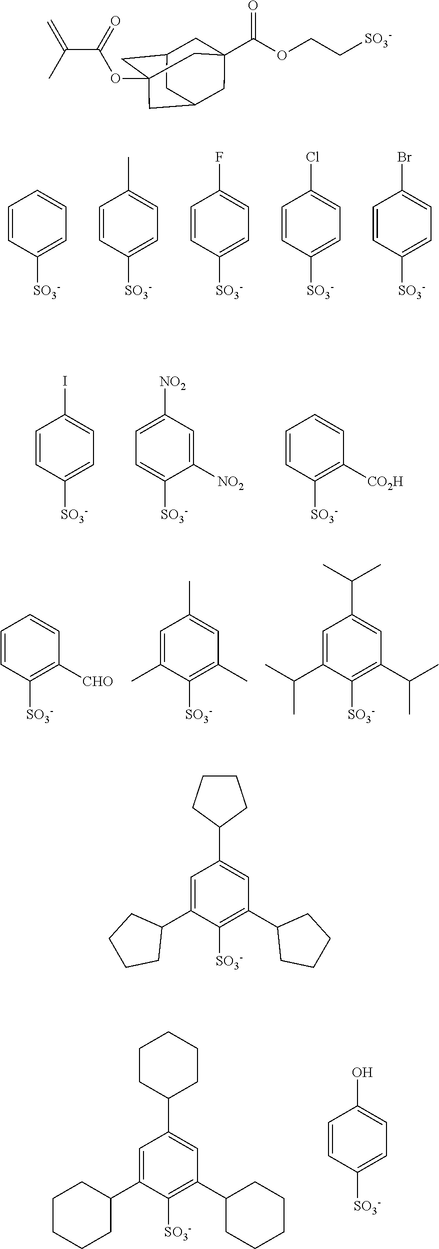

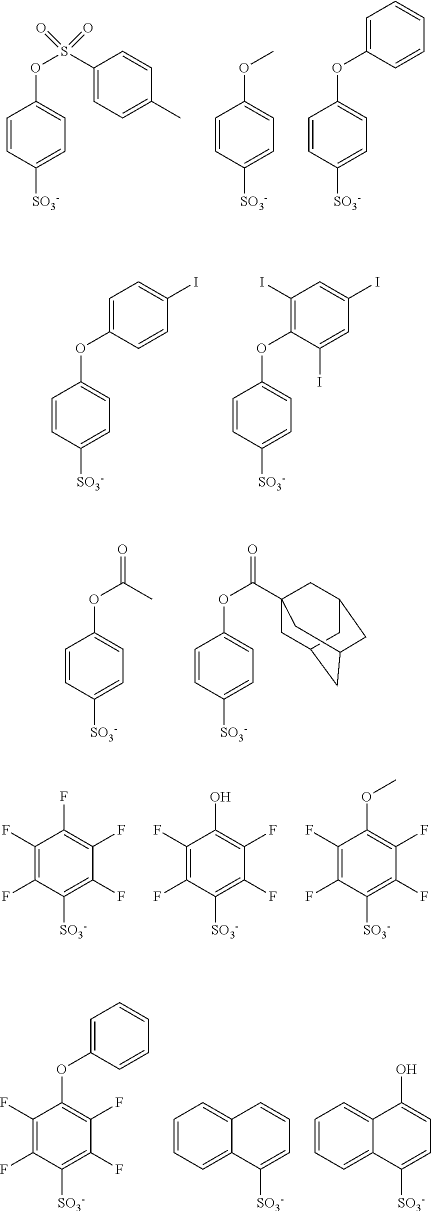

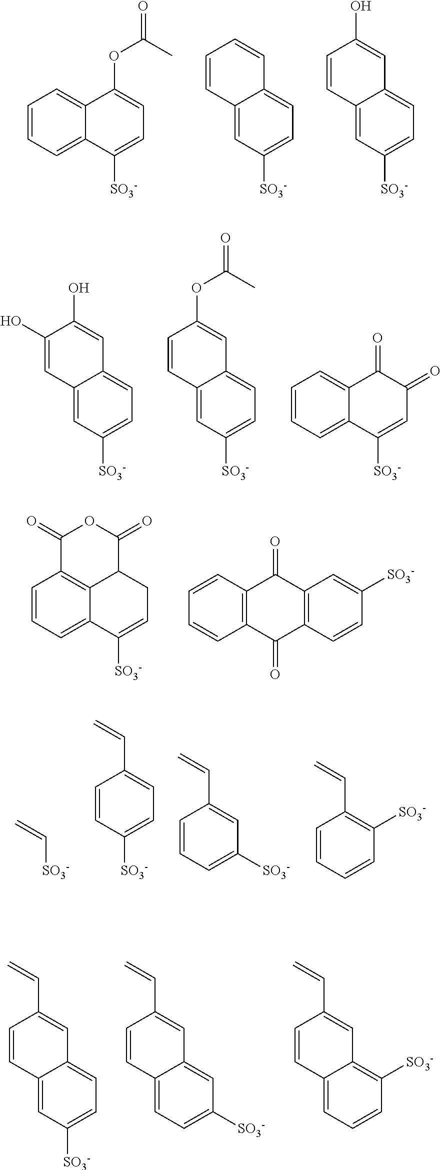

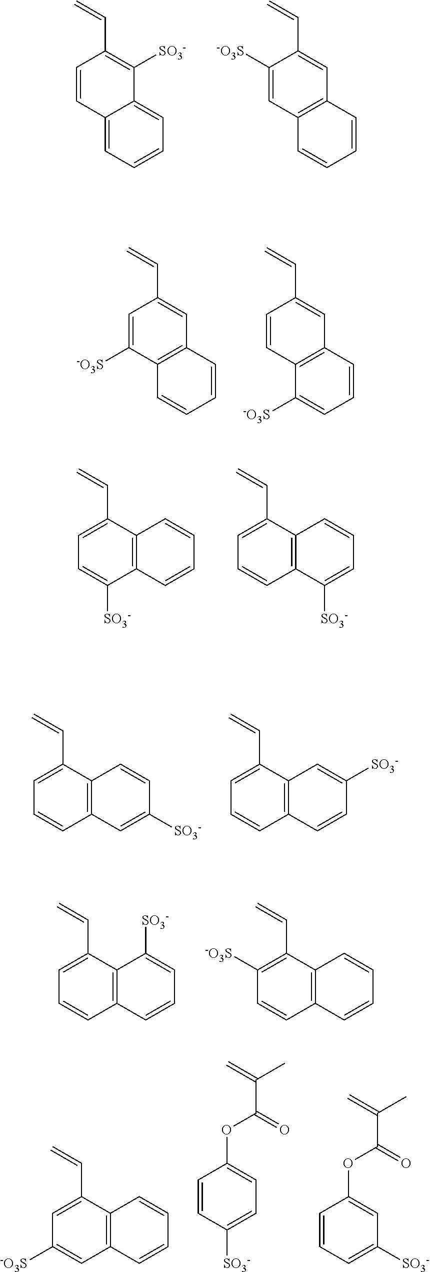

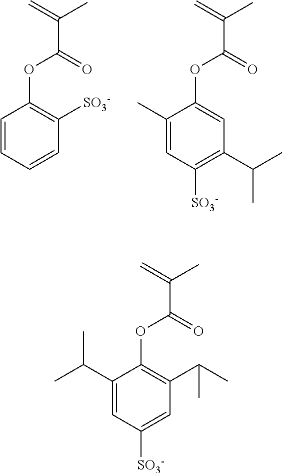

Examples of the anion represented by formula (1-4) include, but are not limited to, those shown below.

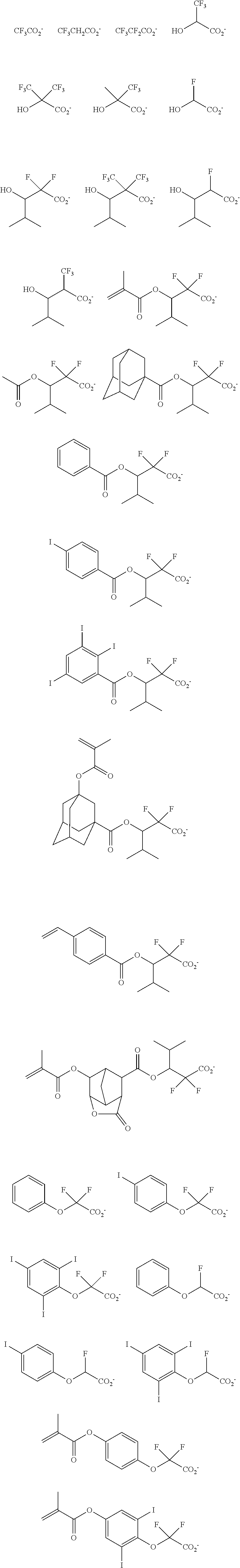

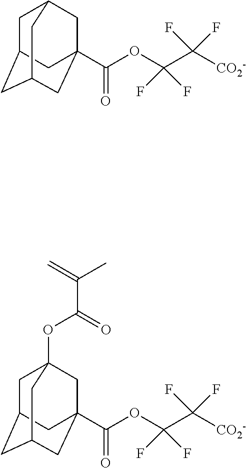

Examples of the anion represented by formula (1-5) include, but are not limited to, those shown below.

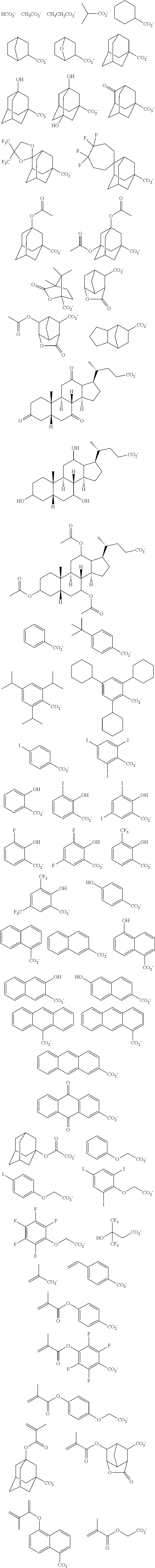

Examples of the anion represented by formula (1-6) include, but are not limited to, those shown below.

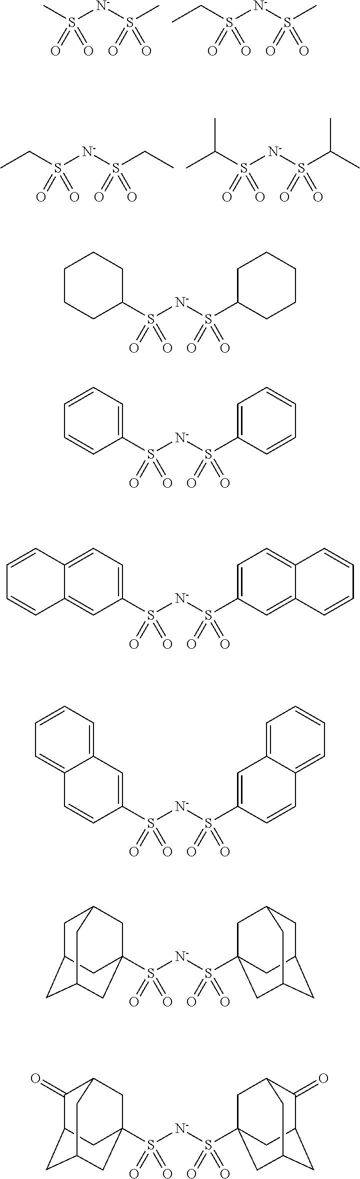

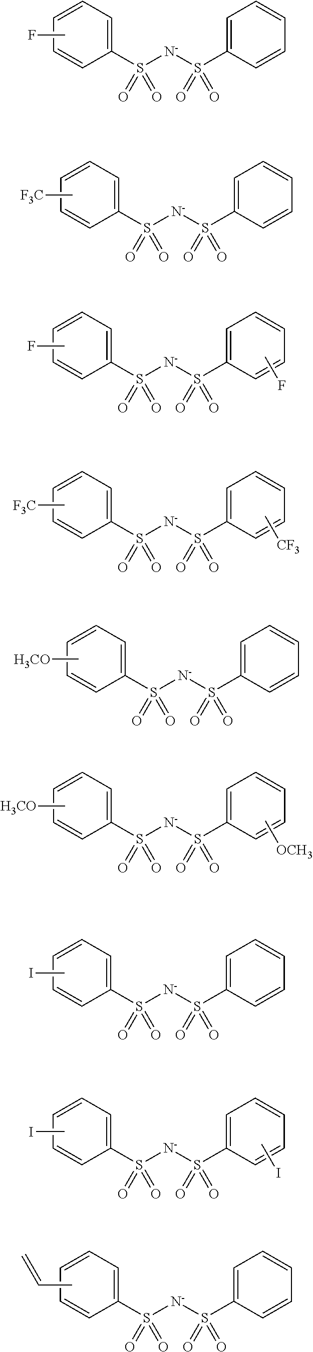

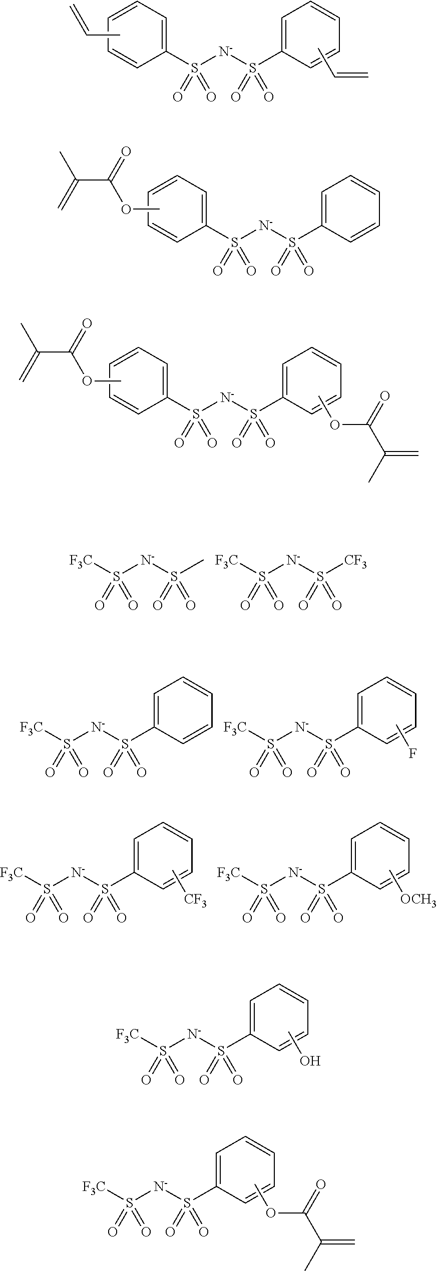

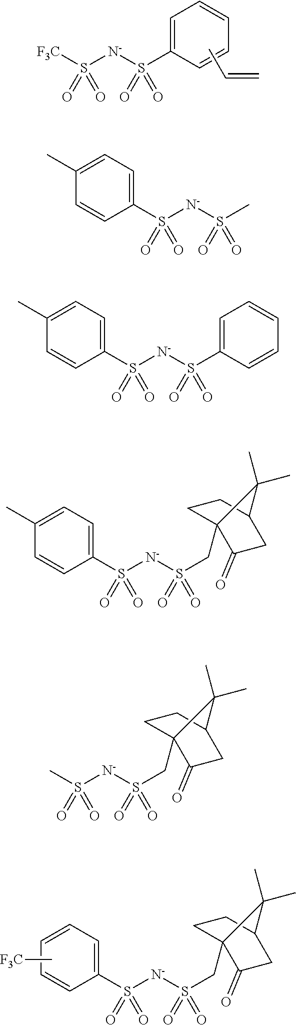

Examples of the anion represented by formula (1-7) include, but are not limited to, those shown below.

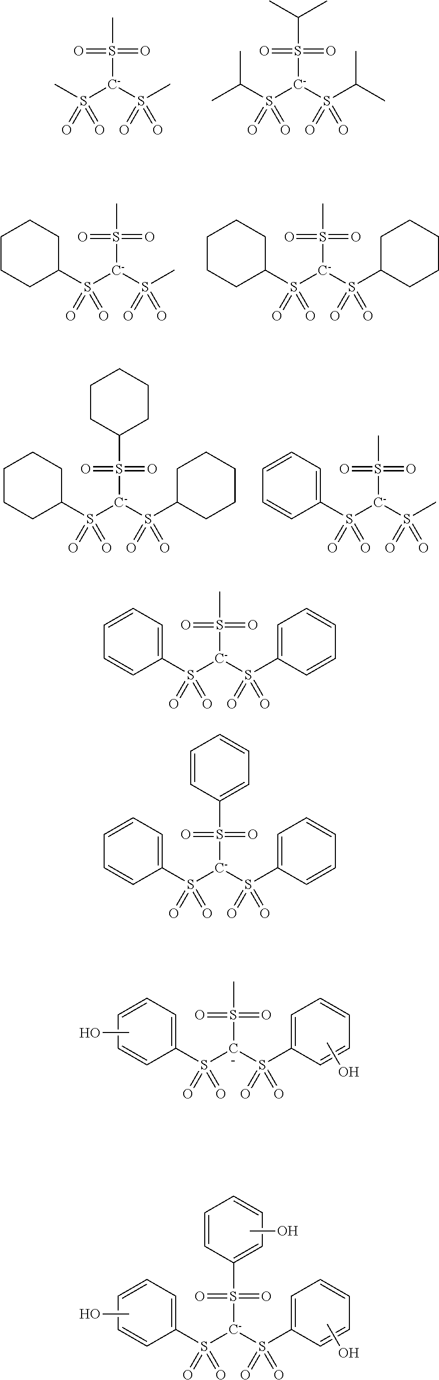

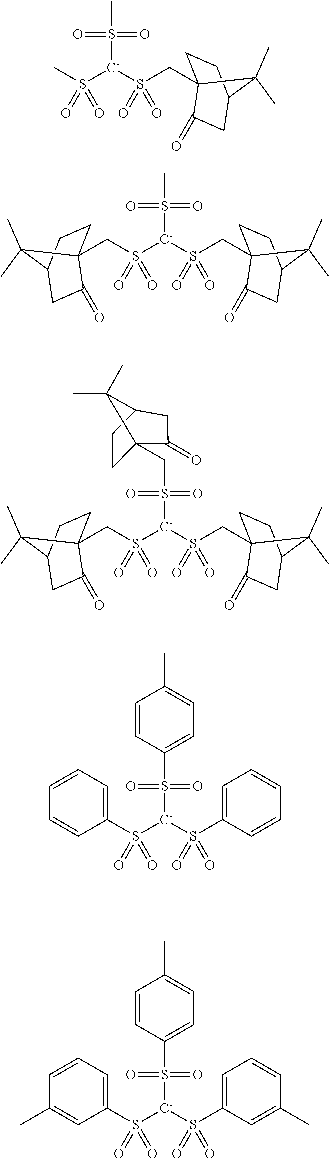

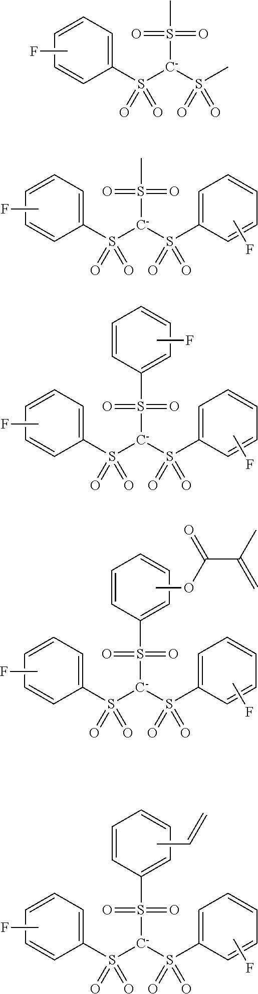

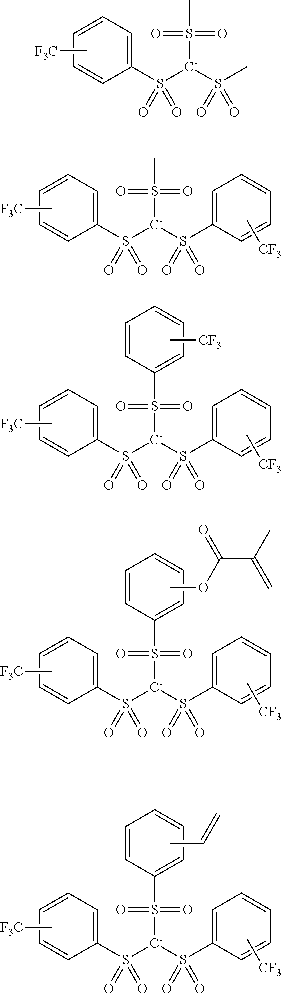

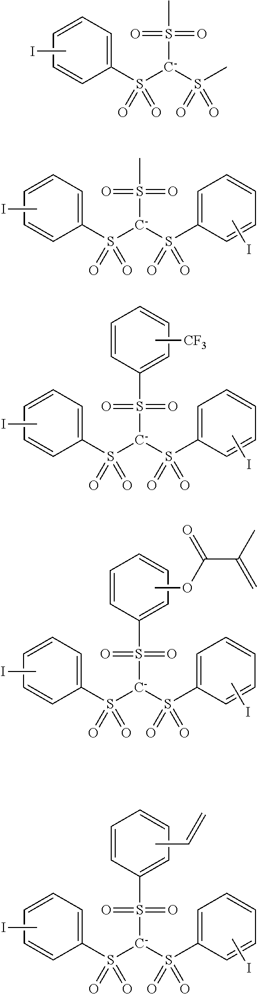

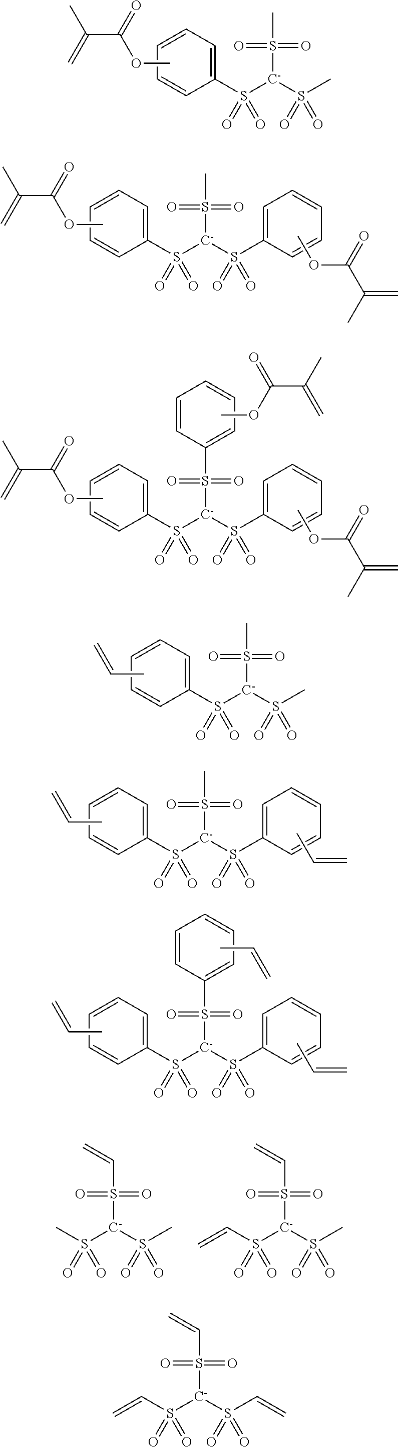

Examples of the anion represented by formula (1-8) include, but are not limited to, those shown below.

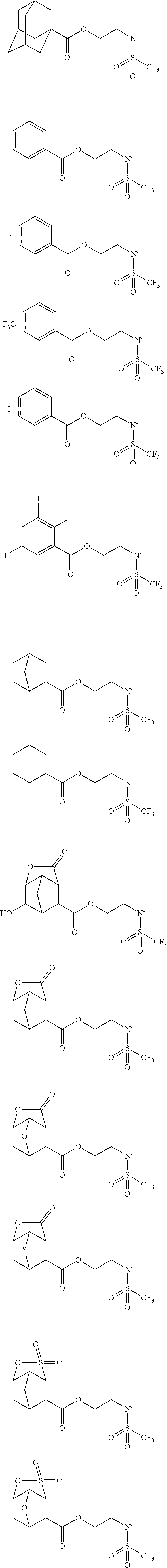

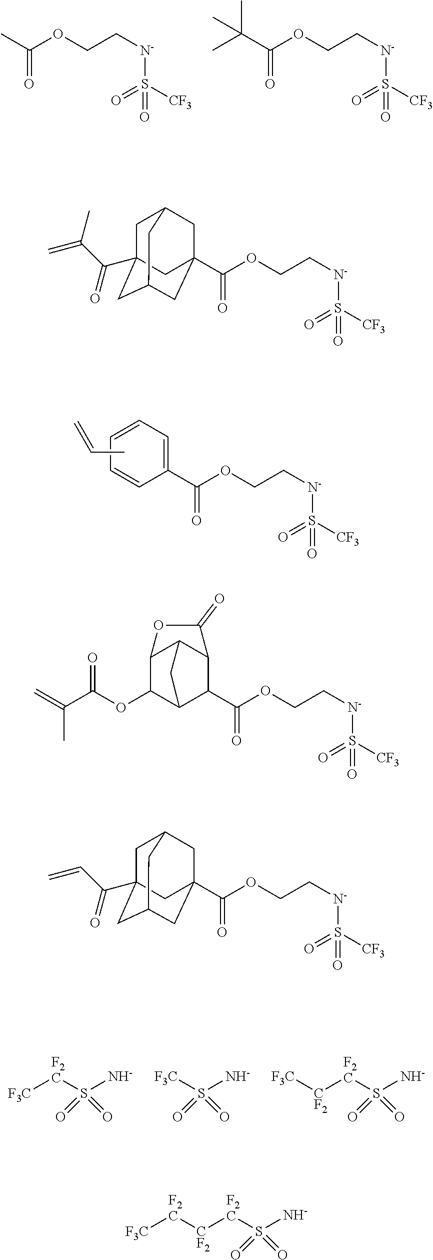

Specific examples of the sulfonium salt represented by formula (1) or (2) include arbitrary combinations of the above-described specific examples of the anion and the cation.

From the viewpoint of pattern formation, it is preferable that the sulfonium salt represented by formula (1) or (2) includes polymerizable functional groups in both the cation and the anion forming the salt.

The sulfonium salt represented by formula (1) or (2) may be used alone as a single compound or in combination of two or more compounds; however, from the viewpoint of improving component uniformity, it is preferable to use a single compound alone or a combination of two compounds.

The sulfonium salt represented by formula (1) or (2) can be synthesized by using known organic synthetic methods in combination. For example, there is a method in which onium salt intermediates having a desired cation and a desired anion are mixed and subjected to an ion exchange reaction. The ion exchange reaction can be easily performed by a known method, and reference may be made, for example, to JP 2007-145797 A.

### [Iodonium Salt]

The molecular resist composition of the present invention comprises an iodonium salt comprising an iodonium cation represented by the following formula (1-1), and any one of a halide ion, a nitrate ion, a hydrogen sulfate ion, a hydrogen carbonate ion, a tetraphenylborate ion, or an anion represented by any of formulae (1-2) to (1-8).

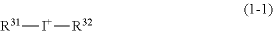

wherein R³¹ and R³² are each independently a halogen atom or a hydrocarbyl group having 1 to 30 carbon atoms and optionally containing a hetero atom.

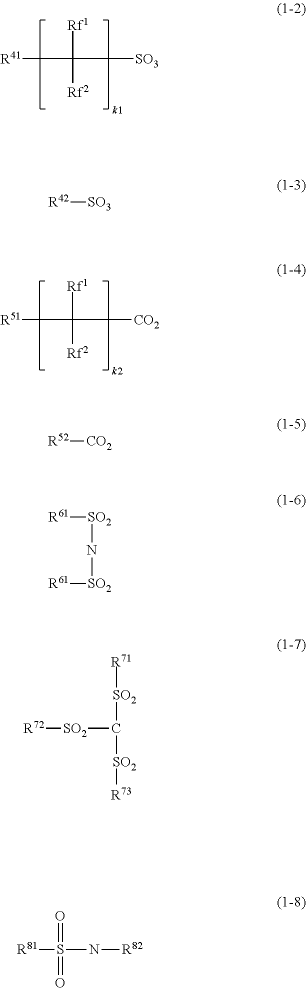

wherein k1 and k2 are each independently 1, 2, 3, or 4; Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time; R⁴¹ is a hydrogen atom, a halogen atom, a hydroxy group, or a hydrocarbyl group having 1 to 50 carbon atoms and optionally containing a hetero atom; R⁴² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the sulfo group is substituted with a fluorine atom or a fluoroalkyl group; R⁵¹ is a hydrogen atom, a halogen atom, a hydroxy group, or a hydrocarbyl group having 1 to 50 carbon atoms and optionally containing a hetero atom; R⁵² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the carboxy group is substituted with a fluorine atom or a fluoroalkyl group; R⁶¹ and R⁶² are each independently a hydrocarbyl group having 1 to 50 carbon atoms and optionally containing a hetero atom; R⁷¹ to R⁷³ are each independently a hydrocarbyl group having 1 to 50 carbon atoms and optionally containing a hetero atom; R⁸¹ is a fluorine atom or a fluorinated hydrocarbyl group having 1 to 10 carbon atoms, and the fluorinated hydrocarbyl group optionally contains a hydroxy group, an ether bond, or an ester bond; R⁸² is a hydrogen atom or a hydrocarbyl group having 1 to 20 carbon atoms, and the hydrocarbyl group optionally contains a hydroxy group, an ether bond, or an ester bond; R⁸¹ and R⁸² are optionally bonded to each other to form a ring together with the atoms to which they are bonded.

Examples of the halogen atom represented by R³¹ and R³² in formula (1-1) include a fluorine atom, a chlorine atom, a bromine atom, an iodine atom, and the like. The hydrocarbyl group having 1 to 30 carbon atoms represented by R³¹, R³² may be saturated or unsaturated, and may be linear, branched, or cyclic. Specific examples thereof include alkyl groups having 1 to 30 carbon atoms, such as methyl group, ethyl group, propyl group, isopropyl group, n-butyl group, isobutyl group, sec-butyl group, tert-butyl group, n-pentyl group, tert-pentyl group, n-hexyl group, n-octyl group, 2-ethylhexyl group, n-nonyl group, and n-decyl group; cyclic saturated hydrocarbyl groups having 3 to 30 carbon atoms, such as cyclopentyl group, cyclohexyl group, cyclopentylmethyl group, cyclopentylethyl group, cyclopentylbutyl group, cyclohexylmethyl group, cyclohexylethyl group, cyclohexylbutyl group, norbornyl group, tricyclo[5.2.1.0^{2,6}]decyl group, and adamantyl group, adamantylmethyl group; and aryl groups having 6 to 30 carbon atoms, such as phenyl group, naphthyl group, and anthracenyl group. In addition, some or all of the hydrogen atoms of the above hydrocarbyl group are optionally substituted with a group containing a hetero atom such as an oxygen atom, a sulfur atom, a nitrogen atom, or a halogen atom, and some of the —CH₂— groups constituting the hydrocarbyl group are optionally substituted with a group containing a hetero atom such as an oxygen atom, a sulfur atom, or a nitrogen atom, and as a result, the hydrocarbyl group optionally contains a hydroxy group, a cyano group, a halogen atom, a carbonyl group, an ether bond, a thioether bond, an ester bond, a sulfonate ester bond, a carbonate bond, a carbamate bond, a lactone ring, a sultone ring, or a carboxylic acid anhydride group (—C(═O)—O—C(═O)—).

In addition, the anion X⁻ in formula (1) or (2) may be the same as the counter anion of the iodonium cation represented by formula (1-1), that is, the anion X⁻ of the sulfonium salt and the counter anion of the iodonium cation may be expressed by the similar structure. Furthermore, independently or in addition thereto, the anion represented by any of the above formulae (1-2) to (1-8) may include a polymerizable functional group.

Specific examples of the group represented by the above formula (1-1) include, but are not limited to, the groups shown below. It should be noted that the anion represented by any of formulae (1-2) to (1-8) is similar to that in the sulfonium salt.

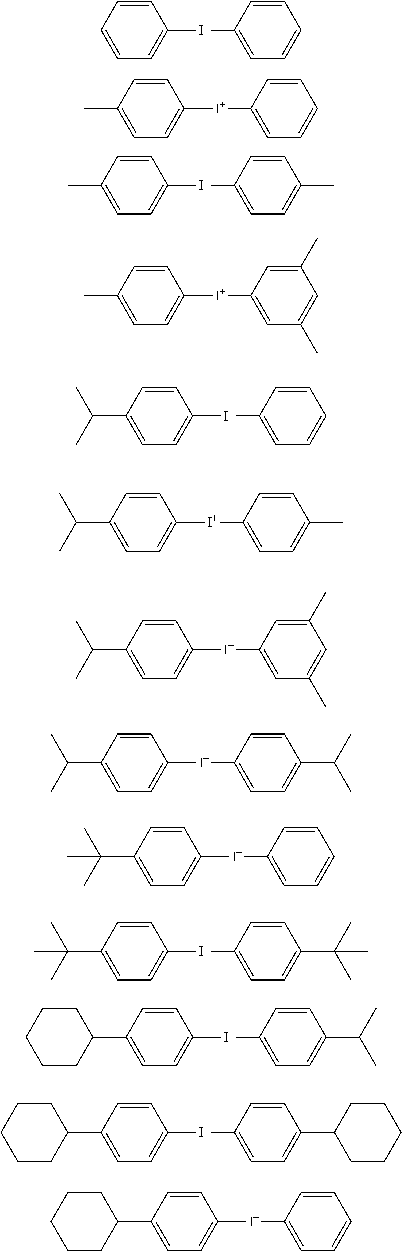

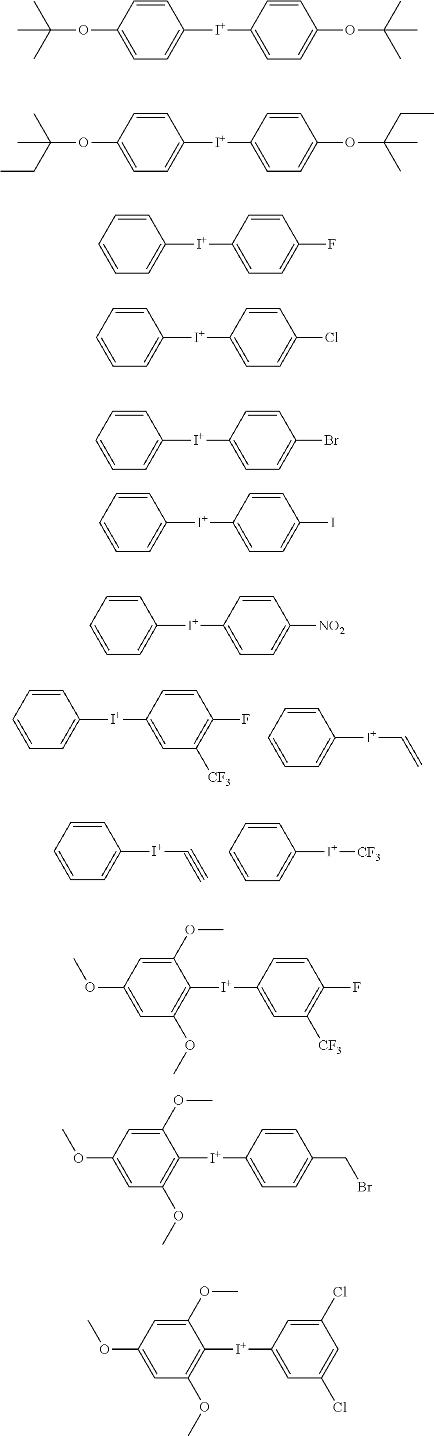

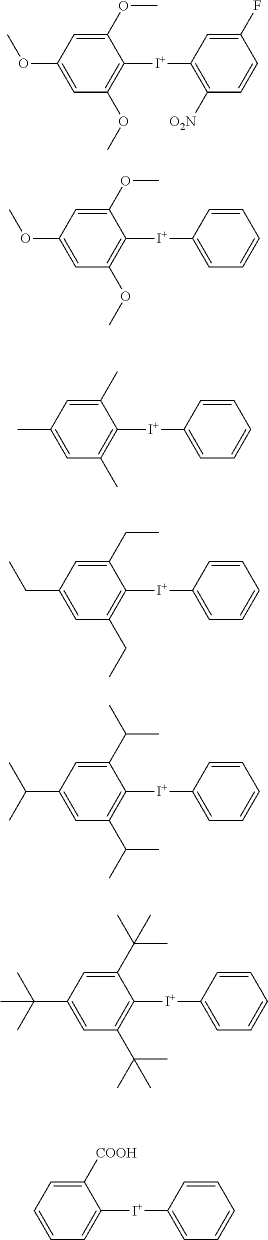

The content of the iodonium salt is preferably from 1 to 100 parts by mass, and more preferably from 5 to 15 parts by mass, based on 100 parts by mass of the above-described sulfonium salt. The iodonium salt may be used alone or in combination of two or more kinds.

The molecular resist composition of the present invention is characterized in that, in addition to the sulfonium salt as a main component, an iodonium salt is added. As described later, the addition of the iodonium salt enhances EUV light absorption, thereby improving the stochastics, sensitivity, and roughness of the resist. Furthermore, since the iodonium salt exhibits a high EUV light absorption rate, the iodonium salt undergoes photodecomposition to efficiently generate radicals. The radicals thus generated initiate radical polymerization of the polymerizable substituent of the sulfonium salt, thereby efficiently increasing the molecular weight and resulting in improvements in the contrast, sensitivity, and resolution of the resist.

### [Organic Solvent]

The molecular resist composition of the present invention contains an organic solvent. The solvent is not particularly limited as long as it can dissolve the sulfonium salt represented by formula (1) or (2) and the iodonium salt represented by formula (1-1), and is capable of forming a film. Examples of the organic solvent include: ketones such as cyclohexanone and methyl-2-n-pentyl ketone; alcohols such as 3-methoxy-butanol, 3-methyl-3-methoxy-butanol, 1-methoxy-2-propanol, 1-ethoxy-2-propanol, and diacetone alcohol (DAA); ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, tert-butyl acetate, tert-butyl propionate, and propylene glycol mono-tert-butyl ether acetate; and lactones such as γ-butyrolactone.

Among the organic solvents, 1-ethoxy-2-propanol, PGMEA, cyclohexanone, DAA, γ-butyrolactone, and mixed solvents thereof are preferred.

The content of the organic solvent in the molecular resist composition of the present invention is preferably from 200 parts by mass to 5,000 parts by mass based on 100 parts by mass of the sulfonium salt represented by formula (1) or (2). The organic solvent may be used alone or in combination of two or more kinds.

The molecular resist composition of the present invention is characterized by containing, as a main component, a sulfonium salt represented by formula (1) or (2), an iodonium salt represented by formula (1-1), and an organic solvent, and by being free of a base polymer. A resist film obtained from the molecular resist composition of the present invention can form a negative-type pattern by being exposed to EB or EUV, whereby the exposed portion becomes insoluble in an alkaline developer. It is to be noted that the base polymer refers to a polymer that serves as a main component of a polymer-based resist composition and whose solubility in a developer changes upon the action of an acid generated from an acid generator.

In a conventional resist composition having a structure in which a multi-component polymer is used as a main component (base polymer) and further containing a photoacid generator, a sensitivity modifier, or the like, the components are less likely to be uniformly distributed within the resist film, which has a significant impact on the roughness, especially in the formation of fine pattern by EUV lithography. In addition, since the polymer is a material having a large molecular size, such a property also contributes to the degradation of LWR and CDU.

In contrast, the molecular resist composition of the present invention has a very simple structure that is free of multi-component polymer component, thereby improving the uniformity of components in the resist film. Furthermore, since the main component is a low-molecular-weight compound, the molecular size is small, and LWR and CDU can be improved particularly in fine pattern formation by EB lithography and EUV lithography.

The molecular resist composition of the present invention enables pattern formation by utilizing a structural change resulting from the photoreaction of the sulfonium salt serving as a main component and polymerization through a polymerizable functional group. In this case, by using the sulfonium salt represented by formula (1) or (2), particularly in EB lithography and EUV lithography, photodecomposition of the sulfonium salt and radical polymerization of polymerizable groups derived from radicals generated during exposure occur, resulting in a significant change in solubility in an alkaline developer (insolubilization), making it possible to form a negative pattern. In particular, when a sulfonium salt having polymerizable functional groups in both the cation and the anion forming the salt is used, all components of the salt contribute to pattern formation through radical polymerization upon exposure, thereby effectively enhancing the dissolution contrast between the exposed portion and the unexposed portion. Since the structural change occurs during exposure, diffusion of acid, which is observed in conventional polymer-based chemically amplified resist compositions, does not occur, and therefore, image blurring due to acid diffusion is not generated. The resolution performance of the molecular resist composition of the present invention is superior to that of conventional polymer-based chemically amplified resist compositions in which a polymer is used as a main component, and the molecular resist composition is also resistant to pattern collapse, thereby being extremely effective in fine pattern formation.

The molecular resist composition of the present invention is characterized in that, an iodonium salt is added in addition to the sulfonium salt as a main component. By the addition of an iodonium salt, absorption of EUV light is enhanced, resulting in improvements in the stochastics, sensitivity, and roughness of the resist. In addition, when the iodonium salt having high EUV light absorption undergoes photodecomposition, radicals are generated, which initiate radical polymerization of polymerizable substituents of the sulfonium salt, thereby efficiently increasing the molecular weight and leading to improvements in the contrast, sensitivity, and resolution of the resist.

It is to be noted that although the molecular resist composition of the present invention does not contain a polymer component functioning as a base polymer, a polymer component used as an additive (i.e., not as a main component), such as a polymer used as a surfactant, may be included, if necessary, for pattern formation by the sulfonium salt represented by formula (1) or (2).

### [Other Components]

The molecular resist composition of the present invention may further contain a radical scavenger as another component. By adding a radical scavenger, the photoreaction during photolithography can be controlled and the sensitivity can be adjusted.

Examples of such radical scavengers include hindered phenols, quinones, hindered amines, thiol compounds, and the like. Specific examples of the hindered phenols include dibutylhydroxytoluene (BHT), 2,2′-methylenebis(4-methyl-6-tert-butylphenol), and the like. Examples of the quinones include 4-methoxyphenol(methoquinone), hydroquinone, and the like. Examples of the hindered amines include 2,2,6,6-tetramethylpiperidine, 2,2,6,6-tetramethylpiperidine-N-oxyl radical, and the like. Examples of the thiol compounds include dodecanethiol, hexadecanethiol, benzenethiol, and the like. When the molecular resist composition of the present invention contains the above-described radical scavenger, the content thereof is preferably from 0.1 to 20 parts by mass, more preferably from 0.5 to 10 parts by mass, based on 100 parts by mass of the sulfonium salt. The radical scavenger may be used alone or in combination of two or more kinds.

The molecular resist composition of the present invention may further contain a surfactant as another component. Examples of the surfactant include FC-4432 and FC-4430 (manufactured by 3M Company), and PF636, PF656, PF6320, and PF6520 (manufactured by Omnova Solutions Inc.). When the molecular resist composition of the present invention contains a surfactant, the content thereof is preferably from 0.001 to 20 parts by mass, more preferably from 0.1 to 10 parts by mass, based on 100 parts by mass of the sulfonium salt. The surfactant may be used alone or in combination of two or more kinds.

### [Patterning Process]

When the molecular resist composition of the present invention is used in the fabrication of various integrated circuits, known lithography techniques can be applied. Examples of the patterning process include a process including a step of forming a resist film on a substrate using the above-described molecular resist composition, a step of exposing the resist film to high-energy ray, and a step of developing the exposed resist film with a developer.

First, the molecular resist composition of the present invention is applied onto a substrate for integrated circuit fabrication (such as Si, SiO₂, SiN, SiON, TiN, WSi, BPSG, SOG, or an organic antireflective coating) or a substrate for mask circuit fabrication (such as Cr, CrO, CrON, MoSi₂, or SiO₂) by a suitable coating method such as spin coating, roll coating, flow coating, dip coating, spray coating, or doctor blade coating, so that the resulting coating film has a thickness of 0.01 to 2 μm. The coated film is then prebaked on a hot plate, preferably at a temperature of 60 to 150° C. for 10 seconds to 30 minutes, and more preferably at 80 to 120° C. for 30 seconds to 20 minutes, to form a resist film.

Next, the resist film is exposed using high-energy rays. Examples of the high-energy rays include ultraviolet rays, deep ultraviolet rays, EB, EUV, X⁻ rays, soft X-rays, excimer laser light, γ-rays, synchrotron radiation, or the like. When the high-energy rays used are ultraviolet rays, deep ultraviolet rays, EUV, X-rays, soft X-rays, excimer laser light, γ-rays, synchrotron radiation, or the like, the exposure is preferably performed at an exposure dose of approximately 1 to 200 mJ/cm², more preferably approximately 10 to 100 mJ/cm², either directly or through a mask for forming a desired pattern. When the high-energy ray is an EB for use, pattern drawing is preferably performed at an exposure amount of approximately 0.1 to 100 μC/cm², more preferably approximately 0.5 to 50 μC/cm², either directly or through a mask for forming a desired pattern. Among the above-described high-energy rays, the molecular resist composition of the present invention is particularly suitable for fine patterning using KrF excimer laser light, ArF excimer laser light, EB, EUV, X-rays, soft X⁻ rays, γ-rays, or synchrotron radiation, and is especially suitable for fine patterning using EB or EUV.

Since, in the molecular resist composition of the present invention, the sulfonium salt undergoes a structural change during exposure to form an image, post exposure bake (PEB), which is generally required for chemically amplified resist compositions, is not necessarily required. When PEB is performed, it is preferably performed on a hot plate or in an oven after exposure under conditions of preferably 30 to 120° C. for 10 seconds to 30 minutes, and more preferably 60 to 100° C. for 30 seconds to 20 minutes.

When the molecular resist composition of the present invention is of the negative-type, the exposed portions become insoluble in the developer, while the unexposed portions dissolve. On the other hand, when the composition is of the positive type, the exposed portions dissolve in the developer, while the unexposed portions become insoluble.

Pattern formation is achieved through radical polymerization of the sulfonium salt in the molecular resist composition of the present invention upon exposure. In cases where the polymer is insoluble in the alkaline developer or organic solvent developer described later, and the unreacted sulfonium salt remains soluble, a negative-type pattern is formed.

After exposure or PEB, the resist film is developed using an alkaline aqueous solution developer containing 0.1 to 10% by mass, preferably 2 to 5% by mass, of tetramethylammonium hydroxide (TMAH), tetraethylammonium hydroxide (TEAH), tetrapropylammonium hydroxide (TPAH), tetrabutylammonium hydroxide (TBAH), and the like, and exposed by a conventional method such as dip method, puddle method, spray method, and the like, for a period of 3 seconds to 3 minutes, preferably 5 seconds to 2 minutes, to form the desired pattern.

After development with the alkaline developer, rinsing with pure water is performed, followed by spin-drying. To reduce stress applied to the pattern during drying and thereby prevent pattern collapse, it is also effective to use a rinse solution containing a surfactant or to perform supercritical rinsing using carbon dioxide or the like.

The molecular resist composition of the present invention can also be used to obtain a negative-type pattern by organic solvent development. Examples of the developer used in such a case include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate. These organic solvents may be used alone or in combination of two or more kind.

After development, rinsing may be performed as necessary. As the rinse solution, a solvent that is miscible with the developer and does not dissolve the resist film is preferably used. Examples of such solvents used preferably include alcohols having 3 to 10 carbon atoms, ether compounds having 8 to 12 carbon atoms, alkanes, alkenes, alkynes and aromatic compounds having 6 to 12 carbon atoms.

Specific examples of alcohols having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, 1-octanol, and the like.

Examples of ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, di-n-hexyl ether, and the like.

Examples of alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, cyclononane, and the like. Examples of alkenes having 6 to 12 carbon atoms include hexene, heptene, octene, cyclohexene, methylcyclohexene, dimethylcyclohexene, cycloheptene, cyclooctene, and the like. Examples of alkynes having 6 to 12 carbon atoms include hexyne, heptyne, octyne, and the like.

Examples of aromatic solvents include toluene, xylene, ethylbenzene, isopropylbenzene, tert-butylbenzene, mesitylene, and the like.

By performing rinsing, it is possible to reduce pattern collapse and defect generation in the resist pattern. In addition, the rinsing is not necessarily essential, and omission of the rinsing can reduce the amount of solvent used.

### EXAMPLE

Hereinafter, the present invention will be described in detail with reference to Synthesis Examples, Examples, and Comparative Examples; however, the present invention is not limited to the following Examples. The apparatuses used were as follows:
IR: Nicolet 6700, manufactured by Thermo Fisher Scientific Inc.
¹H-NMR: ECA-500, manufactured by JEOL Ltd.
MALDI TOF-MS: S3000, manufactured by JEOL Ltd.

### [1] Synthesis of Sulfonium Salt

### [Synthesis Example 1-1] Synthesis of PAG-1

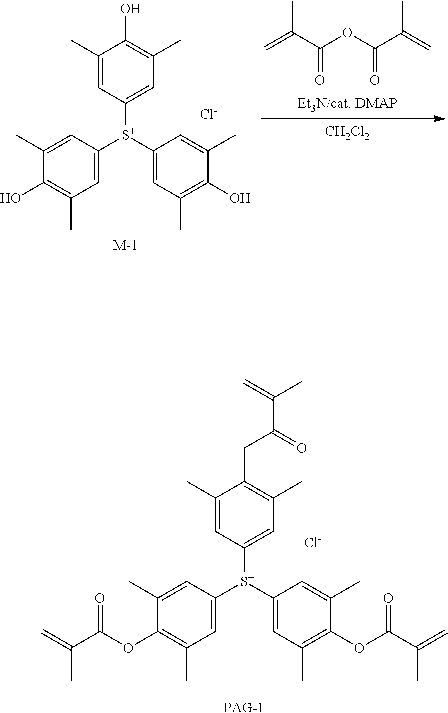

Under a nitrogen atmosphere, 43.1 g of raw material M-1, 42.5 g of triethylamine, and 1.22 g of 4-dimethylaminopyridine were dissolved in 431 g of methylene chloride. The reaction system was cooled to 10° C. or below, and 55.8 g of methacrylic anhydride was added dropwise thereto. After the dropwise addition, the mixture was aged at 20° C. for 12 hours. After aging, the reaction solution was cooled, and 200 g of saturated sodium bicarbonate solution was added dropwise to stop the reaction. Subsequently, a conventional aqueous work-up was performed, the solvent was distilled off, and recrystallization was performed using diisopropyl ether to obtain PAG-1 as white crystals (yield: 58.1 g, yield ratio: 92%).

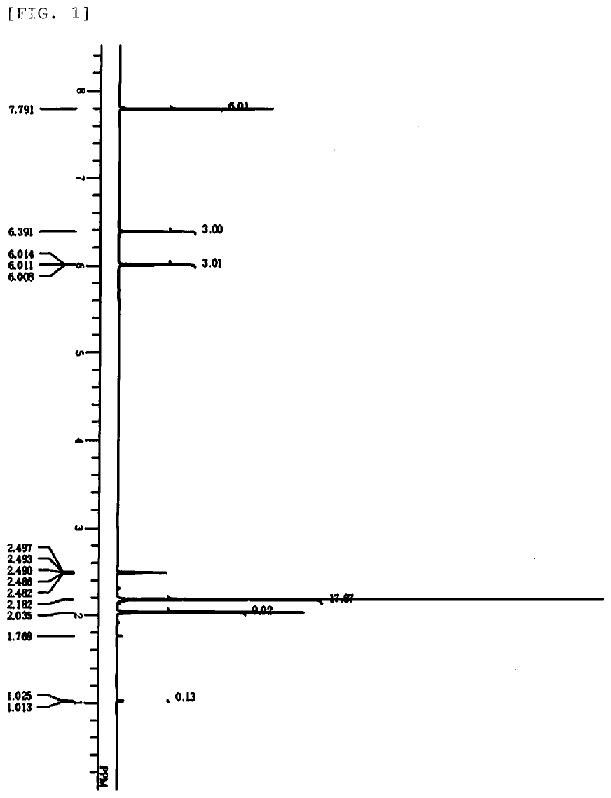

The spectral data of PAG-1 are shown below. In addition, the result of the nuclear magnetic resonance spectrum (¹H-NMR/DMSO-d₆) is shown in FIG. 1.

### IR (D-ATR):

3371,2973,2927,1737,1677,1637,1608,1477,1454,1379,1317,1 293,1276,1231,1182,1120,1038,1011,947,877,807,714,650,61 3, 583, 489 cm⁻¹.

### MALDI-TOFMS:

POSITIVE [M⁺]599 (corresponding to C₃₆H₃₉O₆S⁺)
NEGATIVE [M⁻]35 (corresponding to Cl⁻)

### [Synthesis Example 1-2] Synthesis of PAG-2

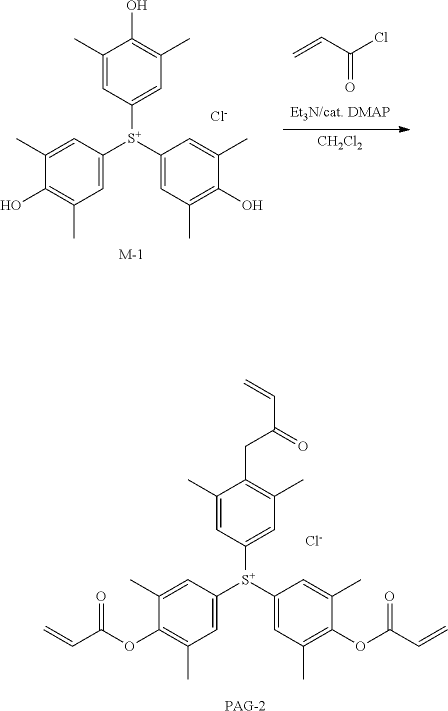

PAG-2 was synthesized in the same manner as in Synthesis Example 1-1, except that methacrylic anhydride was replaced with acryloyl chloride (14.4 g, yield ratio: 89%).

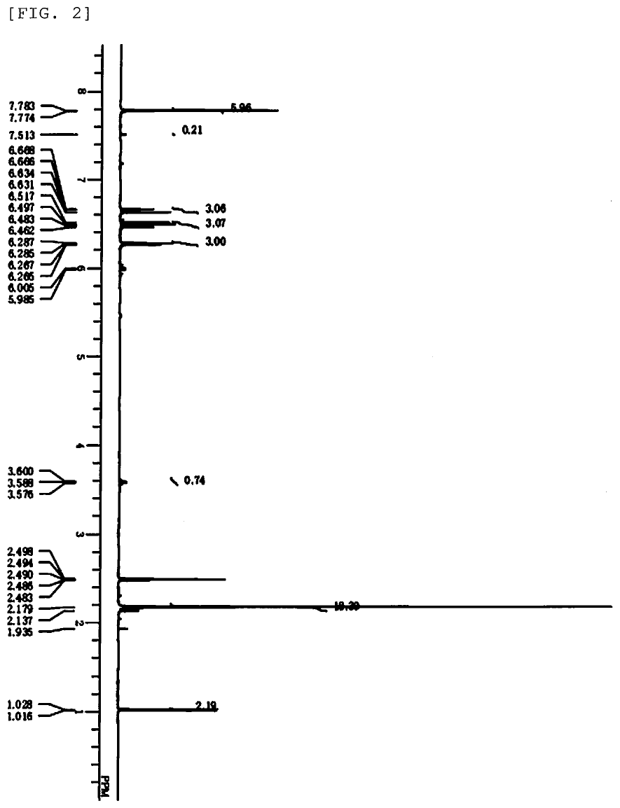

The spectral data of PAG-2 are shown below. In addition, the result of the nuclear magnetic resonance spectrum (¹H-NMR/DMSO-d₆) is shown in FIG. 2.

### IR (D-ATR):

3607,3366,2974,2926,1741,1633,1577,1476,1403,1293,1277,1 243,1180,1139,1102,1016,982,901,802,718,667,611,588 cm⁻¹.

### MALDI-TOFMS:

POSITIVE [M⁺]557 (corresponding to C₃₃H₃₃O₆S⁺)
NEGATIVE [M⁻]35 (corresponding to Cl⁻)

### [Synthesis Example 1-3] Synthesis of PAG-3

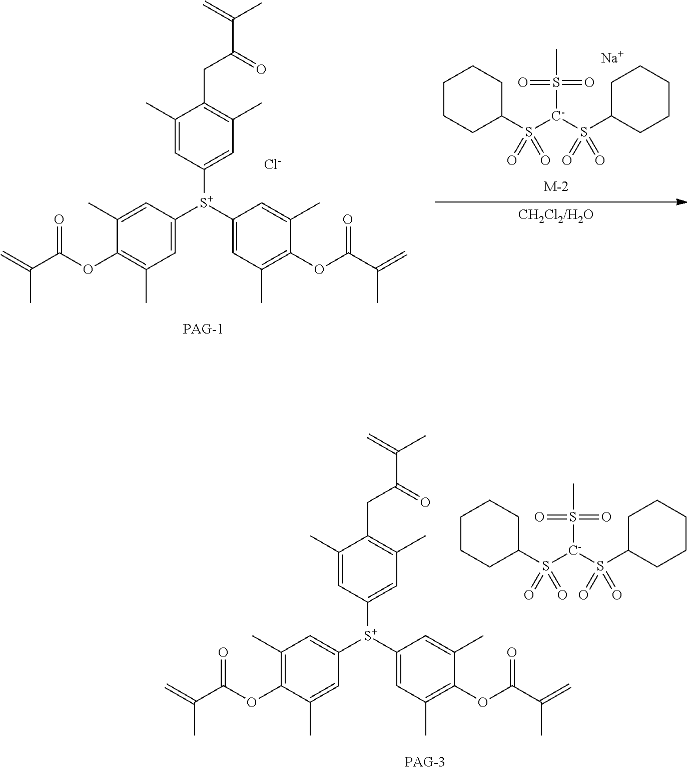

Under a nitrogen atmosphere, 14.6 g of PAG-1, 10.3 g of the raw material M-2, 40 g of methylene chloride, and 40 g of water were charged and stirred for 30 minutes. Thereafter, the organic layer was separated by liquid separation and washed five times with 40 g of water. The solvent in the organic layer was distilled off, and recrystallization was performed using diisopropyl ether to obtain PAG-3 as white crystals (yield: 9.3 g, yield ratio: 75%).

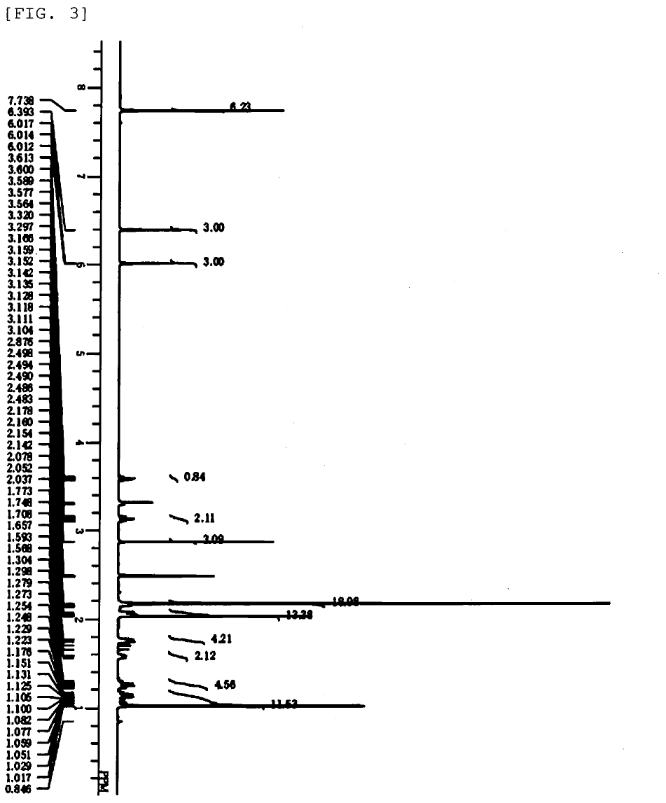

The spectral data of PAG-3 are shown below. In addition, the result of the nuclear magnetic resonance spectrum (¹H-NMR/DMSO-d₆) is shown in FIG. 3.

### IR (D-ATR):

3506,2929,2855,1737,1637,1476,1452,1379,1290,1182,1110,1 036,1011,990,947,877,807,755,657,609,582,544,528,457 cm⁻¹.

### MALDI-TOFMS:

POSITIVE [M⁺]599 (corresponding to C₃₆H₃₉O₆S⁺)
NEGATIVE [M⁻]385 (corresponding to C₁₄H₂₅O₆S₃⁻)

### [Synthesis Example 1-4] Synthesis of PAG-4

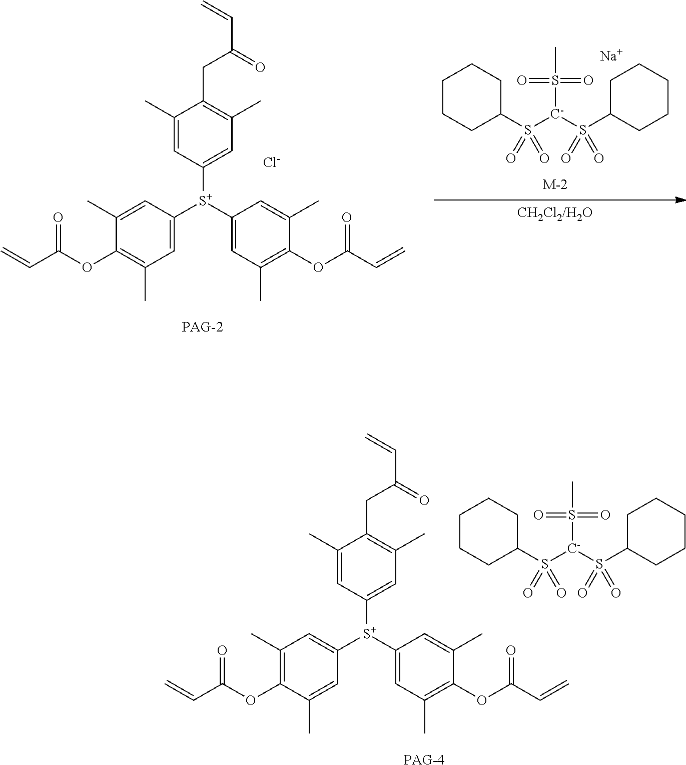

PAG-4 was synthesized in the same manner as in Synthesis Example 1-3, except that PAG-1 was replaced with PAG-2 (10.3 g, yield ratio: 84%).

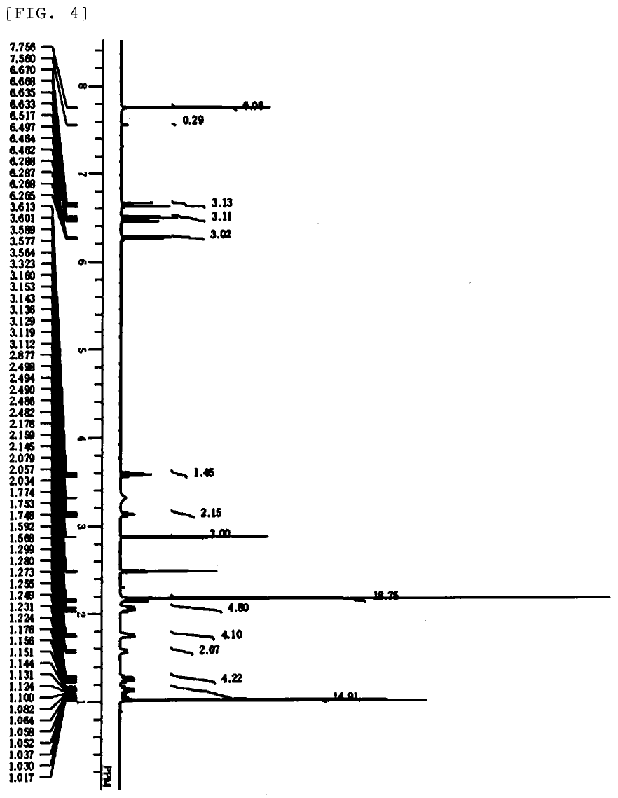

The spectral data of PAG-4 are shown below. In addition, the result of the nuclear magnetic resonance spectrum (¹H-NMR/DMSO-d₆) is shown in FIG. 4.

### IR (D-ATR):

3489,3046,2933,2856,1743,1633,1579,1477,1451,1401,1379,1 293,1242,1180,1136,1107,1015,983,959,901,802,764,718, 656,628,610,586,544,528,458,403 cm⁻¹.

### MALDI-TOFMS:

POSITIVE [M⁺]557 (corresponding to C₃₃H₃₃O₆S⁺)
NEGATIVE [M⁻]385 (corresponding to C₁₄H₂₅O₆S₃⁻)

### [Synthesis Example 1-5] Synthesis of PAG-5

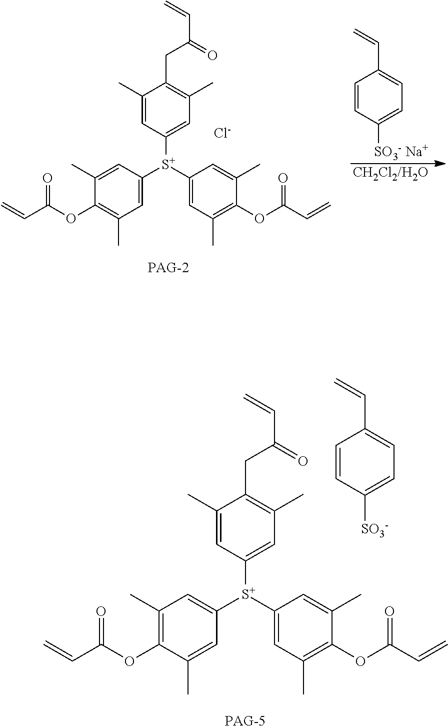

PAG-5 was synthesized in the same manner as in Synthesis Example 1-4, except that the raw material M-2 was replaced with sodium styrenesulfonate (13.7 g, yield ratio: 90%).

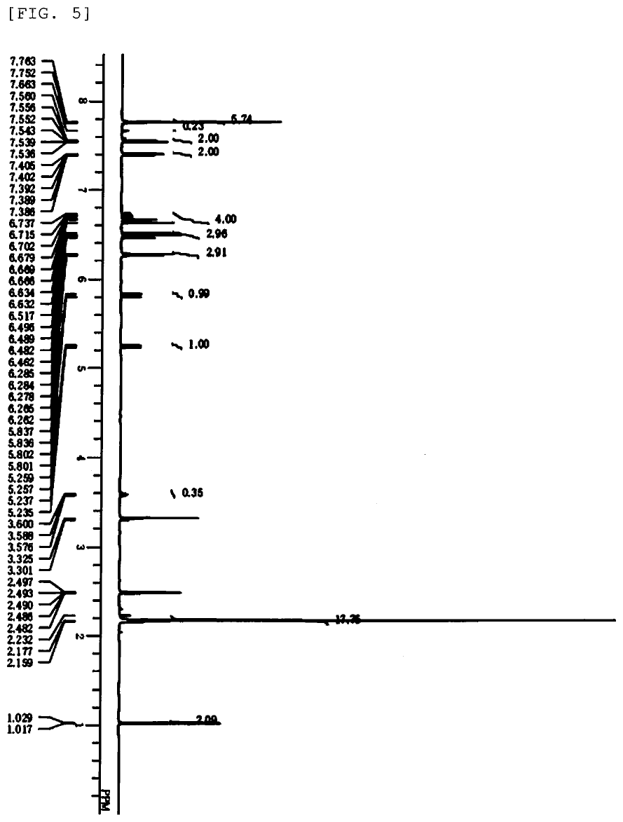

The spectral data of PAG-5 are shown below. In addition, the result of the nuclear magnetic resonance spectrum (¹H-NMR/DMSO-d₆) is shown in FIG. 5.

### IR (D-ATR):

3048,2972,2926,1743,1633,1477,1399,1294,1277,1240,1206,1 180,1137,1104,1060,1033,1010,987,975,902,841,804,714,674,611,584,553 cm⁻¹.

### MALDI-TOFMS:

POSITIVE [M⁺]557 (corresponding to C₃₃H₃₃O₆S⁺)
NEGATIVE [M⁻]183 (corresponding to C₈H₇O₃S⁻)

### [Synthesis Example 1-6] Synthesis of PAG-6

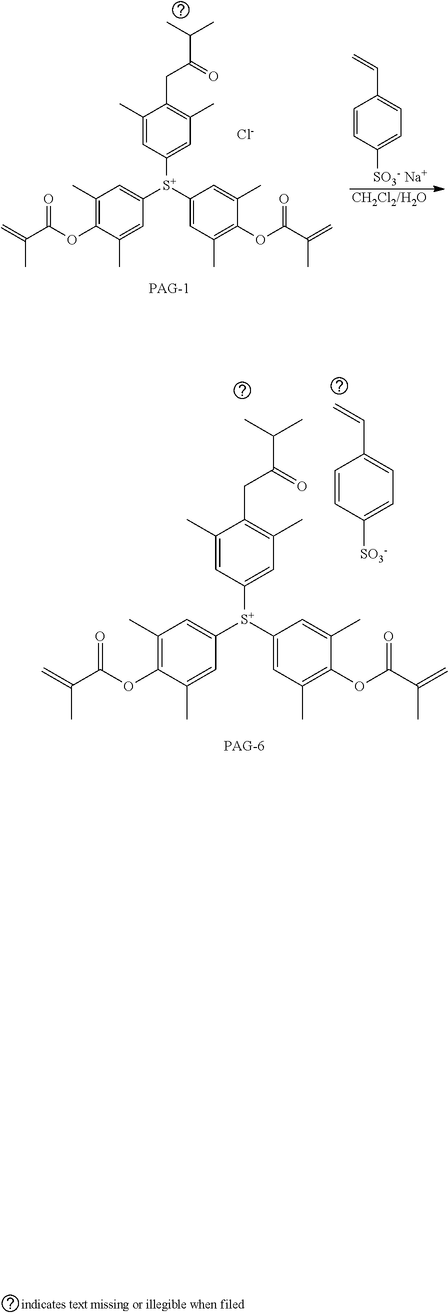

PAG-6 was synthesized in the same manner as in Synthesis Example 1-3, except that the raw material M-2 was replaced with sodium styrenesulfonate (16.1 g, yield ratio: 96%).

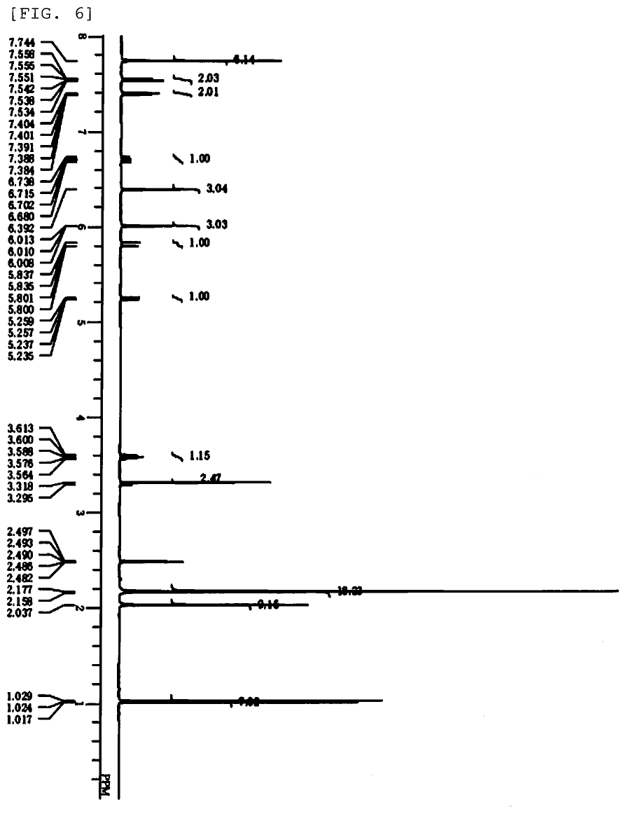

The spectral data of PAG-6 are shown below. In addition, the result of the nuclear magnetic resonance spectrum (¹H-NMR/DMSO-d₆) is shown in FIG. 6.

### IR (D-ATR):

3453,2972,2927,1729,1637,1475,1452,1379,1317,1294,1276,1 216, 1202, 1180, 1119, 1034, 1010, 943, 891, 843, 810, 714, 675, 612,582,557,505,487 cm⁻¹.

### MALDI-TOFMS:

POSITIVE [M⁺]599 (corresponding to C₃₆H₃₉O₆S⁺)
NEGATIVE [M⁻]183 (corresponding to C₈H₇O₃S⁻)

### [Synthesis Example 1-7] Synthesis of PAG-7

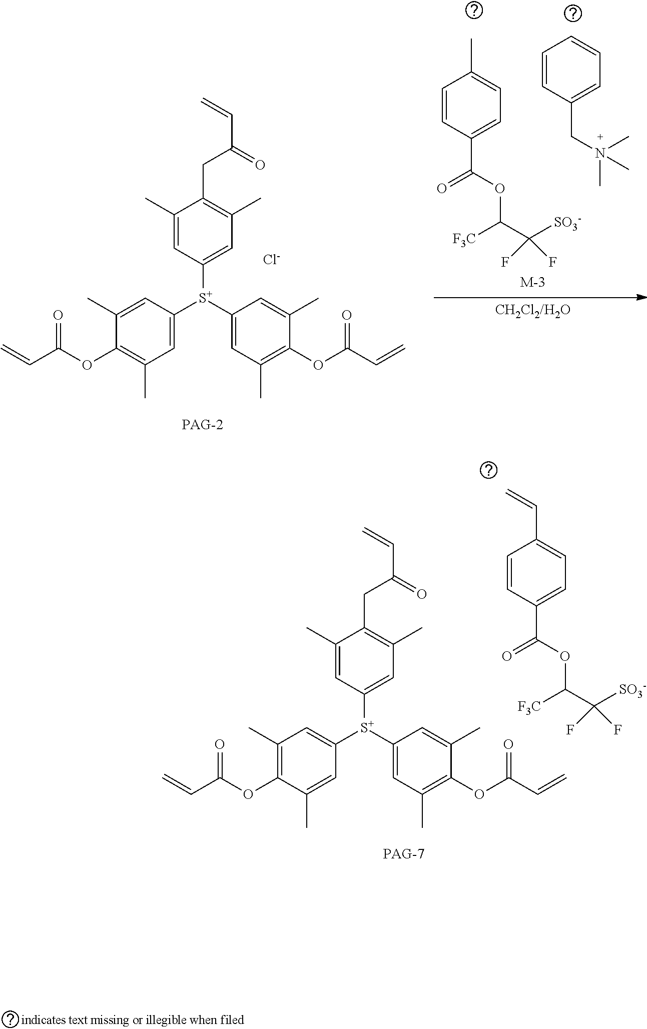

PAG-7 was synthesized in the same manner as in Synthesis Example 1-4, except that the raw material M-2 was replaced with the raw material M-3 (15.9 g, yield ratio: 86%).

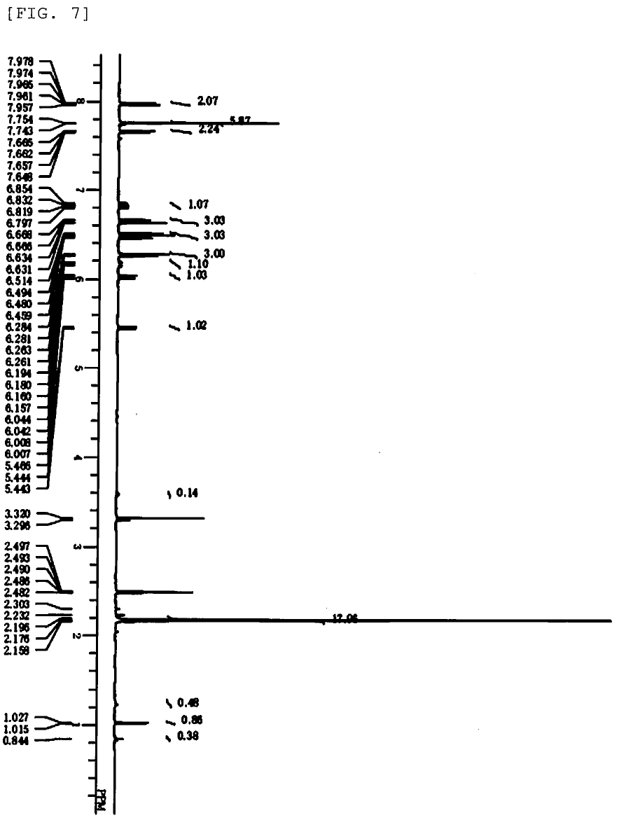

The spectral data of PAG-7 are shown below. In addition, the result of the nuclear magnetic resonance spectrum (¹H-NMR/DMSO-d₆) is shown in FIG. 7.

### IR (D-ATR):

3480,3050,2971,2928,1743,1633,1608,1476,1404,1377,1328,1 245,1181,1139,1101,1071,1015,991,902,860,840,802,777,712,667,642,610,574,552,521 cm⁻¹.

### MALDI-TOFMS:

POSITIVE [M⁺]557 (corresponding to C₃₃H₃₃O₆S⁺)
NEGATIVE [M−]359 (corresponding to C₁₂H₈F₅O₅S⁻)

### [Synthesis Example 1-8] Synthesis of PAG-8

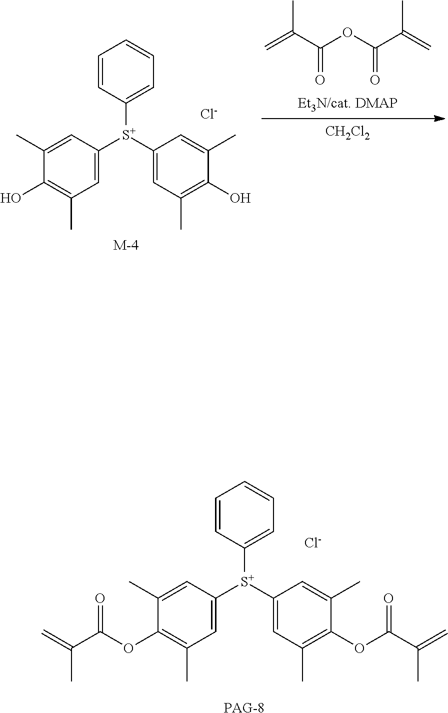

PAG-8 was synthesized in the same manner as in Synthesis Example 1-1, except that the raw material M-1 was replaced with the raw material M-4 (32.1 g, yield ratio: 92%).

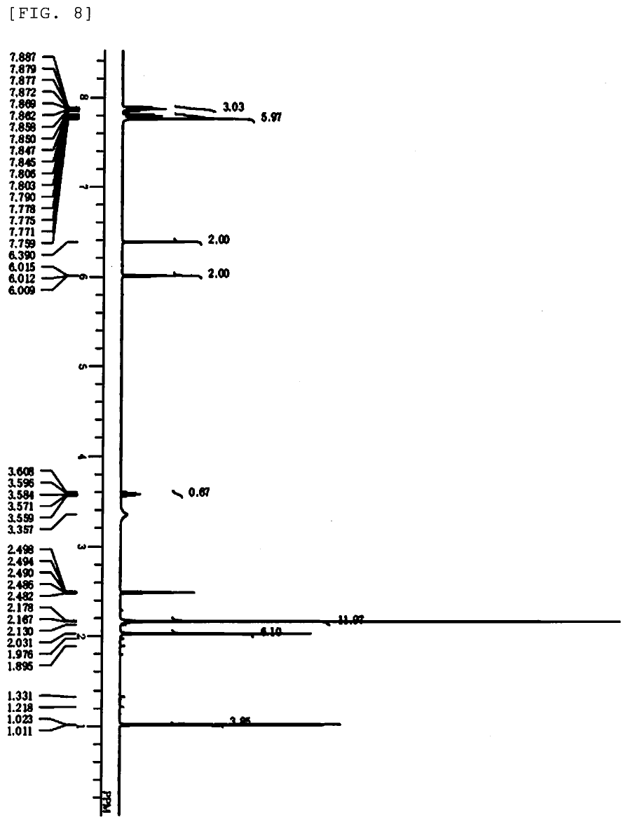

The spectral data of PAG-8 are shown below. In addition, the result of the nuclear magnetic resonance spectrum (¹H-NMR/DMSO-d₆) is shown in FIG. 8.

### IR (D-ATR):

3379,2974,2926,1735,1636,1477,1446,1379,1317,1293,1277,1 182,1120,1040,1011,947,878,808,751,714,685,649,613,568,5 22,492 cm⁻¹.

### MALDI-TOFMS:

POSITIVE [M⁺]487 (corresponding to C₃₀H₃₁O₄S⁺)
NEGATIVE [M⁻]35 (corresponding to Cl⁻)

### [Synthesis Example 1-9] Synthesis of PAG-9

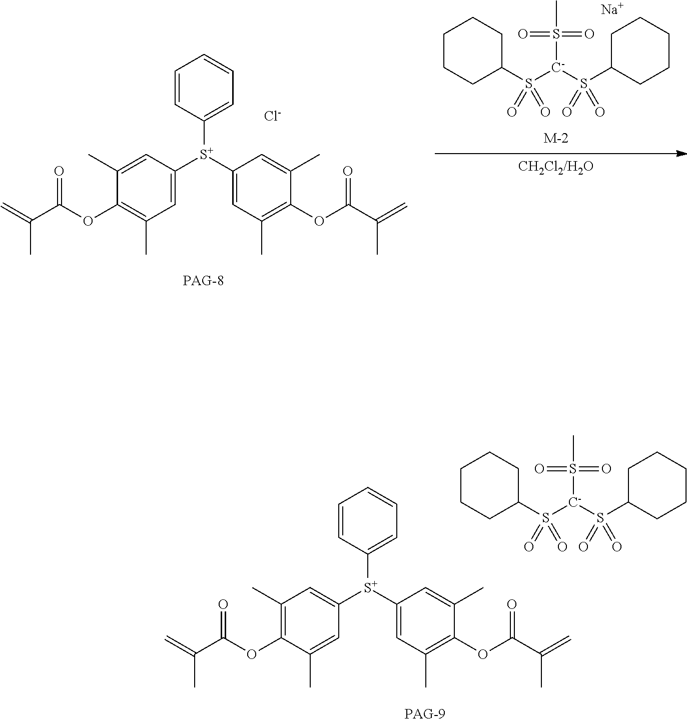

PAG-9 was synthesized in the same manner as in Synthesis Example 1-3, except that PAG-1 was replaced with PAG-8 (16.5 g, yield ratio: 89%).

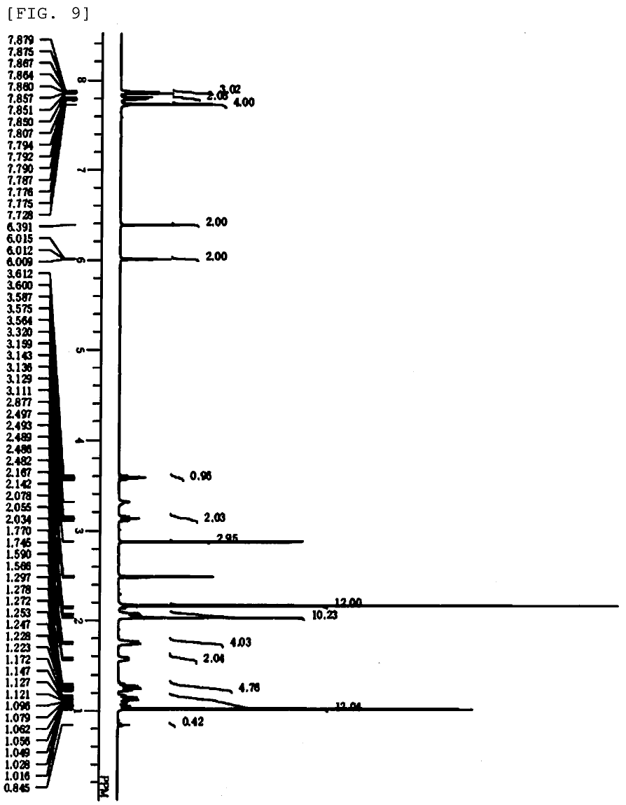

The spectral data of PAG-9 are shown below. In addition, the result of the nuclear magnetic resonance spectrum (¹H-NMR/DMSO-d₆) is shown in FIG. 9.

### IR (D-ATR):

3506,3056,2929,2854,1738,1637,1476,1448,1379,1289,1258,1 183,1110,1012,990,948,892,852,807,754,713,686,657,609,58 2,544,528,456 cm⁻¹.

### MALDI-TOFMS:

POSITIVE [M⁺]487 (corresponding to C₃₀H₃₁O₄S⁺)
NEGATIVE [M⁻]385 (corresponding to C₁₄H₂₅O₆S₃⁻)

### [Synthesis Example 1-10 to 1-20] Synthesis of PAG-10 to PAG-20

PAG-10 to PAG-20 were synthesized by various organic synthesis reactions.

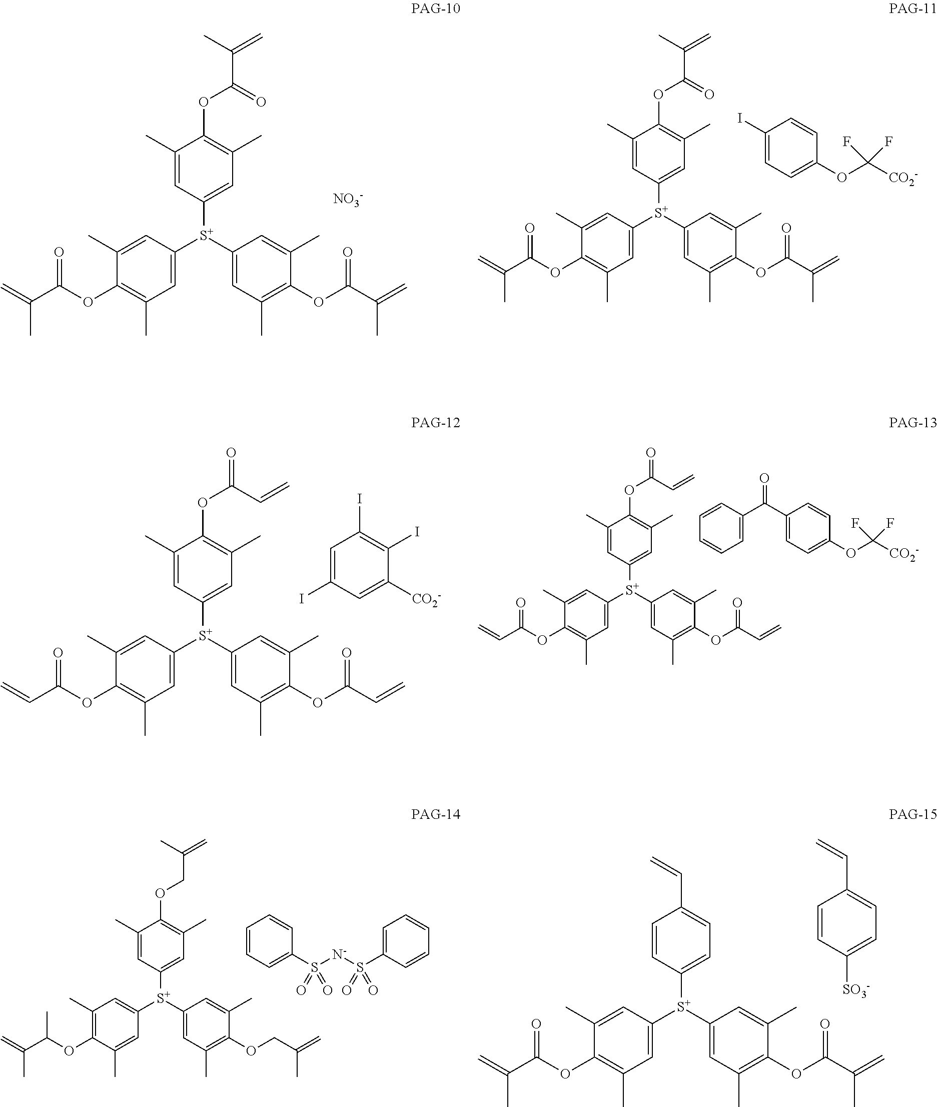

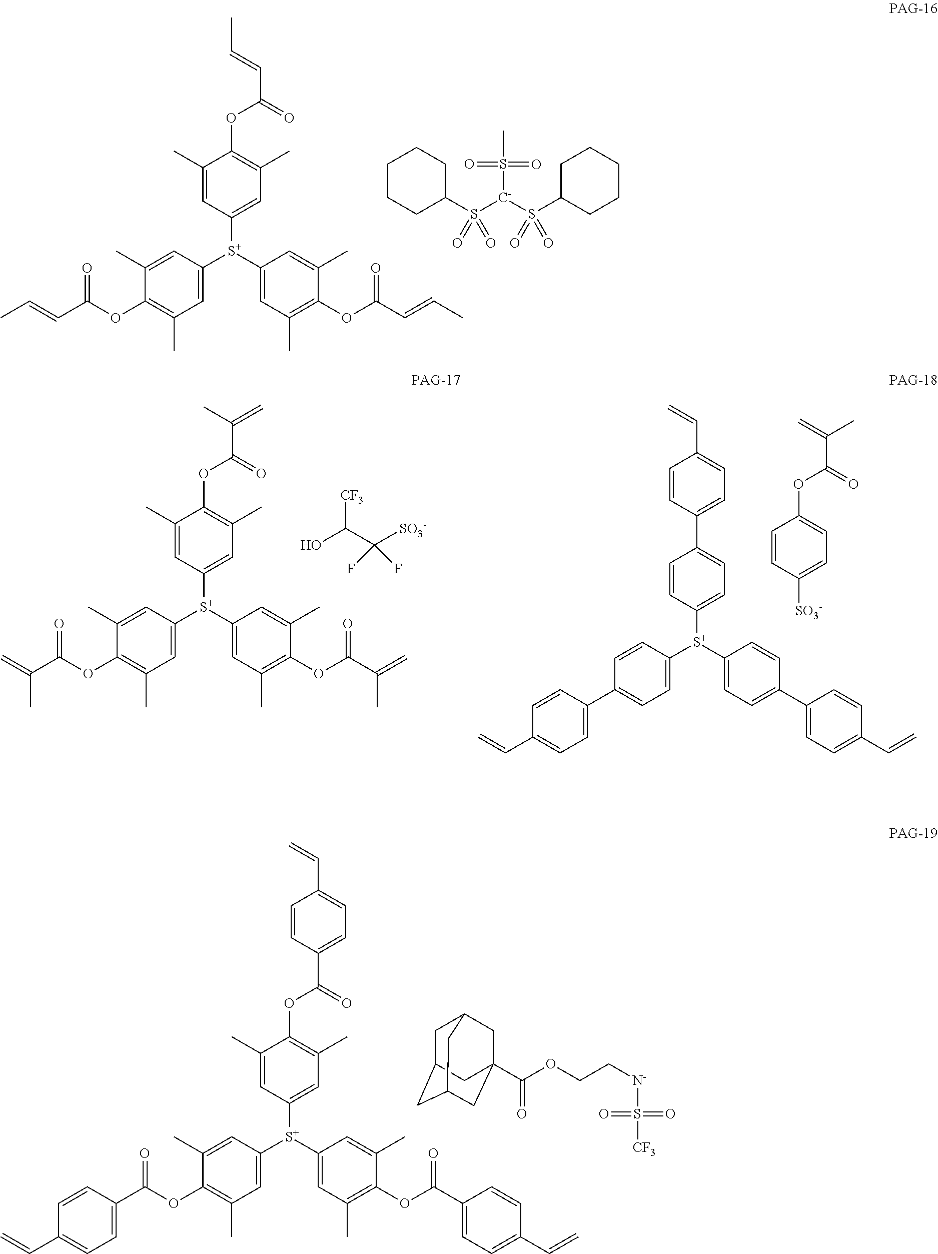

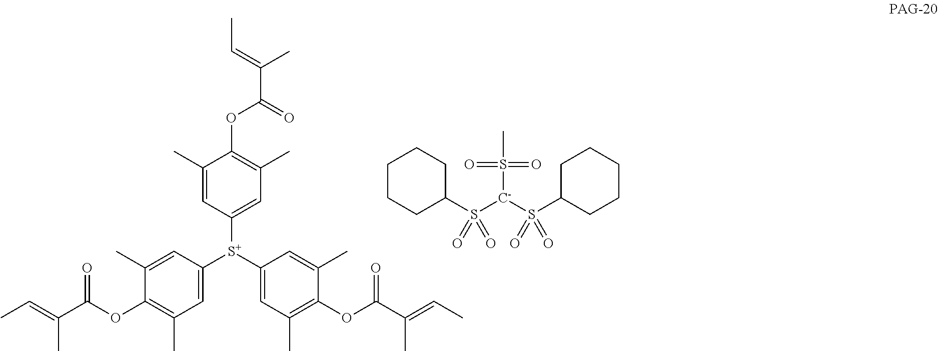 [SMILES: C/C=C(\C)C(=O)Oc1c(C)cc([S+](c2cc(C)c(OC(=O)/C(C)=C/C)c(C)c2)c2cc(C)c(OC(=O)/C(C)=C/C)c(C)c2)cc1C ; CS(=O)(=O)[C-](S(=O)(=O)C1CCCCC1)S(=O)(=O)C1CCCCC1]

### [2] Synthesis of Base Polymer for Comparative Resist Composition

### [Comparative Synthesis Example 1] Synthesis of Polymer P-1

Under a nitrogen atmosphere, 27.8 g of p-hydroxystyrene, 72.2 g of 1-methylcyclopentyl methacrylate, and 6.08 g of dimethyl 2,2′-azobisisobutyrate were dissolved in 155 g of PGMEA to prepare a solution. The resulting solution was added dropwise over 6 hours to 78 g of PGMEA stirred at 80° C. under a nitrogen atmosphere. After the completion of the dropwise addition, the mixture was stirred for 2 hours while maintaining the temperature at 80° C. Thereafter, the reaction solution was cooled to room temperature, and the resulting reaction solution was added dropwise to 3,000 g of n-hexane. The resulting solid precipitate was separated by filtration and vacuum-dried at 50° C. for 20 hours to obtain polymer P-1 as a white powder. The yield was 85 g, and the yield ratio was 85%.

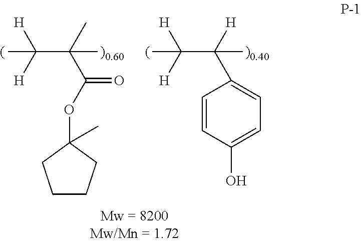

### [Comparative Synthesis Example 2] Synthesis of Polymer P-2

Except that the types and blending ratios of the monomers were changed, polymer P-2 was produced in the same manner as in Comparative Synthesis Example 1.

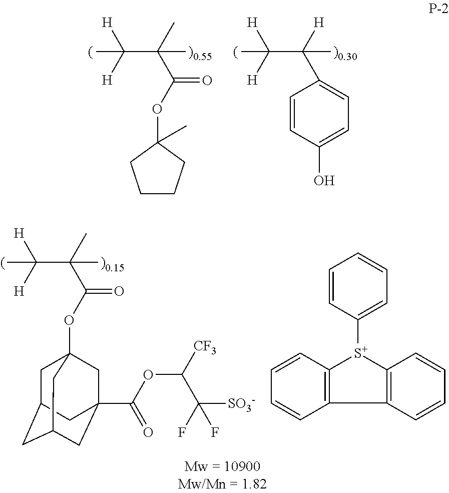

### [3] Preparation of Resist Composition

### Examples 1-1 to 1-20, Comparative Examples 1-1 to 1-8

A molecular resist composition (R-1 to R-20) was prepared by dissolving a sulfonium salt (PAG-1 to PAG-20) in a solvent according to the formulation shown in Table 1 below, followed by filtration of the resulting solution through a 0.2 μm Teflon® a filter. Also, for comparative purposes, a comparative resist composition (CR-1 to CR-8) was prepared by mixing a polymer, a photoacid generator, a sensitivity modifier, a surfactant, and a solvent in accordance with the formulation shown in Table 1 below, followed by filtration through a 0.2 μm Teflon® a filter.

TABLE 1

| | | Base | Sulfonium | Iodonium | Nonionic | Sensitivity | | | |
|---|---|---|---|---|---|---|---|---|---|
| | | polymer | salt | salt | monomer | modifier | Surfactant | Solvent 1 | Solvent 2 |
| | Resist | (parts by | (parts by | (parts by | (parts by | (parts by | (parts by | (parts by | (parts by |
| | composition | mass) | mass) | mass) | mass) | mass) | mass) | mass) | mass) |
| Example 1-1 | R-1 | — | PAG-1 | I-1 | — | — | — | PGMEA | DAA |
| | | | (100) | (10) | | | | (1,500) | (600) |
| Example 1-2 | R-2 | — | PAG-2 | I-2 | — | — | — | PGMEA | DAA |
| | | | (100) | (10) | | | | (1,500) | (600) |
| Example 1-3 | R-3 | — | PAG-3 | I-3 | — | — | — | PGMEA | DAA |
| | | | (100) | (10) | | | | (1,500) | (600) |
| Example 1-4 | R-4 | — | PAG-4 | I-3 | — | — | — | PGMEA | DAA |
| | | | (100) | (10) | | | | (1,500) | (600) |
| Example 1-5 | R-5 | — | PAG-5 | I-3 | — | — | — | PGMEA | DAA |
| | | | (100) | (10) | | | | (1,500) | (600) |
| Example 1-6 | R-6 | — | PAG-6 | I-3 | — | — | — | PGMEA | DAA |
| | | | (100) | (10) | | | | (1,500) | (600) |
| Example 1-7 | R-7 | — | PAG-7 | I-1 | — | — | — | PGMEA | DAA |
| | | | (100) | (5) | | | | (1,500) | (600) |
| Example 1-8 | R-8 | — | PAG-8 | I-1 | — | — | — | PGMEA | DAA |
| | | | (100) | (10) | | | | (1,500) | (600) |
| Example 1-9 | R-9 | — | PAG-9 | I-1 | — | — | — | PGMEA | DAA |
| | | | (100) | (15) | | | | (1,500) | (600) |
| Example 1-10 | R-10 | — | PAG-10 | I-2 | — | — | — | PGMEA | DAA |
| | | | (100) | (5) | | | | (1,500) | (600) |
| Example 1-11 | R-11 | — | PAG-11 | I-2 | — | — | — | PGMEA | DAA |
| | | | (100) | (10) | | | | (1,500) | (600) |
| Example 1-12 | R-12 | — | PAG-12 | I-2 | — | — | — | PGMEA | DAA |
| | | | (100) | (15) | | | | (1,500) | (600) |
| Example 1-13 | R-13 | — | PAG-13 | I-3 | — | — | — | PGMEA | DAA |
| | | | (100) | (5) | | | | (1,500) | (600) |
| Example 1-14 | R-14 | — | PAG-14 | I-3 | — | — | — | PGMEA | DAA |
| | | | (100) | (10) | | | | (1,500) | (600) |
| Example 1-15 | R-15 | — | PAG-15 | I-3 | — | — | — | PGMEA | DAA |
| | | | (100) | (15) | | | | (1,500) | (600) |
| Example 1-16 | R-16 | — | PAG-16 | I-3 | — | — | — | PGMEA | DAA |
| | | | (100) | (10) | | | | (1,500) | (600) |
| Example 1-17 | R-17 | — | PAG-17 | I-3 | — | — | — | PGMEA | DAA |
| | | | (100) | (10) | | | | (1,500) | (600) |
| Example 1-18 | R-18 | — | PAG-18 | I-3 | — | — | — | PGMEA | DAA |
| | | | (100) | (10) | | | | (1,500) | (600) |
| Example 1-19 | R-19 | — | PAG-19 | I-3 | — | — | — | PGMEA | DAA |
| | | | (100) | (10) | | | | (1,500) | (600) |
| Example 1-20 | R-20 | — | PAG-20 | I-3 | — | — | — | PGMEA | DAA |
| | | | (100) | (10) | | | | (1,500) | (600) |
| Comparative | CR-1 | — | PAG-A | | — | — | — | PGMEA | DAA |
| Example 1-1 | | | (108) | | | | | (1,500) | (600) |
| Comparative | CR-2 | — | PAG-B | | — | — | — | PGMEA | DAA |
| Example 1-2 | | | (100) | | | | | (1,500) | (600) |
| Comparative | CR-3 | P-1 | PAG-C | | — | Q-A | SF-1 | PGMEA | DAA |
| Example 1-3 | | (65) | (19) | | | (1.3) | (0.01) | (1,500) | (600) |
| Comparative | CR-4 | P-2 | — | | — | Q-B | SF-1 | PGMEA | DAA |
| Example 1-4 | | (65) | | | | (4.0) | (0.01) | (1,500) | (600) |
| Comparative | CR-5 | — | PAG-C | | Y-1 | Q-A | SF-1 | PGMEA | DAA |
| Example 1-5 | | | (10) | | (100) | (1.3) | (0.01) | (1,500) | (600) |
| Comparative | CR-6 | | PAG-3 | | | | | PGMEA | DAA |
| Example 1-6 | | | (100) | | | | | (1,500) | (600) |
| Comparative | CR-7 | | PAG-4 | | | | | PGMEA | DAA |
| Example 1-7 | | | (100) | | | | | (1,500) | (600) |
| Comparative | CR-8 | | PAG-5 | | | | | PGMEA | DAA |
| Example 1-8 | | | (100) | | | | | (1,500) | (600) |

In Table 1, the iodonium salts (I-1 to I-3), photoacid generators (PAG-A to PAG-C), sensitivity modifiers (Q-A, Q-B), nonionic monomer (Y-1), surfactant (SF-1), and solvents are as follows:

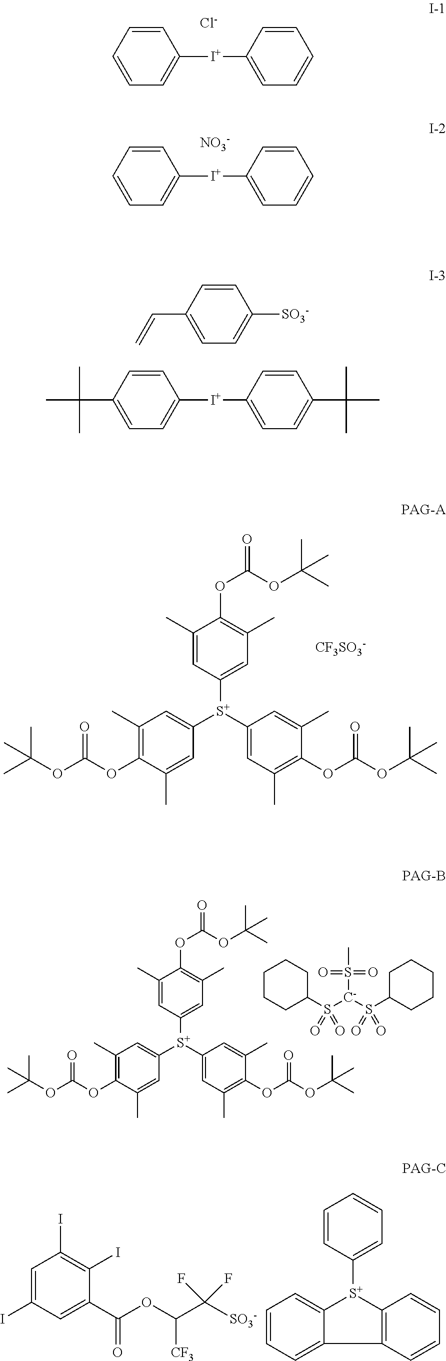

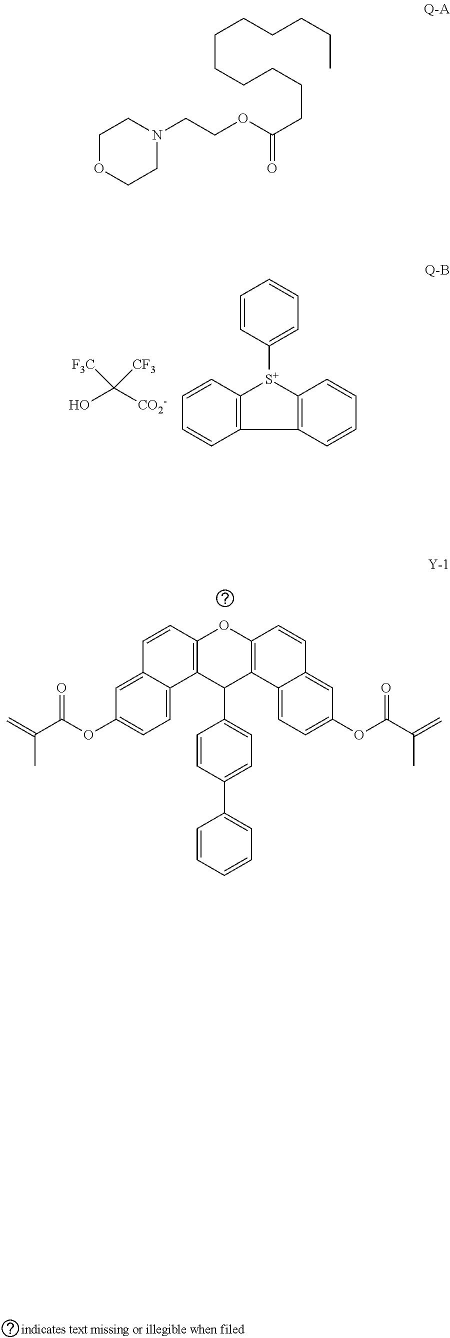

SF-1: PF636 (manufactured by Omnova Solutions Inc.)
Solvent: PGMEA (propylene glycol monomethyl ether acetate)
   DAA (diacetone alcohol)

### [4] EB Lithography Evaluation

### Examples 2-1 to 2-20, Comparative Examples 2-1 to 2-8

Each resist composition (R-1 to R-20, CR-1 to CR-8) was spin-coated onto an Si substrate having an antireflection film (DUV-42, manufactured by Nissan Chemical Corporation) formed thereon to a film thickness of 60 nm, followed by prebaking on a hot plate at 100° C. for 60 seconds to form a resist film having a thickness of 50 nm. The resulting resist film was exposed using an EB drawing apparatus (ELS-F125, manufactured by ELIONIX Inc.; acceleration voltage: 125 kV), subjected to PEB on a hot plate at the temperature shown in Table 2 for 60 seconds, and developed with a 2.38% by mass aqueous TMAH solution for 30 seconds to form a pattern. In Examples 2-1 to 2-20, Comparative Example 2-2, and Comparative Examples 2-5 to 2-8, the resist film remained in the exposed portions, indicating a negative-tone characteristic. In Comparative Examples 2-3 and 2-4, the resist film remained in the unexposed portions, indicating a positive-tone characteristic. As a result, a negative-type or positive-type line-and-space (LS) pattern having a space width of 40 nm and a pitch of 80 nm was obtained. In Comparative Example 2-1, no pattern formation was observed. The obtained LS patterns were evaluated for sensitivity, LWR, and resolution limit in accordance with the methods described below. The results are shown in Table 2.

### [Sensitivity Evaluation]

The above LS pattern was observed using a CD-SEM (CG-5000, manufactured by Hitachi High-Tech Corporation), and the optimum exposure dose Eop (μC/cm²) at which an LS pattern having a space width of 40 nm and a pitch of 80 nm was obtained was determined. This value was defined as the sensitivity.

### [LWR Evaluation]

The LS pattern obtained by exposure at the optimum exposure dose Eop was observed using a CD-SEM (CG-5000, manufactured by Hitachi High-Tech Corporation), and the space width was measured at 10 points in the longitudinal direction. Based on the results, three times (3σ) the standard deviation (σ) was calculated and defined as the LWR. The smaller the value is, the smaller the roughness and the more uniform the space width of the pattern can be obtained.

### [Resolution Limit Evaluation]

The minimum line width (nm) of the LS pattern that was separated at the optimum exposure dose Eop was defined as the resolution limit.

TABLE 2

| | | | Optimum | | |
|---|---|---|---|---|---|
| | | PEB | exposure | | |
| | Resist | temperature | dose | LWR | Resolution |
| | composition | (° C.) | (μC/cm²) | (nm) | limit (nm) |
| Example | R-1 | 60 | 170 | 4.0 | 28 |
| 2-1 | | | | | |
| Example | R-2 | 60 | 180 | 4.0 | 28 |
| 2-2 | | | | | |
| Example | R-3 | 60 | 120 | 3.9 | 26 |
| 2-3 | | | | | |
| Example | R-4 | 60 | 70 | 3.9 | 26 |
| 2-4 | | | | | |
| Example | R-5 | 60 | 40 | 3.8 | 26 |
| 2-5 | | | | | |
| Example | R-6 | 60 | 50 | 3.9 | 24 |
| 2-6 | | | | | |
| Example | R-7 | 60 | 60 | 4.0 | 24 |
| 2-7 | | | | | |
| Example | R-8 | 60 | 220 | 4.0 | 28 |
| 2-8 | | | | | |
| Example | R-9 | 60 | 150 | 4.0 | 26 |
| 2-9 | | | | | |
| Example | R-10 | 60 | 170 | 4.0 | 26 |
| 2-10 | | | | | |
| Example | R-11 | 60 | 110 | 4.1 | 26 |
| 2-11 | | | | | |
| Example | R-12 | 60 | 90 | 4.0 | 26 |
| 2-12 | | | | | |
| Example | R-13 | 60 | 90 | 4.0 | 26 |
| 2-13 | | | | | |
| Example | R-14 | 60 | 110 | 4.0 | 26 |
| 2-14 | | | | | |
| Example | R-15 | 60 | 30 | 4.2 | 26 |
| 2-15 | | | | | |
| Example | R-16 | 60 | 60 | 4.0 | 24 |
| 2-16 | | | | | |
| Example | R-17 | 60 | 60 | 4.1 | 26 |
| 2-17 | | | | | |
| Example | R-18 | 60 | 40 | 4.0 | 24 |
| 2-18 | | | | | |
| Example | R-19 | 60 | 110 | 4.0 | 26 |
| 2-19 | | | | | |
| Example | R-20 | 60 | 50 | 4.0 | 24 |
| 2-20 | | | | | |
| Comparative | CR-1 | 60 | — | — | — |
| Example 2-1 | | | | | |
| Comparative | CR-2 | 60 | 280 | 4.8 | 30 |
| Example 2-2 | | | | | |
| Comparative | CR-3 | 80 | 560 | 6.2 | 40 |
| Example 2-3 | | | | | |
| Comparative | CR-4 | 80 | 500 | 5.4 | 40 |
| Example 2-4 | | | | | |
| Comparative | CR-5 | 85 | 400 | 6.6 | 45 |
| Example 2-5 | | | | | |
| Comparative | CR-6 | 60 | 180 | 4.4 | 26 |
| Example 2-6 | | | | | |
| Comparative | CR-7 | 60 | 130 | 4.4 | 26 |
| Example 2-7 | | | | | |
| Comparative | CR-8 | 60 | 60 | 4.1 | 26 |
| Example 2-8 | | | | | |

From the results shown in Table 2, it was confirmed that the molecular resist compositions of the present invention exhibited superior sensitivity, LWR, and resolution limit in the formation of negative-type patterns by alkali aqueous solution development in EB lithography, as compared with a polymer-based positive-type resist composition and a positive-type resist composition containing a nonionic monomer. Furthermore, it was confirmed that the addition of an iodonium salt improves both sensitivity and LWR. The results of Examples 2-3 to 2-5 and Comparative Examples 2-6 to 2-8 clearly show that, even when the main component of the molecular resist composition (a sulfonium salt having a polymerizable functional group) is the same, the former, in which the iodonium salt used in the present invention is co-present, has a reduced optimum exposure dose (i.e., improved sensitivity) and a smaller LWR compared to the latter, which is free of the iodonium salt.

### [5] EUV Lithography Evaluation

### Examples 3-1 to 3-20, Comparative Examples 3-1 to 3-8

Each resist composition (R-1 to R-20, CR-1 to CR-8) was spin-coated onto an Si substrate having a 20 nm thick silicon-containing spin-on hard mask SHB-A940 (manufactured by Shin-Etsu Chemical Co., Ltd.; with 43% by mass silicon content) formed thereon, followed by prebaking on a hot plate at 100° C. for 60 seconds to form a resist film having a thickness of 40 nm. The 22 nm LS 1:1 pattern was exposed using the EUV scanner NXE3300 (manufactured by ASML; NA 0.33, 6 0.9, 90-degree dipole illumination). After exposure, a PEB was performed on the hot plate at the temperature indicated in Table 3 for 60 seconds, followed by development in a 2.38% by mass TMAH aqueous solution for 30 seconds to form the pattern. In Examples 3-1 to 3-20, Comparative Example 3-2, and Comparative Examples 3-5 to 3-8, the resist film in the exposed portions remained, while in Comparative Examples 3-3 and 3-4, the resist film in the unexposed portions remained. As a result, a LS pattern with a space width of 22 nm and a pitch of 44 nm was obtained in both negative-type and positive-type. In Comparative Example 3-1, no pattern formation was observed. The obtained LS patterns were evaluated for sensitivity, LWR, and resolution limit in accordance with the methods described below. The results are shown in Table 3.

### [Sensitivity Evaluation]

The above LS pattern was observed using a CD-SEM (CG-5000, manufactured by Hitachi High-Tech Corporation), and the optimum exposure dose Eop (mJ/cm²) at which an LS pattern having a space width of 22 nm and a pitch of 44 nm was obtained was determined. This value was defined as the sensitivity.

### [LWR Evaluation]

The LS pattern obtained by exposure at the optimum exposure dose Eop was observed using a CD-SEM (CG-5000, manufactured by Hitachi High-Tech Corporation), and the space width was measured at 10 points in the longitudinal direction. Based on the results, three times (3σ) the standard deviation (σ) was calculated and defined as the LWR. The smaller the value is, the smaller the roughness and the more uniform the space width of the pattern can be obtained.

### [Resolution Limit Evaluation]

The minimum line width (nm) of the LS pattern that was separated at the optimum exposure dose Fop was defined as the resolution limit.

TABLE 3

| | | | Optimum | | |
|---|---|---|---|---|---|
| | | PEB | exposure | | Resolution |
| | Resist | temperature | dose | LWR | limit |
| | composition | (° C.) | (mJ/cm²) | (nm) | (nm) |
| Example | R-1 | 60 | 170 | 2.2 | 14 |
| 3-1 | | | | | |
| Example | R-2 | 60 | 180 | 2.2 | 14 |
| 3-2 | | | | | |
| Example | R-3 | 60 | 120 | 2.2 | 14 |
| 3-3 | | | | | |
| Example | R-4 | 60 | 70 | 2.0 | 14 |
| 3-4 | | | | | |
| Example | R-5 | 60 | 30 | 2.0 | 14 |
| 3-5 | | | | | |
| Example | R-6 | 60 | 40 | 2.1 | 12 |
| 3-6 | | | | | |
| Example | R-7 | 60 | 60 | 2.1 | 14 |
| 3-7 | | | | | |
| Example | R-8 | 60 | 220 | 2.1 | 14 |
| 3-8 | | | | | |
| Example | R-9 | 60 | 150 | 2.2 | 14 |
| 3-9 | | | | | |
| Example | R-10 | 60 | 170 | 2.1 | 14 |
| 3-10 | | | | | |
| Example | R-11 | 60 | 110 | 2.1 | 14 |
| 3-11 | | | | | |
| Example | R-12 | 60 | 90 | 2.2 | 14 |
| 3-12 | | | | | |
| Example | R-13 | 60 | 90 | 2.1 | 14 |
| 3-13 | | | | | |
| Example | R-14 | 60 | 110 | 2.1 | 14 |
| 3-14 | | | | | |
| Example | R-15 | 60 | 30 | 2.3 | 12 |
| 3-15 | | | | | |
| Example | R-16 | 60 | 60 | 2.1 | 14 |
| 3-16 | | | | | |
| Example | R-17 | 60 | 60 | 2.1 | 14 |
| 3-17 | | | | | |
| Example | R-18 | 60 | 40 | 2.1 | 12 |
| 3-18 | | | | | |
| Example | R-19 | 60 | 110 | 2.2 | 14 |
| 3-19 | | | | | |
| Example | R-20 | 60 | 50 | 2.1 | 14 |
| 3-20 | | | | | |
| Comparative | CR-1 | 60 | — | — | — |
| Example 3-1 | | | | | |
| Comparative | CR-2 | 60 | 30 | 3 | 16 |
| Example 3-2 | | | | | |
| Comparative | CR-3 | 80 | 52 | 4.3 | 22 |
| Example 3-3 | | | | | |
| Comparative | CR-4 | 80 | 40 | 3.8 | 20 |
| Example 3-4 | | | | | |
| Comparative | CR-5 | 85 | 36 | 4.1 | 24 |
| Example 3-5 | | | | | |
| Comparative | CR-6 | 60 | 180 | 2.7 | 14 |
| Example 3-6 | | | | | |
| Comparative | CR-7 | 60 | 130 | 2.7 | 14 |
| Example 3-7 | | | | | |
| Comparative | CR-8 | 60 | 60 | 2.6 | 14 |
| Example 3-8 | | | | | |

From the results shown in Table 3, it was confirmed that even in EUV lithography, similar to EB lithography the molecular resist compositions of the present invention exhibited superior sensitivity, LWR, and resolution limit in the formation of negative-type patterns by alkali aqueous solution development, as compared with a polymer-based positive-type resist composition and a positive-type resist composition containing a nonionic monomer. Furthermore, it was confirmed that the addition of an iodonium salt improves both sensitivity and LWR. The results of Examples 3-3 to 3-5 and Comparative Examples 3-6 to 3-8 clearly show that, even when the main component of the molecular resist composition (a sulfonium salt having a polymerizable functional group) is the same, the former, in which the iodonium salt used in the present invention is co-present, has a reduced optimum exposure dose (i.e., improved sensitivity) and a smaller LWR compared to the latter, which is free of the iodonium salt.

The present description includes the following inventions.

[1]:
A molecular resist composition comprising:
   a sulfonium salt represented by the following formula (1) or (2);
   an iodonium salt comprising an iodonium cation represented by the following formula (1-1) and a halide ion, a nitrate ion, a hydrogen sulfate ion, a hydrogen carbonate ion, a tetraphenylborate ion, or an anion represented by any one of the following formulae (1-2) to (1-8); and
   an organic solvent,
   wherein the molecular resist composition is free of a base polymer,

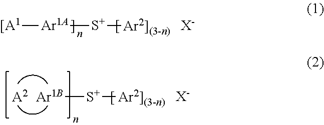

wherein n is an integer of 1 to 3; A¹ is a hydrocarbyl group having 2 to 20 carbon atoms and containing a polymerizable functional group, and the hydrocarbyl group optionally contains a hetero atom; A² is a group containing a polymerizable functional group and forming an alicyclic ring having 4 to 20 carbon atoms together with two carbon atoms in Ar^{1B}, and the alicyclic ring optionally contains a hetero atom; Ar^{1A} is an arylene group having 6 to 20 carbon atoms, and hydrogen atoms on the aromatic ring of the arylene group are optionally partially or entirely substituted with halogen atoms or hydrocarbyl groups having 1 to 20 carbon atoms and optionally containing a hetero atom; Ar^{1B} is a trivalent aromatic hydrocarbon group having 6 to 20 carbon atoms, and hydrogen atoms on the aromatic ring of the trivalent aromatic hydrocarbon group are optionally partially or entirely substituted with halogen atoms or hydrocarbyl groups having 1 to 20 carbon atoms and optionally containing a hetero atom; Ar² is an aryl group having 6 to 20 carbon atoms, and hydrogen atoms on the aromatic ring of the aryl group are optionally partially or entirely substituted with halogen atoms or hydrocarbyl groups having 1 to 20 carbon atoms and optionally containing a hetero atom; two Ar^{1A} groups, two Ar^{1B} groups, two Ar² groups, Ar^{1A} and Ar², or Ar^{1B} and Ar², are optionally bonded to each other to form a ring together with the sulfur atom to which they are bonded; and X⁻ is a counter anion;

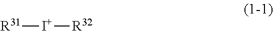

wherein R³¹ and R³² are each independently a halogen atom or a hydrocarbyl group having 1 to 30 carbon atoms and optionally containing a hetero atom;

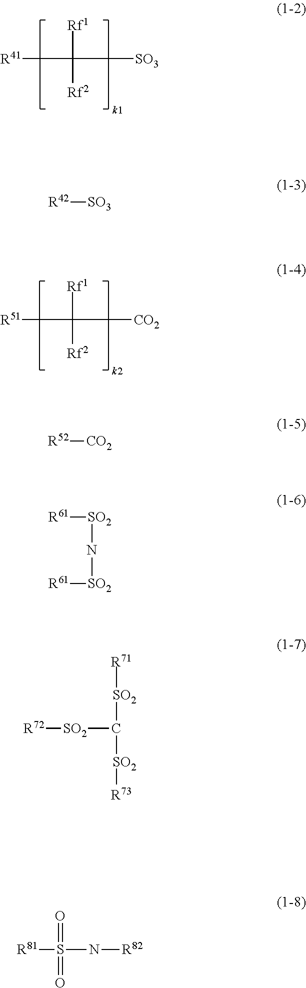

wherein k1 and k2 are each independently 1, 2, 3, or 4; Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time; R⁴¹ is a hydrogen atom, a halogen atom, a hydroxy group, or a hydrocarbyl group having 1 to 50 carbon atoms and optionally containing a hetero atom; R⁴² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the sulfo group is substituted with a fluorine atom or a fluoroalkyl group; R⁵¹ is a hydrogen atom, a halogen atom, a hydroxy group, or a hydrocarbyl group having 1 to 50 carbon atoms and optionally containing a hetero atom; R⁵² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the carboxy group is substituted with fluorine or a fluoroalkyl group; R⁶¹ and R⁶² are each independently a hydrocarbyl group having 1 to 50 carbon atoms and optionally containing a hetero atom; R⁷¹ to R⁷³ are each independently a hydrocarbyl group having 1 to 50 carbon atoms and optionally containing a hetero atom; R⁸¹ is a fluorine atom or a fluorinated hydrocarbyl group having 1 to 10 carbon atoms, and the fluorinated hydrocarbyl group optionally contains a hydroxy group, an ether bond, or an ester bond; R⁸² is a hydrogen atom or a hydrocarbyl group having 1 to 20 carbon atoms, and the hydrocarbyl group optionally contains a hydroxy group, an ether bond, or an ester bond; and R⁸¹ and R⁸² are optionally bonded to each other to form a ring together with the atoms to which they are bonded.
[2] The molecular resist composition according to [1], wherein the A¹ is an acryloyloxy group, a methacryloyloxy group, a cycloalkenyl group having 3 to 20 carbon atoms and optionally containing a hetero atom, a cycloalkenyloxy group having 3 to 20 carbon atoms and optionally containing a hetero atom, a cycloalkenylcarbonyloxy group having 3 to 20 carbon atoms and optionally containing a hetero atom, an alkenyl group having 2 to 20 carbon atoms and optionally containing a hetero atom, or an alkenyloxy group having 2 to 20 carbon atoms and optionally containing a hetero atom, and the A² is a group that forms, together with two carbon atoms in Ar^{1B}, a cycloalkene ring having 4 to 20 carbon atoms and optionally containing a hetero atom or a polycyclic ring having 4 to 20 carbon atoms and having one double bond and optionally containing a hetero atom.
[3] The molecular resist composition according to [1] or [2], wherein X⁻ is the same as the counter anion of the iodonium cation represented by the formula (1-1).
[4] The molecular resist composition according to any one of [1] to [3], wherein the anion represented by any one of the formulae (1-2) to (1-8) includes a polymerizable functional group.
[5] The molecular resist composition according to any one of [1] to [4], further comprising a radical scavenger.
[6] The molecular resist composition according to claim any one of [1] to [5], further comprising a surfactant.
[7]A patterning process comprising:
   forming a resist film on a substrate using the molecular resist composition according to any one of any one of [1] to [6];
   exposing the resist film to high-energy ray; and
   developing the exposed resist film with a developer.
[8] The patterning process according to [7], wherein an alkaline aqueous solution is used as the developer to dissolve an exposed portion, thereby obtaining a positive-type pattern in which an unexposed portion is not dissolved.
[9] The patterning process according to [7], wherein an organic solvent or an alkaline aqueous solution is used as the developer to dissolve an unexposed portion, thereby obtaining a negative-type pattern in which an exposed portion is not dissolved.
[10] The patterning process according to [9], wherein at least one selected from the group consisting of 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate, is used as the organic solvent as the developer.
[11] The patterning process according to any one of [7] to [10], wherein an electron beam or extreme ultraviolet ray is used as the high-energy ray.

It should be noted that the present invention is not limited to the above-described embodiments. The embodiments are just examples, and those that substantially have the same feature and demonstrate the same functions and effects as those in the technical concept disclosed in claims of the present invention are included in the technical scope of the present invention.

1. A molecular resist composition comprising:
a sulfonium salt represented by the following formula (1) or (2);
an iodonium salt comprising an iodonium cation represented by the following formula (1-1) and a halide ion, a nitrate ion, a hydrogen sulfate ion, a hydrogen carbonate ion, a tetraphenylborate ion, or an anion represented by any one of the following formulae (1-2) to (1-8); and
an organic solvent,
wherein the molecular resist composition is free of a base polymer, 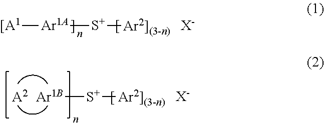
wherein n is an integer of 1 to 3; A¹ is a hydrocarbyl group having 2 to 20 carbon atoms and containing a polymerizable functional group, and the hydrocarbyl group optionally contains a hetero atom; A² is a group containing a polymerizable functional group and forming an alicyclic ring having 4 to 20 carbon atoms together with two carbon atoms in Ar^{1B}, and the alicyclic ring optionally contains a hetero atom; Ar^{1A} is an arylene group having 6 to 20 carbon atoms, and hydrogen atoms on the aromatic ring of the arylene group are optionally partially or entirely substituted with halogen atoms or hydrocarbyl groups having 1 to 20 carbon atoms and optionally containing a hetero atom; Ar^{1B} is a trivalent aromatic hydrocarbon group having 6 to 20 carbon atoms, and hydrogen atoms on the aromatic ring of the trivalent aromatic hydrocarbon group are optionally partially or entirely substituted with halogen atoms or hydrocarbyl groups having 1 to 20 carbon atoms and optionally containing a hetero atom; Ar² is an aryl group having 6 to 20 carbon atoms, and hydrogen atoms on the aromatic ring of the aryl group are optionally partially or entirely substituted with halogen atoms or hydrocarbyl groups having 1 to 20 carbon atoms and optionally containing a hetero atom; two Ar^{1A} groups, two Ar^{1B} groups, two Ar² groups, Ar^{1A} and Ar², or Ar^{1B} and Ar², are optionally bonded to each other to form a ring together with the sulfur atom to which they are bonded; and X⁻ is a counter anion; 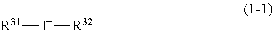
wherein R³¹ and R³² are each independently a halogen atom or a hydrocarbyl group having 1 to 30 carbon atoms and optionally containing a hetero atom; 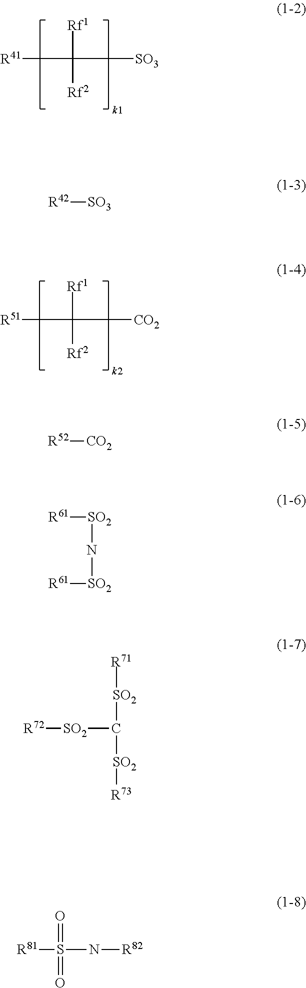
wherein k1 and k2 are each independently 1, 2, 3, or 4; Rf¹ and Rf² are each independently a hydrogen atom, a fluorine atom, or a fluorine-containing alkyl group having 1 to 6 carbon atoms, provided that not all of Rf¹ and Rf² are hydrogen atoms at the same time; R⁴¹ is a hydrogen atom, a halogen atom, a hydroxy group, or a hydrocarbyl group having 1 to 50 carbon atoms and optionally containing a hetero atom; R⁴² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the sulfo group is substituted with a fluorine atom or a fluoroalkyl group; R⁵¹ is a hydrogen atom, a halogen atom, a hydroxy group, or a hydrocarbyl group having 1 to 50 carbon atoms and optionally containing a hetero atom; R⁵² is a hydrogen atom, a halogen atom, a hydroxy group, or a hydrocarbyl group having 1 to 50 carbon atoms and optionally containing a hetero atom, excluding a hydrocarbyl group in which hydrogen on the α- or β-position carbon atoms of the carboxy group is substituted with a fluorine atom or a fluoroalkyl group; R⁶¹ and R⁶² are each independently a hydrocarbyl group having 1 to 50 carbon atoms and optionally containing a hetero atom; R⁷¹ to R⁷³ are each independently a hydrocarbyl group having 1 to 50 carbon atoms and optionally containing a hetero atom; R⁸¹ is a fluorine atom or a fluorinated hydrocarbyl group having 1 to 10 carbon atoms, and the fluorinated hydrocarbyl group optionally contains a hydroxy group, an ether bond, or an ester bond; R⁸² is a hydrogen atom or a hydrocarbyl group having 1 to 20 carbon atoms, and the hydrocarbyl group optionally contains a hydroxy group, an ether bond, or an ester bond; and R⁸¹ and R⁸² are optionally bonded to each other to form a ring together with the atoms to which they are bonded.

2. The molecular resist composition according to claim 1, wherein the A¹ is an acryloyloxy group, a methacryloyloxy group, a cycloalkenyl group having 3 to 20 carbon atoms and optionally containing a hetero atom, a cycloalkenyloxy group having 3 to 20 carbon atoms and optionally containing a hetero atom, a cycloalkenylcarbonyloxy group having 3 to 20 carbon atoms and optionally containing a hetero atom, an alkenyl group having 2 to 20 carbon atoms and optionally containing a hetero atom, or an alkenyloxy group having 2 to 20 carbon atoms and optionally containing a hetero atom, and the A² is a group that forms, together with two carbon atoms in Ar^{1B}, a cycloalkene ring having 4 to 20 carbon atoms and optionally containing a hetero atom or a polycyclic ring having 4 to 20 carbon atoms and having one double bond and optionally containing a hetero atom.

3. The molecular resist composition according to claim 1, wherein X⁻ is the same as the counter anion of the iodonium cation represented by the formula (1-1).

4. The molecular resist composition according to claim 2, wherein X⁻ is the same as the counter anion of the iodonium cation represented by the formula (1-1).

5. The molecular resist composition according to claim 1, wherein the anion represented by any one of the formulae (1-2) to (1-8) includes a polymerizable functional group.

6. The molecular resist composition according to claim 2, wherein the anion represented by any one of the formulae (1-2) to (1-8) includes a polymerizable functional group.

7. The molecular resist composition according to claim 1, further comprising a radical scavenger.

8. The molecular resist composition according to claim 2, further comprising a radical scavenger.

9. The molecular resist composition according to claim 1, further comprising a surfactant.

10. The molecular resist composition according to claim 2, further comprising a surfactant.

11. A patterning process comprising:
forming a resist film on a substrate using the molecular resist composition according to claim 1;
exposing the resist film to high-energy ray; and
developing the exposed resist film with a developer.

12. A patterning process comprising:
forming a resist film on a substrate using the molecular resist composition according to claim 2;
exposing the resist film to high-energy ray; and
developing the exposed resist film with a developer.

13. A patterning process comprising:
forming a resist film on a substrate using the molecular resist composition according to claim 3;
exposing the resist film to high-energy ray; and
developing the exposed resist film with a developer.

14. A patterning process comprising:
forming a resist film on a substrate using the molecular resist composition according to claim 4;
exposing the resist film to high-energy ray; and
developing the exposed resist film with a developer.

15. A patterning process comprising:
forming a resist film on a substrate using the molecular resist composition according to claim 5;
exposing the resist film to high-energy ray; and
developing the exposed resist film with a developer.

16. A patterning process comprising:
forming a resist film on a substrate using the molecular resist composition according to claim 6;
exposing the resist film to high-energy ray; and
developing the exposed resist film with a developer.

17. The patterning process according to claim 11, wherein an alkaline aqueous solution is used as the developer to dissolve an exposed portion, thereby obtaining a positive-type pattern in which an unexposed portion is not dissolved.

18. The patterning process according to claim 11, wherein an organic solvent or an alkaline aqueous solution is used as the developer to dissolve an unexposed portion, thereby obtaining a negative-type pattern in which an exposed portion is not dissolved.

19. The patterning process according to claim 18, wherein at least one selected from the group consisting of 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, cyclohexyl acetate, propyl formate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, and 2-phenylethyl acetate, is used as the organic solvent as the developer.

20. The patterning process according to claim 11, wherein an electron beam or extreme ultraviolet ray is used as the high-energy ray.
